(19) United States
(12) Patent Application Publication
(10) Pub. No.: US 2025/0294804 A1
(43) Pub. Date: Sep. 18, 2025

(54) SEMICONDUCTOR DEVICE

(71) Applicant: ROHM CO., LTD., Kyoto (JP)

(72) Inventors: Keiji YAMAMOTO, Kyoto-shi (JP); Hajime OKUDA, Kyoto (JP); Yoshinori FUKUDA, Kyoto (JP)

(73) Assignee: ROHM CO., LTD., Kyoto (JP)

(21) Appl. No.: 19/221,293

(22) Filed: May 28, 2025

Related U.S. Application Data
(63) Continuation of application No. PCT/JP2023/042566, filed on Nov. 28, 2023.

(30) Foreign Application Priority Data
Nov. 30, 2022 (JP) 2022-192213

(51) Int. Cl. H10D 30/66; H10D 30/01; H10D 62/00; H10D 62/10; H10D 64/00

(52) U.S. Cl. CPC H10D 30/668; H10D 30/0297; H10D 62/01; H10D 62/127; H10D 64/117

(57) ABSTRACT

A semiconductor device includes a chip that has a main surface, a trench that is formed in the main surface, and that has a side wall and a bottom wall, an embedded electrode that is embedded in the trench, and that has an electrode surface positioned on the bottom wall side with respect to the main surface and a recess edge portion recessed toward the bottom wall side at an edge portion along the side wall in the electrode surface, and an edge portion insulator that is embedded in the recess edge portion.

### CROSS REFERENCE TO RELATED APPLICATIONS

The present application is a bypass continuation of International Patent Application No. PCT/JP2023/042566 filed on Nov. 28, 2023, which claims priority to Japanese Patent Application No. 2022-192213 filed in the Japan Patent Office on Nov. 30, 2022, and the entire disclosure of this application is incorporated herein by reference.

### BACKGROUND

### 1. Field of the disclosure

The present disclosure relates to a semiconductor device.

### 2. Description of the Related Art

US2006/0292764A1 discloses a semiconductor device which includes a substrate, a trench, a polysilicon, and a side spacer in FIG. 12. The trench is formed in a surface of the substrate. The polysilicon is embedded in the trench. The side spacer is made of an insulator such as a nitride and is formed on a side wall of the trench on the polysilicon.

### BRIEF DESCRIPTION OF DRAWINGS

FIG. 1 is a plan view showing a semiconductor device according to a specific embodiment.

FIG. 2 is a cross-sectional view taken along line II-II shown in FIG. 1.

FIG. 3 is a schematic circuit diagram of an electrical configuration of the semiconductor device shown FIG. 1.

FIG. 4 is a schematic circuit diagram showing a configuration of an output transistor.

FIG. 5 is a plan view showing an output region.

FIG. 6 is an enlarged plan view showing one principal part of the output region shown in FIG. 5.

FIG. 7 is an enlarged plan view showing a further principal part of the output region shown in FIG. 5.

FIG. 8 is a cross sectional view taken along line VIII-VIII shown in FIG. 6.

FIG. 9 is a cross sectional view taken along line IX-IX shown in FIG. 6.

FIG. 10 is a cross sectional view taken along line X-X shown in FIG. 6.

FIG. 11 is a cross sectional view taken along line XI-XI shown in FIG. 6.

FIG. 12 is a cross sectional view taken along line XII-XII shown in FIG. 6.

FIG. 13 is an enlarged cross sectional view showing one trench structure that is extracted from the structure shown in FIG. 8.

FIG. 14 is an enlarged cross sectional view showing one trench structure that is extracted from the structure shown in FIG. 8.

FIG. 15 is an enlarged cross sectional view showing one trench structure that is extracted from the structure shown in FIG. 9.

FIG. 16 is an enlarged cross sectional view showing a principal part of the trench structure.

FIG. 17 is a schematic diagram showing a wafer to be used for a manufacturing method for the semiconductor device.

FIGS. 18A to 18X are cross sectional views for describing the manufacturing method for the semiconductor device.

FIG. 19 is a cross sectional view in which the trench structure on a first device region side and the trench structure on a second device region side are to be compared.

FIG. 20 is a graph showing a relationship between a channel length and a recess depth.

FIG. 21 is a cross sectional view showing the gate structure according to another configuration example.

FIG. 22 is a cross sectional view showing the gate structure according to another configuration example.

FIG. 23 is a cross sectional view showing the gate structure according to another configuration example.

FIG. 24 is a cross sectional view showing the gate structure according to another configuration example.

FIG. 25 is a cross sectional view showing the gate structure according to another configuration example.

### DETAILED DESCRIPTION OF THE PREFERRED EMBODIMENTS

Hereinafter, specific embodiments will be described in detail with reference to the accompanying drawings. The accompanying drawings are all schematic diagrams and are not strictly illustrated, and the relative positions, scales, ratios, angles, etc., do not necessarily correspond to those shown. The same reference sign is assigned to a constituent that corresponds to each constituent in the accompanying drawings, and a duplicated description of this constituent is omitted or simplified. For structures where descriptions have been omitted or simplified, the description given before the omission or simplification applies.

In a case in which the term “substantially equal” is used when components including a comparison target are described, this term includes a numerical value (form) equal to a numerical value (form) of the comparison target, and, in addition, includes a numerical deviation (error) falling within the range of ±10% based on the numerical value (form) of the comparison target. Although the terms “first,” “second,” “third,” etc., are used in the following descriptions, these are symbols assigned to the name of each constituent in order to clarify the explanatory order, and are not assigned to the effect that the name of each constituent is limited.

In the following descriptions, a conductivity type of a semiconductor region (impurity region) is indicated by using a “p-type” or an “n-type,” but the “p-type” may also be called a “first conductivity type” and the “n-type” may also be called a “second conductivity type.” As a matter of course, the “n-type” may be referred to as the “first conductivity type,” and the “p-type” may be referred to as the “second conductivity type.” The “p-type” is a conductivity type due to trivalent elements and the “n-type” is a conductivity type due to pentavalent elements. The trivalent elements are at least one of boron, aluminum, gallium, and indium, unless otherwise noted. The pentavalent elements are at least one of nitrogen, phosphorus, arsenic, antimony, and bismuth, unless otherwise noted.

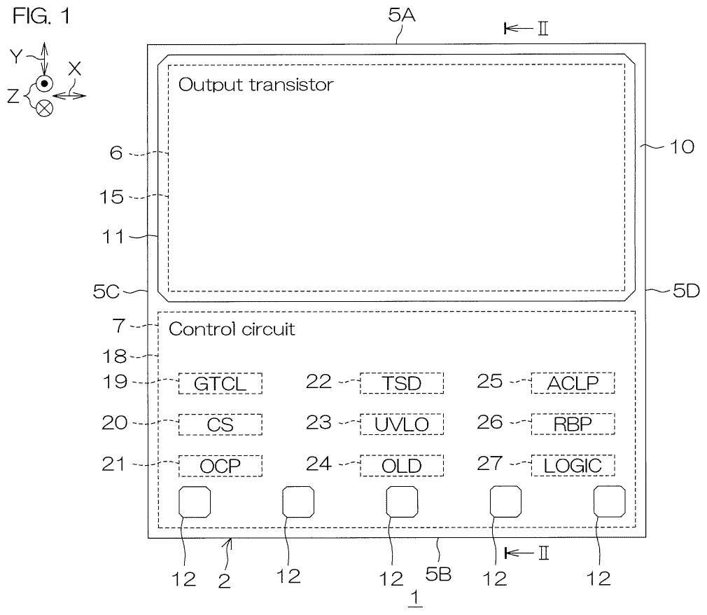

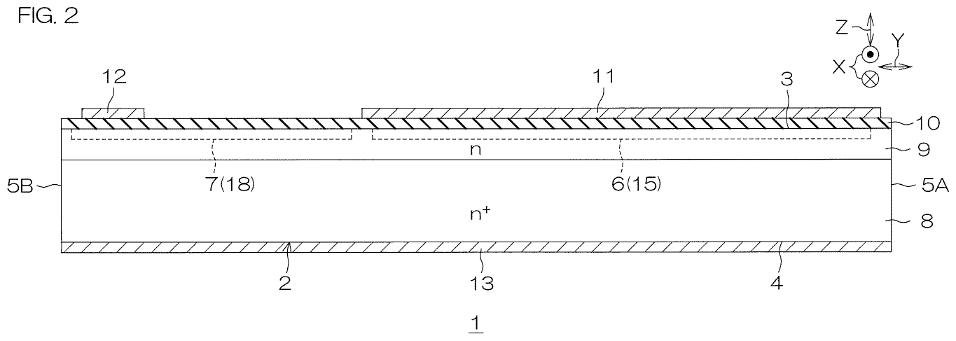

FIG. 1 is a plan view showing a semiconductor device 1 according to a specific embodiment. FIG. 2 is a cross sectional view taken along line II-II shown in FIG. 1. With reference to FIG. 1 and FIG. 2, the semiconductor device 1 includes a chip 2 that is formed in a rectangular parallelepiped shape. The chip 2 is an Si-chip including a silicon monocrystal in this embodiment.

As a matter of course, the chip 2 may be of a wide bandgap semiconductor chip including a monocrystal of a wide bandgap semiconductor. The wide bandgap semiconductor is a semiconductor which has a bandgap greater than a bandgap of the Si. Gallium nitride (GAN), silicon carbide (SiC), and diamond (C), etc., are exemplified as the wide bandgap semiconductor. For example, the chip 2 may be of an SiC-chip including an SiC monocrystal.

The chip 2 has a first main surface 3 on one side, the second main surface 4 on another side, and first to fourth side surfaces 5A to 5D connecting the first main surface 3 and the second main surface 4. The first main surface 3 and the second main surface 4 are each formed in a quadrangular shape as viewed from their normal direction Z (hereinafter, simply referred to as “in the plan view”). The normal direction Z is also a thickness direction of the chip 2.

The first main surface 3 is a circuit surface on which various circuit structures that constitute electronic circuits are formed. The second main surface 4 is a non-circuit surface that does not have any circuit structures. The first side surface 5A and the second side surfaces 5B extend in a first direction X along the first main surface 3 and face in (are opposed to) a second direction Y that intersects (specifically, is perpendicular to) the first direction X. The third side surfaces 5C and the fourth side surfaces 5D extend in the second direction Y and face in (are opposed to) the first direction X.

The semiconductor device 1 includes an output region 6 that is provided in the first main surface 3. The output region 6 is a region which has an electronic circuit (circuit device) configured to generate an output signal to be output to an outside. The output region 6 is demarcated in a region on the first side surface 5A side at the first main surface 3 in this embodiment. The output region 6 is demarcated in a polygonal shape (a quadrangular shape in this embodiment) having four sides parallel to a peripheral edge of the first main surface 3 in the plan view.

A position, a size, a planar shape, etc., of the output region 6 are arbitrary and are not limited to a specific layout. The output region 6 may have a planar area of not less than 25% and not more than 80% with respect to a planar area of the first main surface 3. The planar area of the output region 6 may be not less than 30% of the planar area of the first main surface 3. The planar area of the output region 6 may be not less than 40% of the planar area of the first main surface 3.

The planar area of the output region 6 may be not less than 50% of the planar area of the first main surface 3. The planar area of the output region 6 may be not less than 75% of the planar area of the first main surface 3.

The semiconductor device 1 includes a control region 7 that is provided in a region different from that of the output region 6 in the first main surface 3. The control region 7 is a region which has a plurality of types of electronic circuits (circuit devices) configured to generate control signals for controlling the output region 6. The control region 7 is demarcated in a region on the second side surfaces 5B side with respect to the output region 6, and faces the output region 6 in the second direction Y in this embodiment. The control region 7 is demarcated in a polygonal shape (a quadrangular shape in this embodiment) having four sides parallel to the peripheral edge of the first main surface 3 in a plan view in this embodiment.

A position, a size, a planar shape, etc., of the control region 7 are arbitrary and are not limited to a specific layout. The control region 7 may have a planar area of not less than 25% and not more than 80% with respect to a planar area of the first main surface 3. The planar area of the control region 7 may be not less than 30% of the planar area of the first main surface 3. The planar area of the control region 7 may be not less than 40% of the planar area of the first main surface 3. The planar area of the control region 7 may be not less than 50% of the planar area of the first main surface 3. The planar area of the control region 7 may be not less than 75% of the planar area of the first main surface 3.

The planar area of the control region 7 may be substantially equal to the planar area of the output region 6. The planar area of the control region 7 may be larger than the planar area of the output region 6. The planar area of the control region 7 may be smaller than the planar area of the output region 6. A ratio of the planar area of the control region 7 with respect to the planar area of the output region 6 may be not less than 0.1 and not more than 4.

The semiconductor device 1 includes a drain region 8 of the n-type (first conductivity type) that is formed in a surface layer portion of the second main surface 4. The drain region 8 has an n-type impurity concentration of not less than 1×10¹⁸ cm⁻³ and not more than 1×10²¹ cm⁻³. The drain region 8 is formed in a layered shape extending along the second main surface 4 in a whole region of the surface layer portion of the second main surface 4, and is exposed from the second main surface 4 and the first to fourth side surfaces 5A to 5D.

The drain region 8 may have a thickness of not less than 50 μm and not more than 200 μm. The thickness of the drain region 8 is preferably not more than 150 μm. The drain region 8 is formed by a semiconductor substrate (a silicon substrate) of the n-type in this embodiment.

The semiconductor device 1 includes a drift region 9 of the n-type formed in a surface layer portion of the first main surface 3. The drift region 9 has an n-type impurity concentration lower than that of the drain region 8. The n-type impurity concentration of the drift region 9 may be not less than 1×10¹⁵ cm⁻³ and not more than 1×10¹⁸ cm⁻³. The drift region 9 is formed in a layer extending along the first main surface 3 in the output region 6 and the control region 7.

Specifically, the drift region 9 is formed in a layered shape extending along the first main surface 3 in a whole region of the surface layer portion of the first main surface 3, and is exposed from the first main surface 3 and the first to fourth side surfaces 5A to 5D. The drift region 9 is electrically connected to the drain region 8 inside the chip 2. The drift region 9 has a thickness less than the thickness of the drain region 8.

The thickness of the drift region 9 may be not less than 1 μm and not more than 20 μm. The thickness of the drift region 9 is preferably not less than 5 μm and not more than 15 μm. The thickness of the drift region 9 is particularly preferably not more than 10 μm. The drift region 9 is formed by an epitaxial layer (an Si epitaxial layer) of the n-type in this embodiment.

The semiconductor device 1 includes an interlayer film 10 that covers the first main surface 3. The interlayer film 10 collectively covers the output region 6 and the control region 7.

The interlayer film 10 may cover a whole region of the first main surface 3 so as to be continuous with the peripheral edge of the first main surface 3 (the first to fourth side surfaces 5A to 5D). As a matter of course, the interlayer film 10 may be formed at an interval inward from the peripheral edge of the first main surface 3 so as to expose a peripheral edge portion of the first main surface 3.

The interlayer film 10 has a multilayer wiring structure having a laminated structure in which a plurality of insulating layers and a plurality of wiring layers are alternately laminated in this embodiment. Each of the insulating layers may include at least one of a silicon oxide film and a silicon nitride film. Each of the wiring layers may include at least one of a pure Al layer (an Al layer with a purity of not less than 99%), a Cu layer (a Cu layer with a purity of not less than 99%), an AlCu alloy layer, an AlSiCu alloy layer, and an AlSi alloy layer.

The semiconductor device 1 includes a plurality of terminals 11 to 13 arranged on either or both (both in this embodiment) of the first main surface 3 and the second main surface 4. The terminals 11 to 13 include a source terminal 11, a plurality of control terminals 12, and a drain terminal 13.

The source terminal 11 is provided as an output terminal to be electrically connected to a load, and is arranged on a portion of the interlayer film 10 that covers the output region 6 in this embodiment. The source terminal 11 may cover a whole region of the output region 6 in the plan view. The source terminal 11 may include at least one of a pure Al layer, a Cu layer, an AlCu alloy layer, an AlSiCu alloy layer, and an AlSi alloy layer.

The control terminals 12 are terminals to be electrically connected to various electronic circuits within the control region 7, and are arranged on portions of the interlayer film 10 that cover the control region 7. The control terminals 12 include various terminals such as a ground terminal, an input terminal, a cathode terminal, an anode terminal, and a test terminal, in accordance with a circuit configuration in the control region 7. The control terminals 12 each has a planar area less than that of the source terminal 11, and are arranged at intervals along a peripheral edge portion of the control region 7 (the peripheral edge portion of the first main surface 3).

The planar area of each control terminal 12 is set within a range in which a bonding wire can be connected. The planar area of each control terminal 12 may be not more than 1/10 of the planar area of the source terminal 11. The control terminals 12 may include at least one of a pure Al layer, a Cu layer, an AlCu alloy layer, an AlSiCu alloy layer and an AlSi alloy layer.

The drain terminal 13 is provided as a power terminal and directly covers the second main surface 4 of the chip 2 in this embodiment. That is, the semiconductor device 1 is a high side switching device that is to be electrically interposed between a power supply and a load in this embodiment. The drain terminal 13 is electrically connected to the drain region 8 on the second main surface 4. The drain terminal 13 covers a whole region of the second main surface 4 so as to be continuous with a peripheral edge of the second main surface 4 (the first to fourth side surfaces 5A to 5D).

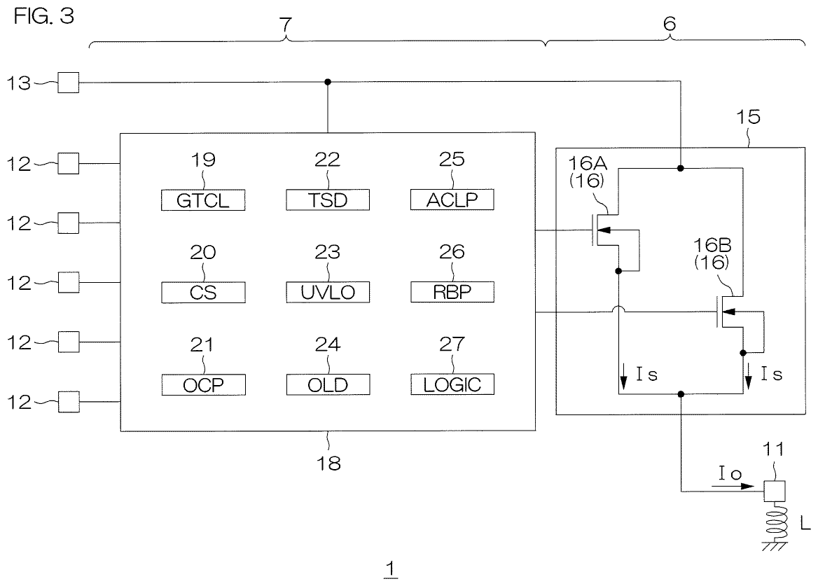

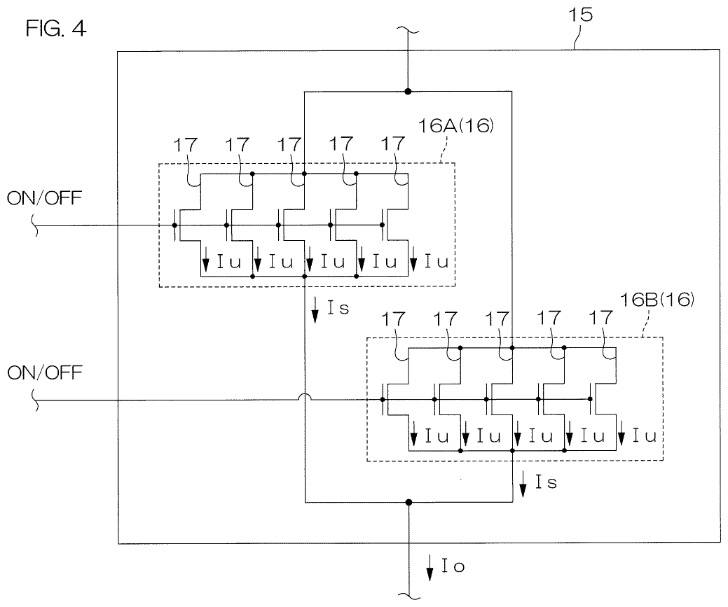

FIG. 3 is a schematic circuit diagram of an electrical configuration of the semiconductor device 1 shown FIG. 1. FIG. 4 is a schematic circuit diagram showing a configuration of an output transistor. In FIG. 3, an inductive load L that is electrically connected to the source terminal 11 is shown as an example of a load to show an operational example of the semiconductor device 1.

The inductive load L is not a component of the semiconductor device 1. Therefore, a configuration including the semiconductor device 1 and the inductive load L may be referred to as an “inductive load driving device” or an “inductive load control device.” A relay, a solenoid, a lamp, a motor, etc., are exemplified as the inductive load L. The inductive load L may be the inductive load L for an automobile use. In other words, the semiconductor device 1 may be the semiconductor device 1 for an automobile.

With reference to FIG. 3, the semiconductor device 1 includes an output transistor 15 that is formed in the output region 6. The output transistor 15 consists of a gate split transistor including a single main drain, a single main source, and a plurality of main gates in this embodiment. The main drain is electrically connected to the drain terminal 13. The main source is electrically connected to the source terminal 11.

The main gates are configured so that a plurality of electrically independent gate signals (gate potentials) are to be individually input. The output transistor 15 generates a single output current Io in response to the plurality of gate signals. That is, the output transistor 15 consists of a multi-input and single-output switching device. The output current Io is a drain-source current that flows between the main drain and the main source. The output current Io is to be output to the outside of the chip 2 (the inductive load L) via the source terminal 11.

The output transistor 15 includes a plurality (two or more) of system transistors 16 that are to be electrically and independently controlled. The plurality of system transistors 16 include a first system transistor 16A and a second system transistor 16B in this embodiment. The system transistors 16 are collectively formed in the output region 6. The system transistors 16 are connected in parallel so that the plurality of gate signals are to be independently input, and the system transistors 16 are configured so that the system transistor 16 in an on state and the system transistor 16 in an off state are to be coexisted.

The system transistors 16 each includes a system drain, a system source, and a system gate. A plurality of the system drains are electrically connected to the main drain (the drain terminal 13). A plurality of the system sources are electrically connected to the main source (the source terminal 11). Each of the system gates is electrically connected to each of the main gates. In other words, each of the system gates constitutes each of the main gates.

The system transistors 16 each generates a system current Is in response to the corresponding gate signal. Each system current Is is a drain-source current flowing between the system drain and the system source of each system transistor 16. The system currents Is may have different values or may have a substantially equal value. The plurality of system currents Is are added between the main drain and the main source. This generates the single output current Io consisting of a sum of the system currents Is.

With reference to FIG. 4, the plurality of system transistors 16 each includes a single or a plurality of unit transistors 17 that are (is) systematized (grouped) as an individual control target. Specifically, the system transistors 16 are each configured by a parallel circuit including the single unit transistor 17 or the plurality of unit transistors 17. The plurality of unit transistors 17 are each composed of the trench gate vertical type. The plurality of system transistors 16 may be configured by the same number of the unit transistors 17, or may be configured by different numbers of the unit transistors 17.

The plurality of unit transistors 17 each includes a unit drain, a unit source, and a unit gate. The unit drain of each unit transistor 17 is electrically connected to the system drain of the corresponding system transistor 16. The unit source of the unit drain of each unit transistor 17 is electrically connected to the system source of the corresponding system transistor 16. The unit gate of the unit drain of each unit transistor 17 is electrically connected to the system gate of the corresponding system transistor 16.

The plurality of unit transistors 17 each generates a unit current Iu in response to the corresponding gate signal. Each unit current Iu is a drain-source current flowing between the unit drain and the unit source of each unit transistor 17. The plurality of unit currents Iu may have different values or may have a substantially equal value. The plurality of unit currents Iu are added between the corresponding system drain and the corresponding system source. This generates the system current Is consisting of a sum of the plurality of unit currents Iu.

As described above, the output transistor 15 is configured so that the first system transistor 16A and the second system transistor 16B are controlled to be turned on and off while being electrically independent of each other. In other words, the output transistor 15 is configured so that both of the first system transistor 16A and the second system transistor 16B are to be simultaneously turned on. Also, the output transistor 15 is configured so that one of the first system transistor 16A and the second system transistor 16B is to be turned on and the other is to be turned off.

When both of the first system transistor 16A and the second system transistor 16B are simultaneously turned on, a channel utilization rate of the output transistor 15 increases, and accordingly an on-resistance decreases. When one of the first system transistor 16A and the second system transistor 16B is to be turned on while the other is to be turned off, the channel utilization rate of the output transistor 15 decreases, and accordingly the on-resistance increases. In other words, the output transistor 15 is a switching device of an on-resistance variable type.

The semiconductor device 1 includes a control circuit 18 that is formed in the control region 7 so as to be electrically connected to the output transistor 15. The control circuit 18 may be referred to as a “control IC.” The control circuit 18 has various functional circuits and constitutes an IPD (Intelligent Power Device) together with the output transistor 15. The IPD may be referred to as an IPM (Intelligent Power Module), an IPS (Intelligent Power Switch), a smart power driver, a smart MISFET (Smart MOSFET), or a protected MISFET (Protected MOSFET).

The control circuit 18 includes a gate control circuit 19, a current monitor circuit 20, an overcurrent protection circuit 21, an overheat protection circuit 22, a low voltage malfunction avoidance circuit 23, a load open detection circuit 24, an active clamp circuit 25, a power supply reverse connection protection circuit 26, and a logic circuit 27 in this embodiment. The control circuit 18 does not necessarily have to include all of those functional circuits at the same time, and it is sufficient if the control circuit 18 includes at least one of those functional circuits.

The current monitor circuit 20 may be referred to as a CS circuit (Current Sense Circuit). The overcurrent protection circuit 21 may be referred to as an OCP circuit (Over Current Protection Circuit). The overheat protection circuit 22 may be referred to as a TSD circuit (Thermal Shut Down Circuit). The low voltage malfunction avoidance circuit 23 may be referred to as a UVLO circuit (Under Voltage Lock Out Circuit). The load open detection circuit 24 may be referred to as an OLD circuit (Open Load Detection Circuit). The power supply reverse connection protection circuit 26 may be referred to as a RBP circuit (Reverse Battery Protection Circuit).

The gate control circuit 19 is configured to generate the gate signals that control the on/off of the output transistor 15. Specifically, the gate control circuit 19 generates the plurality of gate signals that individually control the on/off of the plurality of system transistors 16. That is, the gate control circuit 19 generates a first gate signal that individually controls the on/off of the first system transistor 16A, and a second gate signal that individually controls the on/off of the second system transistor 16B electrically independent of the first system transistor 16A in this embodiment.

The current monitor circuit 20 generates a monitor current that monitors the output current Io of the output transistor 15 and outputs it to another circuit. For example, the current monitor circuit 20 may include a transistor having a similar configuration to the output transistor 15 and may be configured to generate a monitor current linked to the output current Io by being controlled to be turned on/off simultaneously with the output transistor 15. As a matter of course, the current monitor circuit 20 may be configured to generate a monitor current linked to one or more of the system currents Is.

The overcurrent protection circuit 21 generates an electrical signal to control the gate control circuit 19 based on the monitor current from the current monitor circuit 20, and cooperates with the gate control circuit 19 and controls the on/off of the output transistor 15.

For example, the overcurrent protection circuit 21 may be configured to determine that the output transistor 15 is in an overcurrent state when the monitor current becomes not less than a predetermined threshold, and to cooperate with the gate control circuit 19 and control some of or all of the output transistor 15 (the plurality of system transistors 16) to the off state. The overcurrent protection circuit 21 may also be configured to cooperate with the gate control circuit 19 and transition the output transistor 15 to a normal operation when the monitor current becomes less than the predetermined threshold.

The overheat protection circuit 22 includes a first temperature sensing device (e.g., a temperature sensing diode) that detects a temperature of the output region 6, and a second temperature sensing device (e.g., a temperature sensing diode) that detects a temperature of the control region 7. The overheat protection circuit 22 generates an electrical signal that controls the gate control circuit 19 based on a first temperature detection signal from the first temperature sensing device and a second temperature detection signal from the second temperature sensing device, and cooperates with the gate control circuit 19 and controls the on/off of the output transistor 15.

For example, the overheat protection circuit 22 may be configured to determine that the output region 6 is in an overheated state when a differential value between the first temperature detection signal and the second temperature detection signal is not less than a predetermined threshold, and to cooperate with the gate control circuit 19 and control some of or all of the output transistor 15 (a plurality of the system transistors 16) to the off state. The overheat protection circuit 22 may also be configured to cooperate with the gate control circuit 19 and transition the output transistor 15 to the normal operation when the differential value becomes less than the predetermined threshold.

The low voltage malfunction avoidance circuit 23 is configured to prevent malfunctions of various functional circuits in the control circuit 18 when a start-up voltage for starting the control circuit 18 is less than a predetermined value. For example, the low voltage malfunction avoidance circuit 23 may be configured to start the control circuit 18 when the start-up voltage becomes not less than a predetermined threshold voltage, and to stop the control circuit 18 when the start-up voltage becomes less than said threshold voltage. The threshold voltage may have a hysteresis characteristic.

The load open detection circuit 24 determines an electrical connection state of the inductive load L. For example, the load open detection circuit 24 may be configured to monitor a terminal voltage of the output transistor 15 and determine that the inductive load L is in an open state when the terminal voltage becomes not less than a predetermined threshold. For example, the load open detection circuit 24 may be configured to determine that the inductive load L is in the open state when the monitor current becomes not more than the predetermined threshold.

The active clamp circuit 25 is electrically connected to the main drain of the output transistor 15 and at least one of the main gates (e.g., the system gate of the first system transistor 16A). The active clamp circuit 25 includes a Zener diode, and a pn-junction diode that is connected in series with the Zener diode in a reverse bias state. The pn-junction diode is a reverse current prevention diode that prevents a reverse current from the output transistor 15. The active clamp circuit 25 is configured to cooperate with the gate control circuit 19

and control some of or all of the output transistor 15 to the on state when a back electromotive force caused by the inductive load Lis applied to the output transistor 15. Specifically, the output transistor 15 is controlled in a multiple operation modes including a normal operation, a first off operation, an active clamp operation, and a second off operation.

In the normal operation, both of the first system transistor 16A and the second system transistor 16B are to be controlled to the on states simultaneously. This increases the channel utilization rate of the output transistor 15 and reduces the on-resistance. In the first off operation, both of the first system transistor 16A and the second system transistor 16B are to be controlled to change from the on states to the off states simultaneously. This causes the back electromotive force caused by the inductive load L to be applied to both of the first system transistor 16A and the second system transistor 16B.

The active clamp operation is an operation in which an energy stored in the inductive load L is to be absorbed (consumed) by the output transistor 15, and is executed when the back electromotive force caused by the inductive load L becomes not less than a predetermined threshold voltage. In the active clamp operation, the first system transistor 16A is to be controlled from the off state to the on state, and at the same time, the second system transistor 16B is to be controlled (maintained) in the off state.

The channel utilization rate of the output transistor 15 during the active clamp operation is less than the channel utilization rate of the output transistor 15 during the normal operation. The on-resistance of the output transistor 15 during the active clamp operation is greater than the on-resistance of the output transistor 15 during the normal operation. This suppresses a sudden increase in temperature of the output transistor 15 during the active clamp operation, and thus the active clamp withstand capability can be improved.

The second off operation is executed when the back electromotive force becomes less than the predetermined threshold voltage. In the second off operation, the first system transistor 16A is to be controlled from the on state to the off state, and at the same time, the second system transistor 16B is to be controlled (maintained) in the off state. In such a way, the back electromotive force (energy) of the inductive load L is absorbed by a part of the output transistor 15 (here, the first system transistor 16A). As a matter of course, during the active clamp operation, the first system transistor 16A may be controlled (maintained) in the off state, and at the same time, the second system transistor 16B may be controlled to the on state.

The power supply reverse connection protection circuit 26 is configured to detect a reverse voltage when the power supply is reversely connected and to protect the control circuit 18 and the output transistor 15 from the reverse voltage (reverse current). The logic circuit 27 is configured to generate electrical signals to be supplied to various circuits in the control circuit 18.

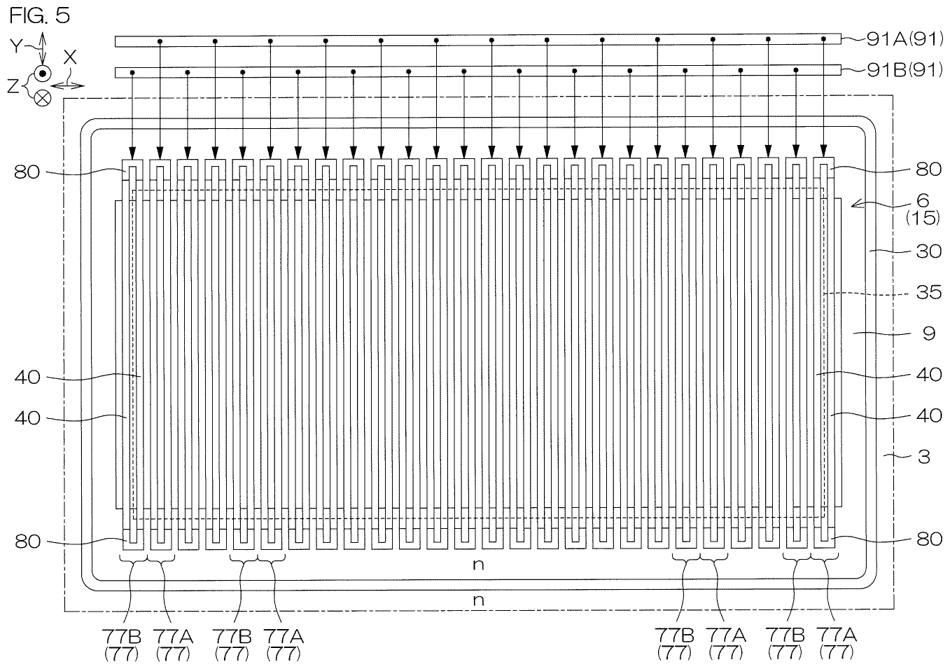

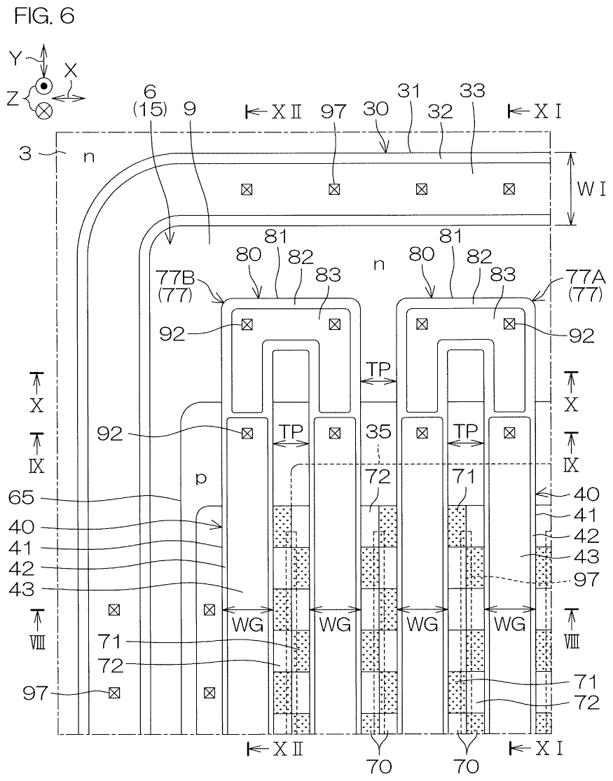

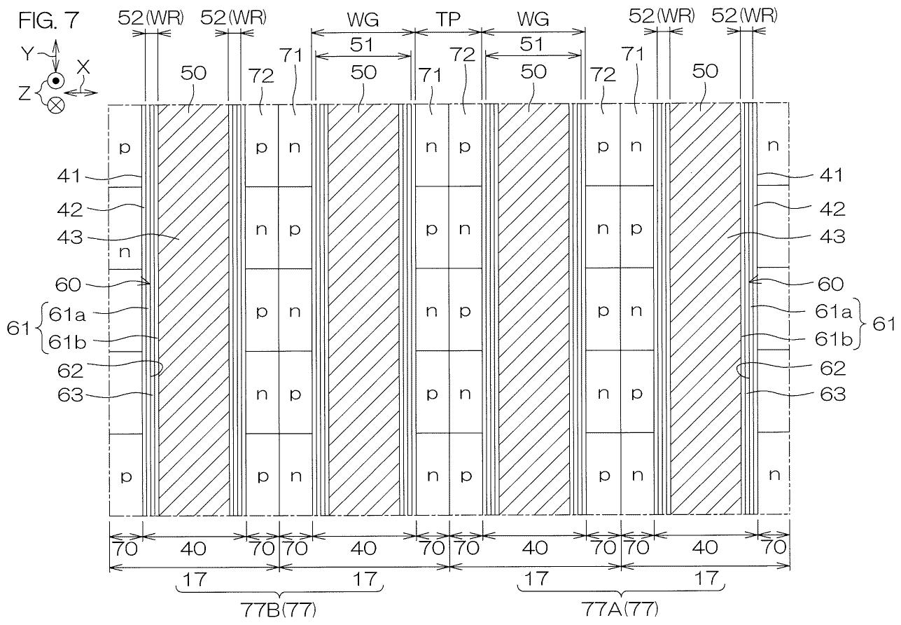

Hereinafter, with reference to FIG. 5 to FIG. 16, a configuration of the output region 6 shall be described. FIG. 5 is a plan view showing the output region 6. FIG. 6 is an enlarged plan view showing one principal part of the output region 6 shown in FIG. 5. FIG. 7 is an enlarged plan view showing a further principal part of the output region 6 shown in FIG. 5.

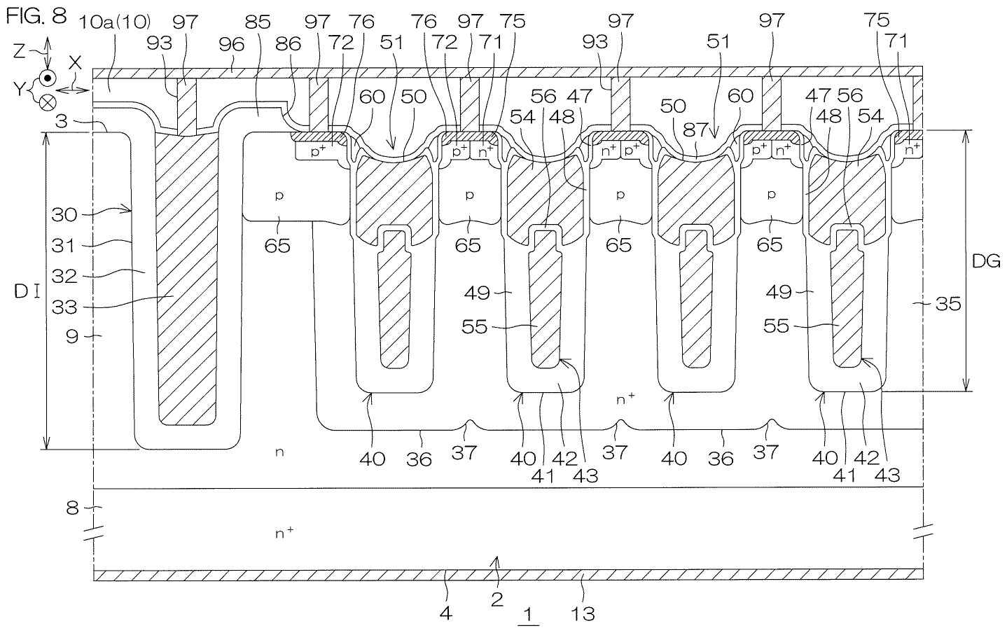

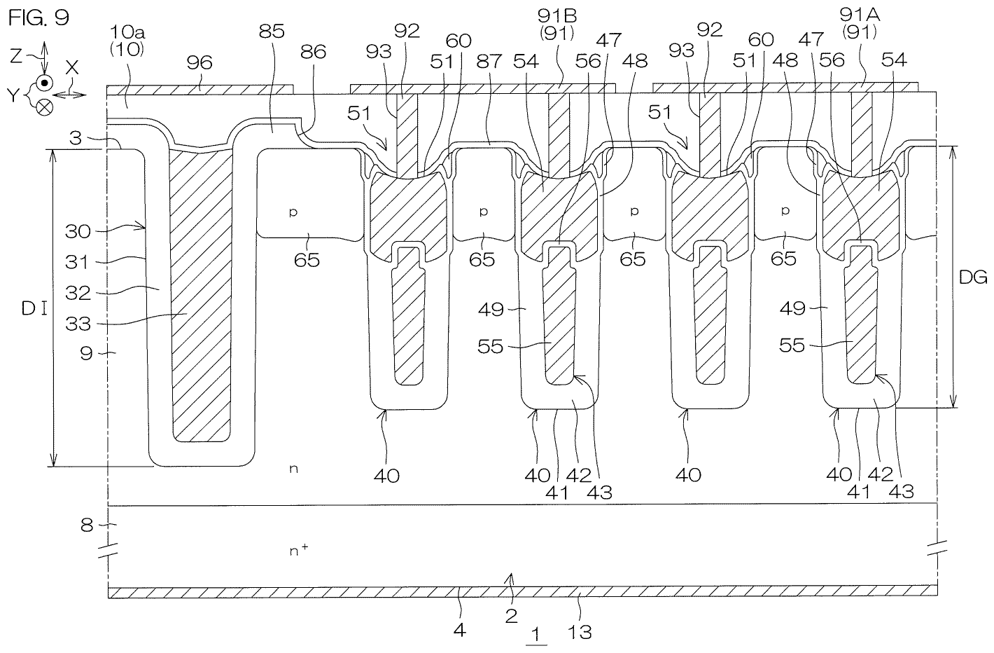

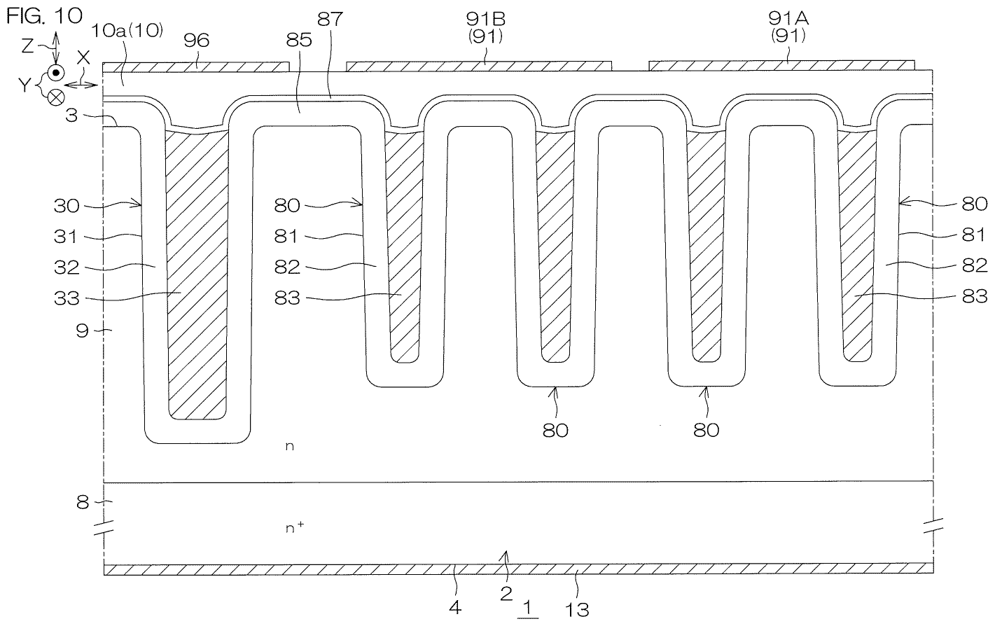

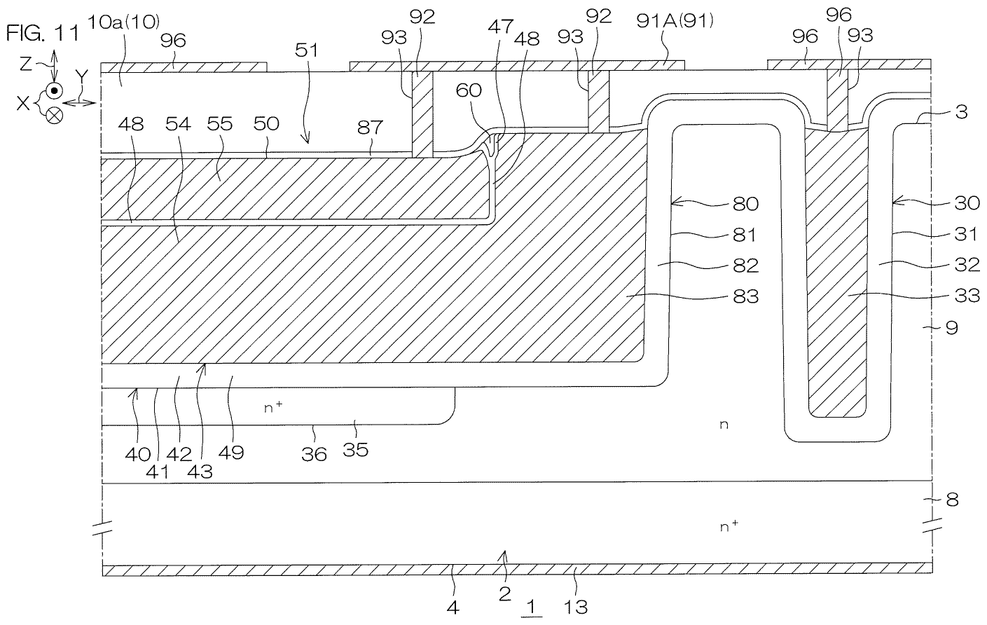

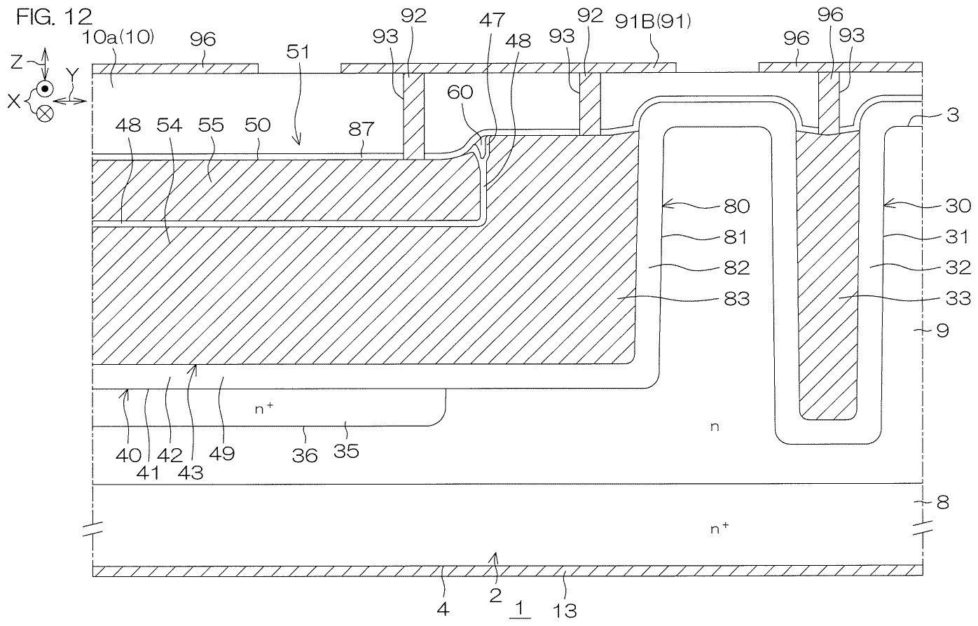

FIG. 8 is a cross sectional view taken along line VIII-VIII shown in FIG. 6. FIG. 9 is a cross sectional view taken along line IX-IX shown in FIG. 6. FIG. 10 is a cross sectional view taken along line X-X shown in FIG. 6. FIG. 11 is a cross sectional view taken along line XI-XI shown in FIG. 6. FIG. 12 is a cross sectional view taken along line XII-XII shown in FIG. 6.

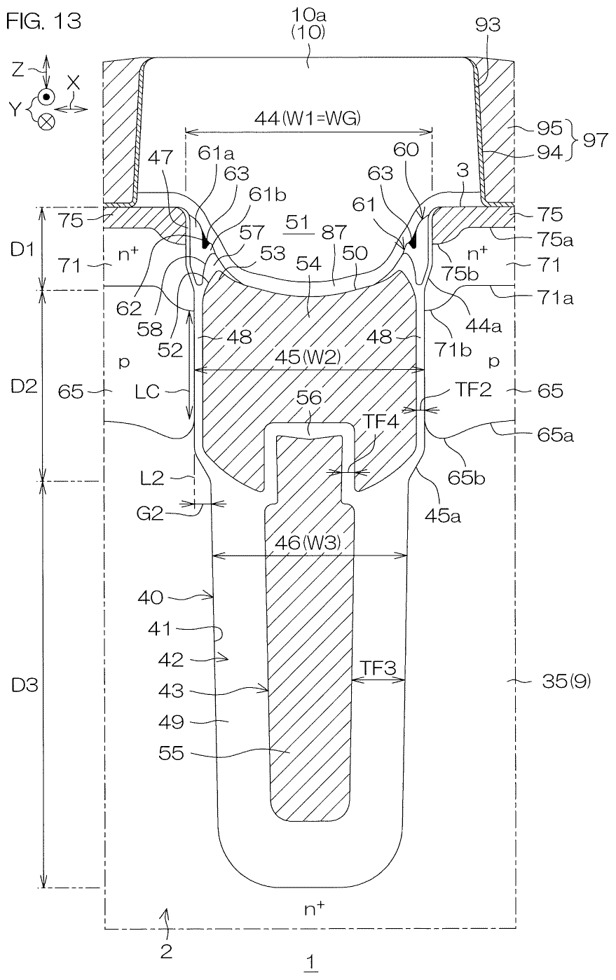

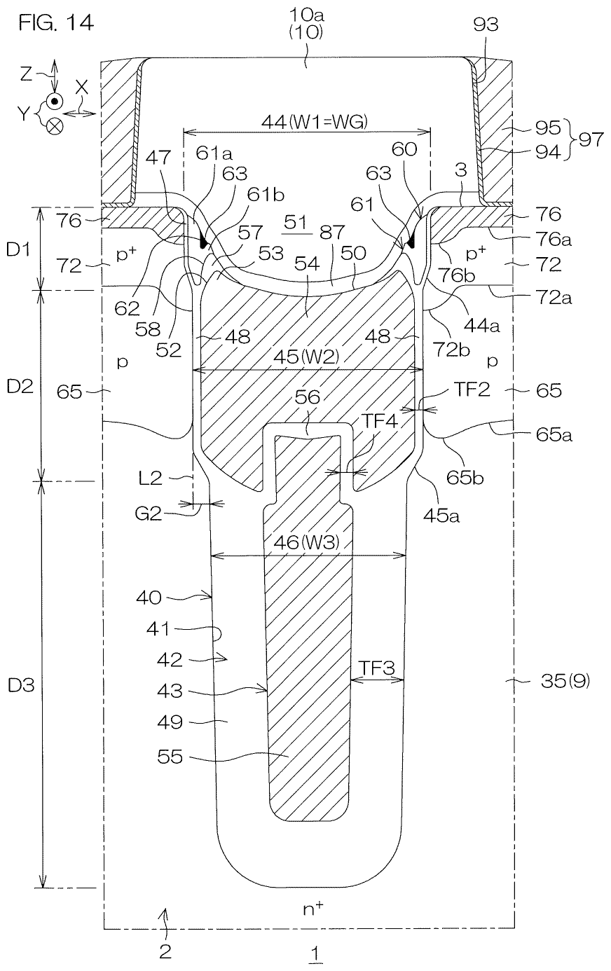

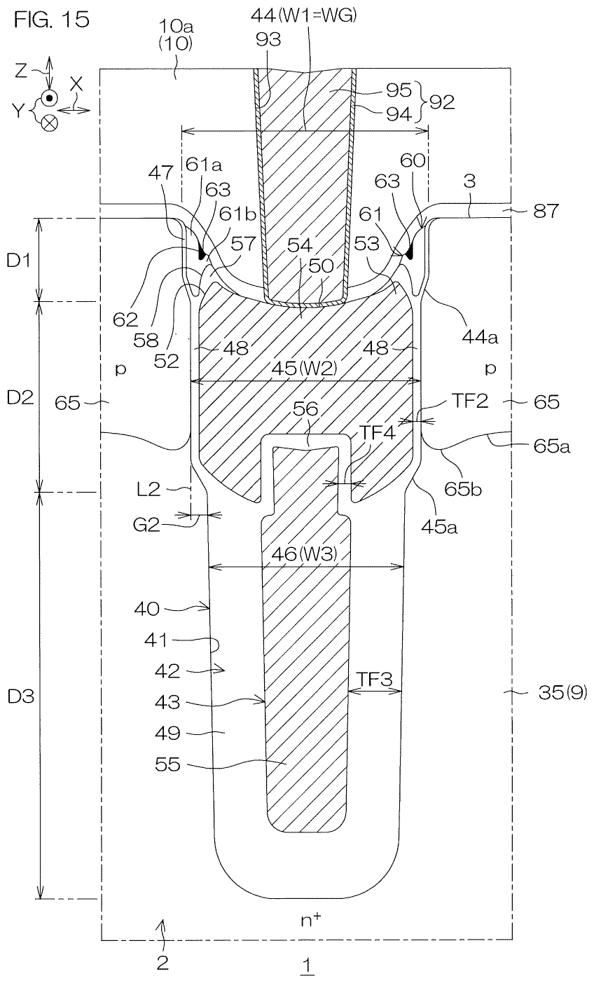

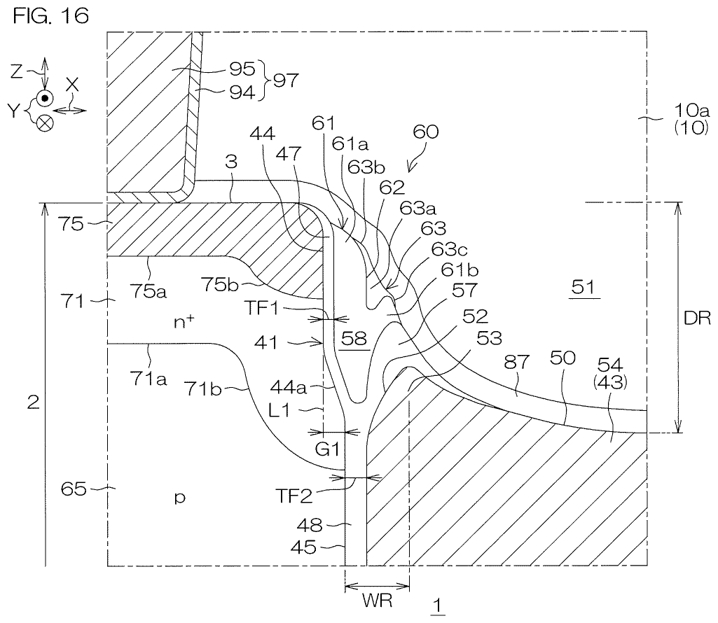

FIG. 13 is an enlarged cross sectional view showing one gate structure 40 (the trench structure) that is extracted with a source region 71 from the structure shown in FIG. 8. FIG. 14 is an enlarged cross sectional view showing one gate structure 40 (the trench structure) that is extracted with a contact region 72 from the structure shown in FIG. 8. FIG. 15 is an enlarged cross sectional view showing one gate structure 40 (the trench structure) that is extracted from the structure shown in FIG. 9. FIG. 16 is an enlarged cross sectional view showing a principal part of the gate structure 40 (the trench structure).

With reference to FIG. 5 and FIG. 6, the semiconductor device 1 includes a single or a plurality of (in this embodiment, single) separation structure 30 of a trench electrode type (a trench isolation type) that is formed in the first main surface 3 so as to demarcate the output region 6. The separation structure 30 may be referred to as a “trench separation structure,” a “region separation structure,” etc. The separation structure 30 electrically isolates the output region 6 from the control region 7 inside the chip 2. The source potential may be applied to the separation structure 30.

The separation structure 30 is formed in an annular shape surrounding the output region 6 in the plan view. The separation structure 30 is formed in a polygonal annular shape (a rectangular annular shape, in this embodiment) having four sides parallel to the peripheral edge of the first main surface 3 in the plan view. The separation structure 30 is formed at an interval from a bottom portion of the drift region 9 toward the first main surface 3 side, and faces the drain region 8 across a part of the drift region 9.

The separation structure 30 has a separation width WI and a separation depth DI. The separation width WI is a width in a direction perpendicular to an extending direction of the separation structure 30. The separation width WI may be not less than 0.4 μm and not more than 2.5 μm. The separation width WI may have a value falling within at least one of ranges of not less than 0.4 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm. The separation width WI is preferably not less than 1.25 μm and not more than 1.75 μm.

The separation depth DI may be not less than 1 μm and not more than 10 μm. The separation depth DI may have a value falling within at least one of ranges of not less than 1 μm and not more than 2 μm, not less than 2 μm and not more than 4 μm, not less than 4 μm and not more than 6 μm, not less than 6 μm and not more than 8 μm, and not less than 8 μm and not more than 10 μm. The separation depth DI is preferably not less than 3 μm and not more than 5 μm.

The separation structure 30 includes a separation trench 31, a separation insulating film 32 and a separation electrode 33. That is, the separation structure 30 has a single electrode structure including a single electrode (the separation electrode 33) embedded in the separation trench 31 across an insulator (the separation insulating film 32).

The separation trench 31 is formed in the first main surface 3 and defines a wall surface of the separation structure 30. The separation trench 31 may be formed in a tapered shape in which an opening width gradually narrows from an opening side toward a bottom wall side in a cross sectional view.

The separation insulating film 32 covers the wall surface of the separation trench 31. The separation insulating film 32 may include a silicon oxide film. The separation insulating film 32 may include a silicon oxide film made of an oxide of the chip 2, or may include a silicon oxide film (an oxide separated from the chip 2) formed by a CVD method. The separation insulating film 32 may have a thickness of not less than 100 nm and not more than 500 nm.

The separation electrode 33 is embedded in the separation trench 31 across the separation insulating film 32. The separation electrode 33 may include a conductive polysilicon of the n-type or the p-type. When the semiconductor device 1 includes a plurality of separation structures 30 (a multi-separation structure), the separation structures 30 are each formed in an annular shape surrounding the output region 6 at intervals from each other, and separate the single output region 6 from the control region 7. In this case, the separation structures 30 are preferentially formed at regular intervals.

With reference to FIG. 5 to FIG. 16, the semiconductor device 1 includes the output transistor 15 formed in the first main surface 3 at the output region 6. The following configurations are described as configurations of the semiconductor device 1, but are also configurations of the output transistor 15.

The semiconductor device 1 includes a high concentration drift region 35 of the n-type that is formed in a surface layer portion of the drift region 9 at the output region 6. The high concentration drift region 35 has an n-type impurity concentration higher than that of the drift region 9. The n-type impurity concentration of the high concentration drift region 35 may be less than the n-type impurity concentration of the drain region 8. The n-type impurity concentration of the high concentration drift region 35 may be not less than 1×10¹⁶ cm⁻³ and not more than 1×10¹⁹ cm⁻³. The high concentration drift region 35 may be considered as a part (high concentration portion) of the drift region 9.

The high concentration drift region 35 forms a concentration gradient in which the n-type impurity concentration increases from the bottom portion side of the drift region 9 toward the first main surface 3 side, in the drift region 9. That is, the drift region 9 in the output region 6 has a concentration gradient formed by the high concentration drift region 35 in which the n-type impurity concentration increases from the bottom portion side toward the first main surface 3 side.

The high concentration drift region 35 is formed in an inner portion of the output region 6 at an interval from the separation structure 30. Therefore, the high concentration drift region 35 is surrounded by the drift region 9 in the output region 6 and is not in contact with the separation structure 30. The high concentration drift region 35 locally increases the n-type impurity concentration of the drift region 9 in the output region 6.

The high concentration drift region 35 is formed at an interval from the bottom portion of the drift region 9 toward the first main surface 3 side, and faces the drain region 8 across a part of the drift region 9. The high concentration drift region 35 has a bottom portion located on the bottom portion side of the drift region 9 with respect to the bottom wall of the separation structure 30. The bottom portion of the high concentration drift region 35 meanders on one side and another side in the thickness direction in the cross sectional view.

Specifically, the bottom portion of the high concentration drift region 35 has a plurality of bulging portions 36 and a plurality of recessed portions 37 in a cross sectional view.

The bulging portions 36 are portions that are each bulged in an arc shape toward the bottom portion side of the drift region 9. The bulging portions 36 are formed continuously in the first direction X in a plan view, and each formed in a band shape extending in the second direction Y. Each of the bulging portions 36 is formed wider than the separation structure 30 in the first direction X.

The recessed portions 37 are each formed in a band shape extending in the second direction Y in regions between the bulging portions 36. The recessed portions 37 are portions where shallow portions of the bulging portions 36 are connected to each other, and are located on the first main surface 3 side with respect to deepest portions of the bulging portions 36. As a matter of course, the high concentration drift region 35 may have a flat bottom portion that does not meander up and down in the thickness direction.

The high concentration drift region 35 may increase the concentration across the entire drift region 9 within the output region 6. With this configuration, an on-resistance of the drift region 9 can be reduced by increasing the concentration of the drift region 9. However, in this case, it should be noted that there is a possibility in which a breakdown voltage may decrease as a result of electric field concentration being more likely to occur due to an increase in carrier density in the drift region 9. Therefore, in order to reduce the on-resistance while suppressing the decrease in the breakdown voltage, it is preferable to introduce the high concentration drift region 35 into a part of the output region 6.

The semiconductor device 1 includes a plurality of gate structures 40 of a trench electrode type that is formed in the first main surface 3 at the output region 6. The gate structure 40 may be referred to as a “trench structure,” a “trench gate structure,” etc. The plurality of gate structures 40 are formed in an inner portion of the output region 6 at intervals from the separation structure 30.

The gate structures 40 are arranged at intervals in the first direction X, and are each formed in a band shape extending in the second direction Y. That is, the gate structures 40 are arranged in a strip shape extending in the second direction Y. The gate structures 40 each has a first end portion on one side in a longitudinal direction (the second direction Y) and a second end portion on another side in the longitudinal direction (the second direction Y).

The first end portion is located in a region between the separation structure 30 and one end portion of the high concentration drift region 35 in the plan view. The second end portion is located in a region between the separation structure 30 and another end portion of the high concentration drift region 35 in the plan view. That is, the gate structures 40 cross one end portion and another end portion of the high concentration drift region 35 in the longitudinal direction (the second direction Y).

The gate structures 40 are formed at intervals from the bottom portion of the drift region 9 toward the first main surface 3 side and face the drain region 8 across a part of the drift region 9 in the cross sectional view. Specifically, the gate structures 40 are formed at intervals from the bottom portion of the high concentration drift region 35 toward the first main surface 3 side and face the drift region 9 across a part of the high concentration drift region 35.

That is, the gate structures 40 are located within the high concentration drift region 35 in the cross sectional view. The gate structures 40 are each formed offset in the first direction X with respect to the recessed portions 37, and face the bulging portions 36 in the thickness direction. The gate structures 40 preferably face the deepest portions of the bulging portions 36.

The two gate structures 40 that are located on both sides of the first direction X are preferably formed in regions outside the high concentration drift region 35. That is, the outermost gate structures 40 are preferably located within the drift region 9 at positions spaced from the high concentration drift region 35 toward the separation structure 30 side. The outermost gate structures 40 are formed at intervals from the bottom portion of the drift region 9 toward the first main surface 3 side, and face the drain region 8 across a part of the drift region 9.

The gate structure 40 has a gate width WG (trench width) and a gate depth DG (trench depth). The gate width WG is a width in a direction perpendicular to an extending direction (that is the first direction X) of the gate structure 40. The gate width WG may be substantially equal to the separation width WI. The gate width WG is preferably not more than the separation width WI. The gate width WG is particularly preferably less than the separation width WI.

The gate width WG may be not less than 0.4 μm and not more than 2 μm. The gate width WG may have a value falling within at least one of ranges of not less than 0.4 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm. The gate width WG is preferably not less than 0.8 μm and not more than 1.2 μm.

The gate depth DG may be substantially equal to the separation depth DI. The gate depth DG is preferably not more than the separation depth DI. The gate depth DG is particularly preferably less than the separation depth DI. The gate depth DG may be not less than 1 μm and not more than 6 μm. The gate depth DG may have a value falling within at least one of ranges of not less than 1 μm and not more than 2 μm, not less than 2 μm and not more than 3 μm, not less than 3 um and not more than 4 μm, not less than 4 μm not more than 5 μm, and not less than 5 μm and not more than 6 μm. The gate depth DG is preferably not less than 2.5 μm and not more than 4.5 μm.

The gate structures 40 are arranged in the first direction X at a predetermined trench pitch TP. The trench pitch TP is also a mesa width of a mesa portion that is demarcated in a region between two adjacent gate structures 40. The trench pitch TP is preferably not more than the separation width WI. The trench pitch TP is preferably not more than the gate width WG. The trench pitch TP is particularly preferably less than the gate width WG.

The trench pitch TP may be not less than 0.4 μm and not more than 0.8 μm. The trench pitch TP may have a value falling within at least one of ranges of not less than 0.4 μm and not more than 0.5 μm, not less than 0.5 μm and not more than 0.6 μm, not less than 0.6 μm and not more than 0.7 μm, and not less than 0.7 μm and not more than 0.8 μm. The trench pitch TP is preferably not less than 0.5 μm and not more than 0.7 μm.

Hereinafter, with reference to FIG. 13 to FIG. 16, an internal configuration of the single gate structures 40 shall be described. The gate structure 40 includes a trench 41, an insulating film 42 and an embedded electrode 43. The trench 41 is formed in the first main surface 3 and defines the wall surface of the gate structure 40. The trench 41 is formed in a tapered shape (a dwindling shape) in which an opening width gradually narrows from an opening side toward a bottom wall side in the cross sectional view. Specifically, the trench 41 has a first trench portion 44, a second trench portion 45 and a third trench portion 46, which are formed in that order from the opening side toward the bottom wall side in the cross sectional view.

The first trench portion 44 is formed relatively wide in the surface layer portion of the first main surface 3, and defines an uppermost end (an opening end portion) of the trench 41. The first trench portion 44 has an upper end portion on the first main surface 3 side, and a lower end portion on the bottom wall side of the trench 41. The upper end portion of the first trench portion 44 defines the opening end portion extending in an arc shape, and is connected to the first main surface 3. The lower end portion of the first trench portion 44 defines a first inclined portion 44a that slopes obliquely downward inwardly of the trench 41.

With reference to FIG. 13 to FIG. 16, the first trench portion 44 has a relatively wide first width W1 and a relatively shallow first depth D1. The first width W1 defines the gate width WG. The first depth D1 is a depth between the upper end portion and lower end portion of the first trench portion 44.

The first depth D1 may be not less than 0.1 μm and not more than 1 μm. The first depth D1 may have a value falling within at least one of ranges of not less than 0.1 μm and not more than 0.25 μm, not less than 0.25 μm and not more than 0.5 μm, not less than 0.5 μm and not more than 0.75 μm, and not less than 0.75 μm and not more than 1 μm. The first depth D1 is preferably not less than 0.1 μm and not more than 0.5 μm.

The second trench portion 45 is formed narrower than the first trench portion 44 in a region below the first trench portion 44, and defines a middle portion of the trench 41. The second trench portion 45 has an upper end portion on the first trench portion 44 side, and a lower end portion on the bottom wall side of the trench 41. The upper end portion of the second trench portion 45 is connected to the lower end portion (the first inclined portion 44a) of the first trench portion 44. The lower end portion of the second trench portion 45 defines a second inclined portion 45a that slopes obliquely downward inwardly of the trench 41. The second inclined portion 45a is located on an inner side of the trench 41 with respect to the first inclined portion 44a.

The second trench portion 45 has a second width W2 less than the first width W1, and a second depth D2 greater than the first depth D1. A first gap amount G1 between a wall surface of the first trench portion 44 and a wall surface of the second trench portion 45 may be not less than 1 nm and not more than 50 nm (see FIG. 16).

The first gap amount G1 is a distance in a horizontal direction from a first virtual line L1 that passes through the wall surface of the first trench portion 44 in the normal direction Z to the wall surface of the second trench portion 45 in the cross sectional view. The horizontal direction is a direction along the first main surface 3 (here, the first direction X). The first gap amount G1 is also a value obtained by halving a differential value of the second width W2 with respect to the first width W1.

The first gap amount G1 may have a value falling within at least one of ranges of not less than 1 nm and not more than 5 nm, not less than 5 nm and not more than 10 nm, not less than 10 nm and not more than 20 nm, not less than 20 nm and not more than 30 nm, not less than 30 nm and not more than 40 nm, and not less than 40 nm and not more than 50 nm. The first gap amount G1 is preferably not less than 5 nm. The first gap amount G1 is preferably not more than 25 nm.

The second depth D2 is a depth between the upper end portion and the lower end portion of the second trench portion 45. The second depth D2 may be not less than 0.5 μm and not more than 2 μm. The second depth D2 may have a value falling within at least one of ranges of not less than 0.5 μm and not more than 0.75 μm, not less than 0.75 μm and not more than 1 μm, not less than 1 μm and not more than 1.25 μm, not less than 1.25 μm and not more than 1.5 μm, not less than 1.5 μm and not more than 1.75 μm, and not less than 1.75 μm and not more than 2 μm. The second depth D2 is preferably not less than 0.5 μm and not more than 1.5 μm.

The third trench portion 46 is formed narrower than the second trench portion 45 in a region below the second trench portion 45, and defines a lower end portion of the trench 41. The third trench portion 46 has an upper end portion on the second trench portion 45 side and a lower end portion on the second main surface 4 side. The upper end portion of the third trench portion 46 is connected to the lower end portion (the second inclined portion 45a) of the second trench portion 45. The lower end portion of the third trench portion 46 defines the bottom wall of the trench 41.

The third trench portion 46 has a third width W3 less than the second width W2 and a third depth D3 greater than the second depth D2. The second gap amount G2 between the wall surface of the second trench portion 45 and a wall surface of the third trench portion 46 may be not less than 1 nm and not more than 50 nm (see FIG. 13 and FIG. 15).

The second gap amount G2 is a distance in a horizontal direction from a second virtual line L2 that passes through the wall surface of the second trench portion 45 in the normal direction Z to the wall surface of the third trench portion 46 in the cross sectional view. The second gap amount G2 is also a value obtained by halving a differential value of the third width W3 with respect to the second width W2.

The second gap amount G2 may have a value falling within at least one of ranges of not less than 1 nm and not more than 5 nm, not less than 5 nm and not more than 10 nm, not less than 10 nm and not more than 20 nm, not less than 20 nm and not more than 30 nm, not less than 30 nm and not more than 40 nm, and not less than 40 nm and not more than 50 nm. The second gap amount G2 is preferably not less than 5 nm. The second gap amount G2 is preferably not more than 25 nm.

The third depth D3 is a depth between the upper end portion and the lower end portion of the third trench portion 46. The third depth D3 is a value obtained by subtracting a sum value of the first depth D1 and the second depth D2 from the gate depth DG of the trench 41. The third depth D3 is preferably not less than the second depth D2. The third depth D3 is particularly preferably not less than 1.5 times and not more than 4 times of the second depth D2.

The third depth D3 may be not less than 0.5 μm and not more than 5 μm. The third depth D3 may have a value falling within at least one of ranges of not less than 0.5 μm and not more than 1.5 μm, not less than 1.5 μm and not more than 2 μm, not less than 2 μm and not more than 2.5 μm, not less than 2.5 μm and not more than 3 μm, not less than 3 μm and not more than 3.5 μm, not less than 3.5 μm and not more than 4 μm, not less than 4 μm and not more than 4.5 μm, and not less than 4.5 μm and not more than 5 μm. The third depth D3 may be not less than 1.5 μm and not more than 3 μm.

The insulating film 42 covers the wall surface of the trench 41 in a film shape. Specifically, the insulating film 42 covers the wall surface of the first trench portion 44, the wall surface of the second trench portion 45, and the wall surface of the third trench portion 46 in a film shape. More specifically, the insulating film 42 includes a first insulating film 47, a second insulating film 48 and a third insulating film 49.

The first insulating film 47 has a relatively small first film thickness TF1 and covers the wall surface of the first trench portion 44. Specifically, the first insulating film 47 covers a region between the upper end portion and the lower end portion of the wall surface of the first trench portion 44 in a film shape. The first insulating film 47 has a portion that covers the first inclined portion 44a of the first trench portion 44. The first insulating film 47 may include a silicon oxide film. The first insulating film 47 preferably includes a silicon oxide film made of an oxide of the chip 2.

The first film thickness TF1 preferably has a value of not more than the first gap amount G1. The first film thickness TF1 may be not less than 1 nm and not more than 50 nm (see FIG. 16). The first film thickness TF1 may have a value falling within at least one of ranges of not less than 1 nm and not more than 5 nm, not less than 5 nm and not more than 10 nm, not less than 10 nm and not more than 20 nm, not less than 20 nm and not more than 30 nm, not less than 30 nm and not more than 40 nm, and not less than 40 nm and not more than 50 nm. The first film thickness TF1 is preferably not less than 5 nm. The first film thickness TF1 is preferably not more than 25 nm.

The second insulating film 48 has a second film thickness TF2 not less than the first film thickness TF1 and covers the wall surface of the second trench portion 45 in a film shape. Specifically, the second insulating film 48 covers a region between the upper end portion and the lower end portion of the wall surface of the second trench portion 45 in a film shape. The second insulating film 48 is connected to the first insulating film 47 at the upper end portion of the second trench portion 45 and has a portion that covers the second inclined portion 45a of the second trench portion 45.

The second insulating film 48 may include a silicon oxide film. The second insulating film 48 preferably includes a silicon oxide film made of an oxide of the chip 2. The second film thickness TF2 is preferably greater than the first film thickness TF1. The second film thickness TF2 is particularly preferably greater than the first gap amount G1. As a matter of course, the second film thickness TF2 may be less than the first film thickness TF1 (the first gap amount G1).

The second film thickness TF2 may be not less than 10 nm and not more than 100 nm (see FIG. 16). The second film thickness TF2 may have a value falling within at least one of ranges of not less than 10 nm and not more than 25 nm, not less than 25 nm and not more than 50 nm, not less than 50 nm and not more than 75 nm, and not less than 75 nm and not more than 100 nm. The second film thickness TF2 is preferably not more than 50 nm. The second film thickness TF2 is preferably not more than 25 nm.

The third insulating film 49 has a third film thickness TF3 not less than the second film thickness TF2 and covers the wall surface of the third trench portion 46 in a film shape. Specifically, the third insulating film 49 covers a region between the upper end portion and the lower end portion of the wall surface of the third trench portion 46 in a film shape, and is connected to the second insulating film 48 at the upper end portion of the third trench portion 46.

The third insulating film 49 defines a recess space having a U-shape in the cross sectional view within the third trench portion 46 (the region on the bottom wall side of the trench 41). The third insulating film 49 may include a silicon oxide film. The third insulating film 49 may include a silicon oxide film made of the an oxide of the chip 2, or may include a silicon oxide film (an oxide separated from the chip 2) formed by a CVD method.

The third film thickness TF3 is preferably greater than the second film thickness TF2. The third film thickness TF3 is particularly preferably greater than the second gap amount G2. The third film thickness TF3 may be not less than 100 nm and not more than 500 nm. The third film thickness TF3 may have a value falling within at least one of ranges of not less than 100 nm and not more than 200 nm, not less than 200 nm and not more than 300 nm, not less than 300 nm and not more than 400 nm, and not less than 400 nm and not more than 500 nm. The third film thickness TF3 is preferably not less than 200 nm. The third film thickness TF3 may be substantially equal to the thickness of the separation insulating film 32.

The embedded electrode 43 is embedded in the trench 41 across the insulating film 42. The embedded electrode 43 may include a conductive polysilicon of the n-type or the p-type. The embedded electrode 43 has an electrode surface 50 exposed from the trench 41. The electrode surface 50 is formed by a portion of the conductive polysilicon in this embodiment.

The electrode surface 50 is located on the bottom wall side of the trench 41 with respect to the first main surface 3, and defines an opening recess 51 with the side walls of the trench 41 on the opening side of the trench 41. The opening recess 51 extends in a band shape along the trench 41. The opening recess 51 may be formed a substantially whole region of the trench 41. The opening recess 51 has a recess depth DR. The recess depth DR is a maximum distance between the first main surface 3 and the electrode surface 50 based on a height position of the first main surface 3.

The recess depth DR may be not less than 100 nm and not more than 600 nm. The recess depth DR may have a value falling within at least one of ranges of not less than 100 nm and not more than 150 nm, not less than 150 nm and not more than 200 nm, not less than 200 nm and not more than 250 nm, not less than 250 nm and not more than 300 nm, not less than 300 nm and not more than 350 nm, not less than 350 nm and not more than 400 nm, not less than 400 nm and not more than 450 nm, not less than 450 nm and not more than 500 nm, not less than 500 nm and not more than 550 nm, and not less than 550 nm and not more than 600 nm. The recess depth DR is preferably not less than 200 nm and not more than 400 nm.

The embedded electrode 43 is embedded in a region on the second trench portion 45 side with respect to an intermediate portion in a depth range of the first trench portion 44, and exposes at least a part of the first trench portion 44. That is, the embedded electrode 43 is embedded in the trench 41 across the insulating film 42 (the second insulating film 48) so as to expose at least a part of the first insulating film 47.

The embedded electrode 43 is embedded in a region on the second trench portion 45 side with respect to the lower end portion of the first trench portion 44, and exposes a substantially whole region of the first trench portion 44 in this embodiment. That is, the embedded electrode 43 exposes at least a part (in this embodiment, the entirety) of a portion of the first insulating film 47 that covers the first inclined portion 44a of the first trench portion 44.

The embedded electrode 43 has a recess edge portion 52 recessed toward the bottom wall of the trench 41 at an edge portion along the side wall of the trench 41 in the electrode surface 50. In this embodiment, a plurality of the recess edge portions 52 are formed in the edge portions on both sides of the electrode surface 50 in the cross sectional view. Since the recess edge portions 52 on both sides have a similar configuration, a configuration of one of the recess edge portions 52 shall be described hereinafter. The descriptions of the recess edge portion 52 of one side are applied to the descriptions of the recess edge portion 52 of the other side.

The recess edge portion 52 is defined in a region between the side wall of the trench 41 (specifically, the wall surface of the first trench portion 44) and the upper end portion of the embedded electrode 43 on the opening side of the trench 41. The recess edge portion 52 extends along the side wall of the trench 41 (the wall surface of the first trench portion 44) in the plan view, and is formed in a tapered shape (a dwindling shape) toward the bottom wall of the trench 41 from the electrode surface 50 in the cross sectional view.

An opening end portion of the recess edge portion 52 is formed at a depth position (height position) facing the wall surface of the first trench portion 44 in the horizontal direction. On the other hand, the bottom wall portion of the recess edge portion 52 is formed at a depth position (height position) facing the wall surface of the second trench portion 45 in the horizontal direction. That is, the opening end portion of the recess edge portion 52 faces the first insulating film 47 in the horizontal direction, and the bottom wall portion of the recess edge portion 52 faces the second insulating film 48 in the horizontal direction. The bottom wall portion of the recess edge portion 52 is located on the bottom wall side of the trench 41 with respect to a height position of an inner portion of the electrode surface 50 in this embodiment.

the recess edge portion 52 has a recess width WR in regard to the horizontal direction. The recess width WR may be not less than 10 nm and not more than 200 nm. The recess width WR may have a value falling within at least one of ranges of not less than 10 nm and not more than 25 nm, not less than 25 nm and not more than 50 nm, not less than 50 nm and not more than 75 nm, not less than 75 nm and not more than 100 nm, not less than 100 nm and not more than 125 nm, not less than 125 nm and not more than 150 nm, not less than 150 nm and not more than 175 nm, and not less than 175 nm and not more than 200 nm. The recess width WR is preferably not less than 50 nm and not more than 150 nm.

The embedded electrode 43 has a protruding edge portion 53 that protrudes toward the opening side of the trench 41 at the edge portion of the electrode surface 50. In this embodiment, a plurality of the protruding edge portions 53 are formed on the edge portions on both sides of the electrode surface 50 in the cross sectional view. The protruding edge portion 53 is formed at an interval from the side wall of the trench 41 (specifically, the wall surface of the first trench portion 44) in the horizontal direction, and defines the recess edge portion 52 with the side wall of the trench 41.

The protruding edge portion 53 is formed in a tapered shape toward the opening side of the trench 41, and have a tip portion that is located on the first main surface 3 side with respect to the inner portion of the electrode surface 50. The tip portion of the protruding edge portion 53 is formed on the bottom wall side of the trench 41 with respect to the height position of the first main surface 3. The protruding edge portion 53 forms the electrode surface 50 that is curved in an arc shape toward the bottom wall.

The embedded electrode 43 has a multi electrode structure including a plurality of electrodes arranged at intervals/an interval in the depth direction of the trench 41 with an insulator in this embodiment. An uppermost electrode of the embedded electrode 43 (a first electrode 54 described below) has the electrode surface 50, the recess edge portion 52, and the protruding edge portion 53 that are described above. The embedded electrode 43 has a double electrode structure including a first electrode 54, a second electrode 55, and an intermediate insulating film 56 arranged separately in a vertical direction in this embodiment.

The first electrode 54 may includes a conductive polysilicon of the n-type or the p-type. The first electrode 54 is embedded in the opening side of the trench 41 across the insulating film 42. Specifically, the first electrode 54 is embedded in the second trench portion 45 across the second insulating film 48. The first electrode 54 is embedded in a region on the second trench portion 45 side with respect to the intermediate portion in the depth range of the first trench portion 44, and exposes at least a part of the first trench portion 44.

The first electrode 54 is embedded in a region on the second trench portion 45 side with respect to the lower end portion of the first trench portion 44 in this embodiment. The first electrode 54 covers a region between the upper end portion and the lower end portion of the second insulating film 48, and exposes a substantially whole region of the first trench portion 44. That is, the first electrode 54 exposes a portion of the first insulating film 47 that covers the first inclined portion 44a of the first trench portion 44. Also, the first electrode 54 has a portion that covers the second inclined portion 45a across the second insulating film 48.

The second electrode 55 may include a conductive polysilicon of the n-type or the p-type. The second electrode 55 is embedded in the bottom wall side of the trench 41 across the insulating film 42. Specifically, the second electrode 55 is embedded in the third trench portion 46 across the third insulating film 49. The second electrode 55 is formed in a wall shape extending in the depth direction of the trench 41.

The second electrode 55 has an upper end portion that protrudes upward with respect to the upper end portion of the third insulating film 49. The upper end portion of the second electrode 55 bites into the lower end portion of the first electrode 54, and engages with the lower end portion of the first electrode 54. The upper end portion of the second electrode 55 faces the second insulating film 48 across the lower end portion of the first electrode 54 in the horizontal direction.

The intermediate insulating film 56 is interposed between the first electrode 54 and the second electrode 55, and electrically insulates the first electrode 54 and the second electrode 55 inside the trench 41. The intermediate insulating film 56 is continuous with the insulating film 42 (the second insulating film 48 and the third insulating film 49). The intermediate insulating film 56 may include a silicon oxide film. The intermediate insulating film 56 preferably includes a silicon oxide film made of an oxide of the second electrode 55. That is, the intermediate insulating film 56 preferably includes an oxide of polysilicon.

The intermediate insulating film 56 has a fourth thickness TF4. The fourth thickness TF4 is greater than the first film thickness TF1 and less than the third film thickness TF3. The fourth thickness TF4 is preferably greater than the second film thickness TF2. As a matter of course, the fourth thickness TF4 may be less than the second film thickness TF2.

In this embodiment, the embedded electrode 43 that has the double electrode structure is shown. As a matter of course, the embedded electrode 43 may have three or more electrodes arranged separately in the vertical direction. In this case, the intermediate insulating films 56 are arranged in regions between two adjacent electrodes in the vertical direction, respectively.

The semiconductor device 1 includes a recess insulating film 57 that covers a portion of the electrode surface 50 that demarcates the recess edge portion 52. The recess insulating film 57 may be regarded as one component of the gate structure 40. The recess insulating film 57 may include a silicon oxide film made of an oxide of the embedded electrode 43. That is, the recess insulating film 57 may include an oxide of polysilicon. The recess insulating film 57 may include a silicon oxide film formed by a CVD method. That is, the recess insulating film 57 may include an oxide separated from the embedded electrode 43.

The recess insulating film 57 is formed in a film shape along a wall surface of the recess edge portion 52 that conforms to the recess edge portion 52, and has a film surface positioned below (on the electrode surface 50 side with respect to) the first main surface 3. The recess insulating film 57 is connected to at least the first insulating film 47 of the insulating film 42. The recess insulating film 57 is also connected to the second insulating film 48 in this embodiment.

The recess insulating film 57 continuously covers a wall surface of the protruding edge portion 53 from the wall surface of the recess edge portion 52 in this embodiment. The recess insulating film 57 has a thickness that gradually increases from the recess edge portion 52 to the protruding edge portion 53. The recess insulating film 57 may have a portion that extends from the protruding edge portion 53 toward the inner portion of the electrode surface 50. In this case, it is preferred that the thickness of the recess insulating film 57 gradually decreases from the protruding edge portion 53 toward the inner portion of the electrode surface 50.

That is, a film thickness of a portion of the recess insulating film 57 that covers the protruding edge portion 53 is greater than a film thickness of a portion of the recess insulating film 57 that covers the recess edge portion 52. Also, the film thickness of the portion of the recess insulating film 57 that covers the protruding edge portion 53 is greater than a film thickness of a portion of the recess insulating film 57 that covers a region on the inner portion the electrode surface 50. The recess insulating film 57 does not necessarily have to be terminated at the peripheral edge portion of the electrode surface 50 in the cross sectional view, and may cover a whole region of the electrode surface 50 in the cross sectional view.

The recess insulating film 57 demarcates an insulating recess edge portion 58 that conforms to the recess edge portion 52 between the wall surface of the trench 41 and the recess insulating film 57 in this embodiment. Specifically, the recess insulating film 57 is formed at an interval from the insulating film 42 in the horizontal direction, and defines the insulating recess edge portion 58 between the insulating film 42 and the recess insulating film 57. More specifically, the recess insulating film 57 is formed at an interval from the first insulating film 47 in the horizontal direction, and defines the insulating recess edge portion 58 with the first insulating film 47. A thickness of a portion of the recess insulating film 57 that covers the protruding edge portion 53 is greater than the thickness (the first film thickness TF1) of the first insulating film 47.

The insulating recess edge portion 58, as with the recess edge portion 52, extends along the side wall of the trench 41 (the wall surface of the first trench portion 44) in the plan view, and is formed in a tapered shape (a dwindling shape) from the electrode surface 50 to the bottom wall of the trench 41 in the cross sectional view. The insulating recess edge portion 58 has an opening end portion located in a region on the electrode surface 50 side with respect to the first main surface 3.

The opening end portion of the insulating recess edge portion 58 is formed at a depth position (height position) facing the wall surface of the first trench portion 44 in the horizontal direction. The opening end portion of the insulating recess edge portion 58 is formed in a region on the electrode surface 50 side with respect to the intermediate portion in the depth range of the first trench portion 44 in this embodiment. As a matter of course, the opening end portion of the insulating recess edge portion 58 may be formed in a region on the first main surface 3 side with respect to the intermediate portion in the depth range of the first trench portion 44.

The insulating recess edge portion 58 has a bottom wall portion formed at a connecting portion between the insulating film 42 (the first insulating film 47) and the recess insulating film 57 in this embodiment. The bottom wall portion of the insulating recess edge portion 58 is formed in a depth position (height position) facing the lower end portion of the first trench portion 44 in the horizontal direction. Specifically, the bottom wall portion of the insulating recess edge portion 58 faces the first inclined portion 44a of the first trench portion 44.

The semiconductor device 1 includes an edge portion insulator 60 that is embedded in the recess edge portion 52. The edge portion insulator 60 is embedded in the recess edge portion 52 across the recess insulating film 57 in this embodiment. That is, the edge portion insulator 60 is embedded in the insulating recess edge portion 58. The edge portion insulator 60 may be considered as one component of the gate structure 40. The edge portion insulator 60 may also be referred to as a “side spacer,” a “sidewall,” a “wall structure,” a “step mitigating portion,” or the like.

In this embodiment, a plurality of the edge portion insulators 60 are embedded in the recess edge portions 52 on both sides of the electrode surface 50 so as to expose the inner portion of the electrode surface 50 in the cross sectional view. Since the edge portion insulators 60 on both sides have a similar configuration, a configuration of one of the edge portion insulators 60 shall be described hereinafter. The descriptions of the edge portion insulator 60 on one side are applied to descriptions of the edge portion insulator 60 on the other side.

The edge portion insulator 60 may include one type of or a plurality types of insulators. The edge portion insulator 60 may include at least one of a silicon oxide, a silicon nitride, and a silicon oxynitride. The edge portion insulator 60 preferably includes an insulator different from the insulator that constitutes the insulating film 42 (specifically the first insulating film 47). The edge portion insulator 60 preferably includes an insulator different from the insulator that constitutes the recess insulating film 57 (the insulating recess edge portion 58).

The edge portion insulator 60 includes an edge insulating film 61 that covers the side wall of the trench 41 and the wall surface of the recess edge portion 52 in a film shape. The edge insulating film 61 faces the surface layer portion of the first main surface 3 across the first insulating film 47 and faces the embedded electrode 43 (the first electrode 54) across the recess insulating film 57 (the recess insulating film 57).

The edge insulating film 61 includes an insulator different from the insulator that constitutes the insulating film 42 (specifically the first insulating film 47). Also, the edge insulating film 61 includes an insulator different from the insulator that constitutes the recess insulating film 57 (the insulating recess edge portion 58). The edge insulating film 61 includes either one or both of a silicon nitride and a silicon oxynitride in this embodiment. That is, the edge insulating film 61 includes a nitride film. The edge insulating film 61 covers the wall surface of the recess edge portion 52 (the insulating recess edge portion 58) in a U-shape or a J-shape in the cross sectional view.

Specifically, the edge insulating film 61 includes a first extension portion 61a and a second extension portion 61b. The first extension portion 61a covers the side wall of the trench 41 in a film shape. The first extension portion 61a covers the first insulating film 47 in a film shape and faces the side wall of the trench 41 across the first insulating film 47 in this embodiment. The first extension portion 61a preferably has a thickness greater than the film thickness (the first film thickness TF1) of the first insulating film 47 in regard to the horizontal direction.

The first extension portion 61a extends from a region outside the recess edge portion 52 to a region inside the recess edge portion 52 in regard to the depth direction of the trench 41. That is, the first extension portion 61a has an upper end portion on the opening side of the trench 41 and a lower end portion inside the recess edge portion 52. The upper end portion of the first extension portion 61a is positioned on the bottom wall side of the recess edge portion 52 with respect to the first main surface 3 and is not formed in a region outside the trench 41.

That is, the upper end portion of the first extension portion 61a is terminated within the trench 41 and exposes the first main surface 3. The upper end portion of the first extension portion 61a may be curved in an arc shape. The lower end portion of the first extension portion 61a is positioned within the insulating recess edge portion 58 and faces the embedded electrode 43 across the recess insulating film 57 in this embodiment.

The second extension portion 61b has a film formation direction that folds back from the lower end portion of the first extension portion 61a to the first main surface 3 side, and covers the wall surface of the recess edge portion 52 in a film shape. Specifically, the second extension portion 61b has a film formation direction that is inclined obliquely toward the opening side in regard to the film formation direction of the first extension portion 61a. The second extension portion 61b covers the recess insulating film 57 in a film shape, and covers the embedded electrode 43 (the first electrode 54) across the recess insulating film 57 in this embodiment.

That is, the second extension portion 61b is formed in a film shape that conforms to the recess insulating film 57, and covers the protruding edge portion 53 of the embedded electrode 43 across the recess insulating film 57. The second extension portion 61b has a thickness smaller than the thickness of the recess insulating film 57 in regard to the depth direction of the trench 41 (the normal direction Z). The second extension portion 61b preferably has a thickness larger than the thickness (the first film thickness TF1) of the first insulating film 47.

The second extension portion 61b has an upper end portion on the opening side of the trench 41 and a lower end portion within the recess edge portion 52. The upper end portion of the second extension portion 61b is located on the electrode surface 50 side with respect to the first main surface 3. Specifically, the upper end portion of the second extension portion 61b is located on the protruding edge portion 53. The upper end portion of the second extension portion 61b is located on the electrode surface 50 side (the bottom wall side of the trench 41) with respect to the upper end portion of the first extension portion 61a and faces the first extension portion 61a in the horizontal direction.

The upper end portion of the second extension portion 61b faces an intermediate portion of a depth range of the first extension portion 61a in this embodiment. That is, the upper end portion of the second extension portion 61b is terminated within the trench 41, and the second extension portion 61b is not formed in a region outside the trench 41. Also, the second extension portion 61b covers the recess edge portion 52 and a region in a vicinity of the recess edge portion 52, and exposes the inner portion of the electrode surface 50. Also, the upper end portion of the second extension portion 61b faces the protruding edge portion 53 across the recess insulating film 57.

The lower end portion of the second extension portion 61b is connected to the lower end portion of the first extension portion 61a within the insulating recess edge portion 58. Therefore, a connecting portion between the lower end portion of the second extension portion 61b and the lower end portion of the first extension portion 61a constitutes a common lower end portion of the first extension portion 61a and the second extension portion 61b. The lower end portion of the second extension portion 61b faces the embedded electrode 43 across the recess insulating film 57. In such a manner, the second extension portion 61b is formed in a U-shape or a J-shape together with the first extension portion 61a in the cross sectional view.

The edge portion insulator 60 has a groove portion 62 that is recessed toward the bottom portion of the recess edge portion 52 in a region above the recess edge portion 52. The groove portion 62 is demarcated by the edge insulating film 61 in the region above the recess edge portion 52 in this embodiment. More specifically, the groove portion 62 is demarcated by the first extension portion 61a and the second extension portion 61b of the edge insulating film 61 in a region above the insulating recess edge portion 58.

The groove portion 62 faces the wall surface of the first trench portion 44 across the first extension portion 61a, and faces the opening recess 51 (a space within the trench 41) across the second extension portion 61b. That is, the groove portion 62 has an opening end portion that is located in a region below the first main surface 3 (a region on the electrode surface 50 side) in a height range between the first main surface 3 and the electrode surface 50 of the embedded electrode 43, and has a bottom wall located in a region above the electrode surface 50 (a region on the first main surface 3 side).

The groove portion 62 has a width less than the width of the recess edge portion 52 in regard to the horizontal direction. The groove portion 62 has a width less than the width of the insulating recess edge portion 58 in regard to the horizontal direction. That is, the edge insulating film 61 narrows the width of the recess edge portion 52 (the insulating recess edge portion 58). The groove portion 62 extends along the side wall of the trench 41 (the wall surface of the first trench portion 44) in the plan view and is formed in a tapered shape (a dwindling shape) from the electrode surface 50 toward the bottom wall of the trench 41 in the cross sectional view.

The edge portion insulator 60 includes an insulating buried object 63 that is embedded in the groove portion 62 in this embodiment. In the accompanying drawings, the insulating buried object 63 is shown by a filled hatching. The insulating buried object 63 mitigates a step (uplift/subsidence) due to the groove portion 62.

The insulating buried object 63 preferably includes an insulating material different from the edge portion insulator 60. The insulating buried object 63 includes an oxide in this embodiment. Specifically, the insulating buried object 63 includes a tetraethyl orthosilicate as one example of the oxide. The tetraethyl orthosilicate may be referred to as a “TEOS.” That is, the oxide that constitutes the insulating buried object 63 is different from the oxide that constitutes the insulating film 42.

The insulating buried object 63 may be embedded only within the groove portion 62 and exposes a whole region of the edge portion insulator 60 positioned outside the groove portion 62. As a matter of course, the insulating buried object 63 may be drawn out from within the groove portion 62 to a region outside the groove portion 62 and covers at least a part of or a whole region of a region of the edge portion insulator 60 outside the groove portion 62.

FIG. 16 shows an example of the insulating buried object 63 that has a main body portion 63a positioned within the groove portion 62, a first overlap portion 63b covering the first extension portion 61a, and a second overlap portion 63c covering the second extension portion 61b. The insulating buried object 63 does not need to include both of the first overlap portion 63b and the second overlap portion 63c at the same time, and may include only one of the first overlap portion 63b and the second overlap portion 63c.

The first overlap portion 63b may cover a part of or a whole region of the first extension portion 61a. The second overlap portion 63c may cover a part or a whole region of the second extension portion 61b. In a case in which the first overlap portion 63b covers a part of the first extension portion 61a, the first overlap portion 63b may be separated from the main body portion 63a. In a case in which the second overlap portion 63c covers a part of the second extension portion 61b, the second overlap portion 63c may be separated from the main body portion 63a.

The semiconductor device 1 includes a plurality of p-type (second conductivity type) body regions 65 that are formed in the surface layer portion of the first main surface 3 (the drift region 9) at the output region 6. Specifically, the body regions 65 are formed in regions along the gate structures 40 in the surface layer portion of the first main surface 3 (the drift region 9), and face the corresponding embedded electrodes 43 across the corresponding insulating films 42. The body regions 65 are formed shallower than the high concentration drift region 35, and face the drift region 9 across a part of the high concentration drift region 35 in this embodiment.

The body region 65 formed in a region between a pair of adjacent gate structures 40 is shared by the pair of gate structures 40. The body regions 65 extend in band shapes in the regions between adjacent pairs of gate structures 40 in the plan view. The body regions 65 may be formed at an interval from the separation structure 30 on the inner side of the output region 6. As a matter of course, the body regions 65 may be formed in a whole region of the output region 6 as a single body region 65. In this case, the single body region 65 may be in contact with the wall surface of the separation structure 30.

Hereinafter, a configuration of one body region 65 with respect to one gate structure 40 shall be described. The body region 65 is located on the first main surface 3 side with respect to an intermediate portion in a depth range of the separation structure 30. The body region 65 is located on the first main surface 3 side with respect to an intermediate portion in a depth range of the gate structure 40. The body region 65 is formed deeper than the lower end portion of the first trench portion 44 and has a portion along the second trench portion 45.

Therefore, the body region 65 faces the first electrode 54 across the insulating film 42 (the second insulating film 48). As a matter of course, the body region 65 may be formed deeper than the lower end portion of the second trench portion 45 and may have a portion along the third trench portion 46. In this case, the body region 65 may have a portion that faces the upper end portion of the second electrode 55 across the insulating film 42 (the third insulating film 49).

The body region 65 includes a main body portion 65a and an extension portion 65b. The main body portion 65a extends in a layered shape along the first main surface 3 so as to contact the side wall of the trench 41. The main body portion 65a preferably has a bottom portion located in a region on the second trench portion 45 side with respect to the lower end portion of the first trench portion 44. The bottom portion of the main body portion 65a is preferably located in a region between the upper end portion and the lower end portion of the second trench portion 45.

The main body portion 65a faces the edge portion insulator 60 across the first insulating film 47 at a portion along the first trench portion 44, and faces the embedded electrode 43 (the first electrode 54) across the second insulating film 48 at a portion along the second trench portion 45. That is, the main body portion 65a faces a part of the edge insulating film 61 (the first extension portion 61a) across the first insulating film 47. Also, the main body portion 65a faces the insulating buried object 63 in the horizontal direction.

The extension portion 65b is a portion that extends toward the bottom wall of the trench 41 from a portion of the main body portion 65a along the trench 41. That is, the extension portion 65b has a bottom portion positioned on the bottom wall side of the trench 41 with respect to the bottom portion of the main body portion 65a. The bottom portion of the extension portion 65b is curved in an arc shape toward the bottom wall side of the trench 41 in the cross sectional view. The bottom portion of the extension portion 65b is positioned at an interval from the lower end portion of the second trench portion 45 to the upper end portion side of the second trench portion 45.

That is, the bottom portion of the extension portion 65b is positioned on an upper side with respect to the second inclined portion 45a of the second trench portion 45. As a matter of course, the extension portion 65b may be drawn out to a region along the upper end portion of the third trench portion 46 via the lower end portion of the second trench portion 45 (the second inclined portion 45a). In this case, the extension portion 65b (the body region 65) may have a portion that faces the second electrode 55 across the third insulating film 49.

The semiconductor device 1 includes a plurality of channel cells 70 that are formed on both sides of each of the gate structures 40 as control objects of each of the gate structures 40. In this embodiment, two channel cells 70 arranged on both sides of one gate structure 40 are controlled by one gate structure 40 and are not controlled by the other of the gate structures 40.

The channel cells 70 are formed in regions along the inner portion of the gate structures 40 at intervals from both of the end portions of the gate structures 40 in the longitudinal direction (the second direction Y). The channel cells 70 expose the body regions 65 from regions of the first main surface 3 sandwiched between both of the end portions of the gate structures 40.

The channel cells 70 face the high concentration drift region 35 across parts of the body regions 65 in the thickness direction. The channel cells 70 are preferably formed in the inner portion side of the high concentration drift region 35 with respect to the peripheral edge of the high concentration drift region 35 in the plan view.

Each of the channel cells 70 includes a plurality of source regions 71 of the n-type. In FIG. 6, the source regions 71 are shown by hatching for clarity. Each of the source regions 71 has an n-type impurity concentration higher than that of the drift region 9. Each of the source regions 71 may have the n-type impurity concentration higher than that of the high concentration drift region 35. The n-type impurity concentration of each source region 71 may be not less than 1×10¹⁸ cm⁻³ and not more than 1×10²¹ cm⁻³.

The source regions 71 are formed at intervals on the first main surface 3 side from the bottom portion of the corresponding body region 65 and are arranged at intervals along the corresponding gate structure 40. The source regions 71 face the edge portion insulator 60 across the insulating film 42 (the first insulating film 47) and face the embedded electrode 43 (the first electrode 54) across the insulating film 42 (the second insulating film 48).

The source regions 71 form channels of the output transistor 15 in regions between the drift region 9 (the high concentration drift region 35) and the source regions 71. A channel length LC of the channel is defined as a distance between the drift region 9 (the high concentration drift region 35) and the source region 71.

Hereinafter, a configuration of one source region 71 shall be described. The source region 71 includes a source body portion 71a and a source extension portion 71b. The source body portion 71a extends in a layered shape along the first main surface 3 so as to contact the side wall of the trench 41. The source body portion 71a has a bottom portion located in a region on the first main surface 3 side with respect to the bottom portion of the body region 65, and faces the drift region 9 (the high concentration drift region 35) across a part of the body region 65.

The source body portion 71a faces the edge portion insulator 60 across the first insulating film 47 at a portion along the first trench portion 44. Specifically, the source body portion 71a faces a part of the edge insulating film 61 (the first extension portion 61a) across the first insulating film 47. That is, the source body portion 71a faces the insulating buried object 63 in the horizontal direction. The source body portion 71a may be formed in a region on the first main surface 3 side with respect to the lower end portion of the first trench portion 44.

As a matter of course, the source body portion 71a may be formed in a region on the second trench portion 45 side with respect to the lower end portion of the first trench portion 44. That is, the source body portion 71a may have a portion along the first inclined portion 44a of the first trench portion 44. In this case, the source body portion 71a is preferably positioned on the upper end portion side of the second trench portion 45 with respect to the intermediate portion in the depth range of the second trench portion 45. The source body portion 71a may face the embedded electrode 43 (the first electrode 54) across the second trench portion 45.

The source extension portion 71b is a portion that extends toward the bottom wall side of the trench 41 from a portion of the source body portion 71a along the trench 41. That is, the source extension portion 71b has a bottom portion located on the bottom wall side of the trench 41 with respect to the bottom portion of the source body portion 71a. The bottom portion of the source extension portion 71b is curved in an arc shape toward the bottom wall of the trench 41 in the cross sectional view. The bottom portion of the source extension portion 71b is formed in a region on the first main surface 3 side with respect to the bottom portion of the body region 65, and faces the drift region 9 (the high concentration drift region 35) across a part of the body region 65.

The bottom portion of the source extension portion 71b is preferably located on the upper end portion side of the second trench portion 45 with respect to the intermediate portion in the depth range of the second trench portion 45. The source extension portion 71b faces the embedded electrode 43 (the first electrode 54) across the second trench portion 45. The aforementioned channel length LC is a distance between the source extension portion 71b and the drift region 9 (the high concentration drift region 35).

In a case in which the source body portion 71a is positioned in a region on the first main surface 3 side with respect to the lower end portion of the first trench portion 44, the source extension portion 71b is drawn out to a depth position that reaches the second trench portion 45 via the lower end portion of the first trench portion 44. That is, the source extension portion 71b may have a portion that extends along the first inclined portion 44a of the first trench portion 44. In this case, the source extension portion 71b faces the edge portion insulator 60 across the first insulating film 47 at a portion along the first trench portion 44.

Specifically, the source extension portion 71b faces a part of the edge insulating film 61 (the first extension portion 61a) across the first insulating film 47. The source extension portion 71b may be located in a region on the bottom wall side of the trench 41 with respect to the lower end portion of the insulating buried object 63. That is, the source extension portion 71b may be formed in a region below the lower end portion of the insulating buried object 63 so as not to face the insulating buried object 63 in the horizontal direction. As a matter of course, the source extension portion 71b may face the insulating buried object 63 in the horizontal direction.

In a case in which the source body portion 71a is positioned in a region on the second trench portion 45 side with respect to the lower end portion of the first trench portion 44, the source extension portion 71b is drawn out from the source body portion 71a toward the lower end portion side of the second trench portion 45. In this case, the source extension portion 71b faces the embedded electrode 43 (the first electrode 54) in the horizontal direction, and does not face the insulating buried object 63 in the horizontal direction.

Each of the channel cells 70 includes a plurality of contact regions 72 of the p-type. The contact regions 72 may be referred to as “first back gate regions.” Each of the contact regions 72 has a p-type impurity concentration higher than that of the body region 65. The p-type impurity concentration of each contact region 72 may be not less than not less than 1×10¹⁸ cm⁻³ and not more than 1×10²¹ cm⁻³.

The contact regions 72 are formed at intervals on the first main surface 3 side from the bottom portion of the corresponding body region 65 and are arranged alternately with the source regions 71 along the corresponding gate structure 40. The contact regions 72 face the edge portion insulator 60 across the insulating film 42 (the first insulating film 47) and face the embedded electrode 43 (the first electrode 54) across the insulating film 42 (the second insulating film 48). Hereinafter, a configuration of one contact region 72 shall be described. The contact region 72 includes a contact body portion 72a and a contact extension portion 72b. The contact body portion 72a extends in a layered shape along the first main surface 3 so as to contact the side wall of the trench 41. The contact body portion 72a has a bottom portion formed in a region on the first main surface 3 side with respect to the bottom portion of the body region 65, and faces the drift region 9 (the high concentration drift region 35) across a part of the body region 65 in between.

The contact body portion 72a faces the edge portion insulator 60 across the first insulating film 47 at a portion along the first trench portion 44. Specifically, the contact body portion 72a faces a part of the edge insulating film 61 (the first extension portion 61a) across the first insulating film 47. That is, the contact body portion 72a faces the insulating buried object 63 in the horizontal direction. The contact body portion 72a is preferably connected to the source body portion 71a of the source region 71 in the second direction Y. The contact body portion 72a may be formed in a region on the first main surface 3 side with respect to the lower end portion of the first trench portion 44.

As a matter of course, the contact body portion 72a may be formed in a region on the second trench portion 45 side with respect to the lower end portion of the first trench portion 44. That is, the contact body portion 72a may have a portion along the first inclined portion 44a of the first trench portion 44. In this case, the contact body portion 72a is preferably positioned on the upper end portion side of the second trench portion 45 with respect to the intermediate portion in the depth range of the second trench portion 45. The contact body portion 72a may face the embedded electrode 43 (the first electrode 54) across the second trench portion 45.

The contact extension portion 72b is a portion that extends toward the bottom wall side of the trench 41 from a portion of the contact body portion 72a along the trench 41. That is, the contact extension portion 72b has a bottom portion positioned on the bottom wall side of the trench 41 with respect to the bottom portion of the contact body portion 72a.

The bottom portion of the contact extension portion 72b is curved in an arc shape toward the bottom wall side of the trench 41 in the cross sectional view. The bottom portion of the contact extension portion 72b is formed in a region on the first main surface 3 side with respect to the bottom portion of the body region 65, and faces the drift region 9 (the high concentration drift region 35) across a part of the body region 65.

The bottom portion of the contact extension portion 72b is preferably located on the upper end portion side of the second trench portion 45 with respect to the intermediate portion in the depth range of the second trench portion 45. The contact extension portion 72b faces the embedded electrode 43 (the first electrode 54) across the second trench portion 45. The contact extension portion 72b is preferably connected to the source extension portion 71b of the source region 71 in the second direction Y.

In a case in which the contact body portion 72a is positioned in a region on the first main surface 3 side with respect to the lower end portion of the first trench portion 44, the contact extension portion 72b is drawn out to a depth position that reaches the second trench portion 45 via the lower end portion of the first trench portion 44. That is, the contact extension portion 72b may have a portion along the first inclined portion 44a of the first trench portion 44. In this case, the contact extension portion 72b faces the edge portion insulator 60 across the first insulating film 47 at a portion along the first trench portion 44.

Specifically, the contact extension portion 72b faces a part of the edge insulating film 61 (the first extension portion 61a) across the first insulating film 47. The contact extension portion 72b may be located in a region on the bottom wall side of the trench 41 with respect to the lower end portion of the insulating buried object 63. That is, the contact extension portion 72b may be formed in a region below the lower end portion of the insulating buried object 63 so as not to face the insulating buried object 63 in the horizontal direction. As a matter of course, the contact extension portion 72b may face the insulating buried object 63 in the horizontal direction.

In a case in which the contact body portion 72a is positioned in a region on the second trench portion 45 side with respect to the lower end portion of the first trench portion 44, the contact extension portion 72b is drawn out from the contact body portion 72a toward the lower end portion side of the second trench portion 45. In this case, the contact body portion 72a faces the embedded electrode 43 (the first electrode 54) in the horizontal direction, and does not face the insulating buried object 63 in the horizontal direction.

In regard to two of the channel cells 70 that are formed on both sides of one gate structure 40, the source regions 71 in one channel cell 70 face the source regions 71 in the other channel cell 70 across the gate structure 40. In this embodiment, the source extension portion 71b on one side and the source extension portion 71b on the other side face each other across the gate structure 40.

Also, the contact regions 72 in one channel cell 70 face the contact regions 72 in the other channel cell 70 across the gate structure 40. In this embodiment, the contact extension portion 72b on one side and the contact extension portion 72b on the other side face each other across the gate structure 40.

As a matter of course, the source regions 71 in one channel cell 70 may face the contact regions 72 in the other channel cell 70 across the gate structure 40. Also, the contact regions 72 in one channel cell 70 may face the source regions 71 in the other channel cell 70 across the gate structure 40.

In regard to two of the channel cells 70 that are interposed between two of the gate structures 40, the source regions 71 in one channel cell 70 are connected to the contact regions 72 in the other channel cell 70 in the first direction X. In this embodiment, the source body portion 71a on one side is connected to the contact body portion 72a on the other side in the first direction X.

Also, the contact regions 72 in one channel cell 70 are connected to the source regions 71 in the other channel cell 70 in the first direction X. In this embodiment, the contact body portion 72a on one side is connected to the source body portion 71a on the other side in the first direction X.

As a matter of course, the source regions 71 in one channel cell 70 may be connected to the source regions 71 in the other channel cell 70 in the first direction X. Also, the contact regions 72 in one channel cell 70 may be connected to the contact regions 72 in the other channel cell 70 in the first direction X.

The channel cell 70 located on an inner side in two of the channel cells 70 that are formed on both sides of the outermost gate structure 40 faces the drift region 9 across a part of the body region 65 in the thickness direction. On the other hand, the channel cell 70 located on an outer side does not include the source region 71, and includes only the contact region 72. This suppresses a formation of a current path in a region between the separation structure 30 and the outermost gate structure 40.

The semiconductor device 1 includes a plurality of first silicide layers 75 that are formed in surface layer portions of the source regions 71, respectively. The first silicide layers 75 are formed by silicidizing the surface layer portions of the source regions 71 with a metal material. The first silicide layers 75 may include the n-type impurities of the source regions 71. The first silicide layers 75 may include at least one of a TiSi layer, a TiSi₂ layer, an NiSi layer, a CoSi layer, a CoSi₂ layer, an MoSi₂ layer, and a WSi₂ layer.

Hereinafter, with reference to FIG. 13, a configuration of one first silicide layer 75 shall be described. The first silicide layer 75 includes a first silicide body portion 75a and a first silicide extension portion 75B. The first silicide body portion 75a has a bottom portion located on the first main surface 3 side with respect to a bottom portion of the corresponding source region 71, and extends in a layered shape or a film shape along the first main surface 3.

That is, the first silicide body portion 75a faces a part of the body region 65 across a part of the source region 71. The first silicide body portion 75a may be formed a substantially whole region of the surface layer portion of the source region 71. The first silicide body portion 75a is exposed from the first main surface 3.

In this embodiment, the first silicide body portion 75a has a portion exposed from the side wall of the trench 41. The first silicide body portion 75a has a portion in contact with the insulating film 42 and faces the edge portion insulator 60 across the insulating film 42. Specifically, the first silicide body portion 75a faces the edge portion insulator 60 across the first insulating film 47 at a portion along the first trench portion 44.

More specifically, the first silicide body portion 75a faces a part of the edge insulating film 61 (the first extension portion 61a) across the first insulating film 47. That is, the first silicide body portion 75a faces the insulating buried object 63 in the horizontal direction. The edge portion insulator 60 (in this embodiment, the laminated structure of the edge insulating film 61 and the insulating buried object 63) is to be functioned as a short circuit blocking structure for the first silicide layer 75 with respect to the embedded electrode 43 (the gate structure 40).

The first silicide extension portion 75b is a portion that extends toward the bottom wall side of the trench 41 from a portion of the first silicide body portion 75a along the trench 41. That is, the first silicide extension portion 75b has a bottom portion positioned on the bottom wall side of the trench 41 with respect to the bottom portion of the first silicide body portion 75a. The bottom portion of the first silicide extension portion 75b is curved in an arc shape toward the bottom wall side of the trench 41 in the cross sectional view.

The bottom portion of the first silicide extension portion 75b is formed in a region on the first main surface 3 side with respect to the bottom portion of the source region 71, and faces the body region 65 across the source region 71. The bottom portion of the first silicide extension portion 75b is preferably located on the upper end portion side of the first trench portion 44 with respect to the lower end portion of the first trench portion 44 (the first inclined portion 44a). The first silicide extension portion 75b faces the edge portion insulator 60 across the first trench portion 44. The first silicide extension portion 75b may face the insulating buried object 63 across the edge insulating film 61 (the first extension portion 61a) in the horizontal direction.

The semiconductor device 1 includes a plurality of second silicide layers 76 that are formed in surface layer portions of the contact regions 72, respectively. The second silicide layers 76 are formed by silicidizing the surface layer portions of the contact regions 72 with a metal material. The first silicide layers 75 may include the p-type impurities of the contact regions 72. The second silicide layers 76 may include at least one of a TiSi layer, a TiSi₂ layer, an NiSi layer, a CoSi layer, a CoSi₂ layer, an MoSi₂ layer, and a WSi₂ layer.

The second silicide layers 76 are made of the same material as that of the first silicide layers 75 and are connected to the adjacent first silicide layers 75. That is, the second silicide layers 76 and the first silicide layers 75 form a single silicide layer within a corresponding channel cell 70.

Hereinafter, with reference to FIG. 14, a configuration of one second silicide layers 76 shall be described. The second silicide layer 76 includes a second silicide body portion 76a and a second silicide extension portion 76b. The second silicide body portion 76a has a bottom portion positioned on the first main surface 3 side with respect to the bottom portion of the corresponding contact region 72, and extends along the first main surface 3 in a layered shape or a film shape.

That is, the second silicide body portion 76a faces a part of the body region 65 across a part of the contact region 72. The second silicide body portion 76a may be formed in a substantially whole region of the surface layer portion of the contact region 72. The second silicide body portion 76a is exposed from the first main surface 3.

In this embodiment, the second silicide body portion 76a has a portion exposed from the side wall of the trench 41. The second silicide body portion 76a has a portion in contact with the insulating film 42 and faces the edge portion insulator 60 across the insulating film 42. Specifically, the second silicide body portion 76a faces the edge portion insulator 60 across the first insulating film 47 at a portion along the first trench portion 44.

More specifically, the second silicide body portion 76a faces a part of the edge insulating film 61 (the first extension portion 61a) across the first insulating film 47. That is, the second silicide body portion 76a faces the insulating buried object 63 in the horizontal direction. The edge portion insulator 60 (in this embodiment, the laminated structure of the edge insulating film 61 and the insulating buried object 63) is to be functioned as a short circuit blocking structure for the second silicide layer 76 with respect to the embedded electrode 43 (the gate structure 40).

The second silicide extension portion 76b is a portion that extends toward the bottom wall side of the trench 41 from a portion of the second silicide body portion 76a along the trench 41. That is, the second silicide extension portion 76b has a bottom portion positioned on the bottom wall side of the trench 41 with respect to the bottom portion of the second silicide body portion 76a. The bottom portion of the second silicide extension portion 76b is curved in an arc shape toward the bottom wall side of the trench 41 in the cross sectional view.

The bottom portion of the second silicide extension portion 76b is formed in a region on the first main surface 3 side with respect to the bottom portion of the contact region 72, and faces the body region 65 across the contact region 72. The bottom portion of the second silicide extension portion 76b is preferably located on the upper end portion side of the first trench portion 44 with respect to the lower end portion of the first trench portion 44 (the first inclined portion 44a). The second silicide extension portion 76b faces the edge portion insulator 60 across the first trench portion 44. The second silicide extension portion 76b may face the insulating buried object 63 across the edge insulating film 61 (the first extension portion 61a) in the horizontal direction.

The output transistor 15 includes the plurality of unit transistors 17. Each of the unit transistors 17 includes the gate structure 40 and the two channel cells 70 formed on both sides of the gate structure 40. In regard to each of the unit transistor 17, the gate structure 40 constitutes the unit gate, the source regions 71 (two of the channel cells 70) constitute the unit source, and the drain region 8 (the drift region 9 and the high concentration drift region 35) constitute the unit drain.

The output transistor 15 includes the first system transistor 16A and the second system transistor 16B. The first system transistor 16A includes the unit transistors 17 that are systematized (grouped) as an individual control target from the unit transistors 17. The second system transistor 16B includes the unit transistors 17 that are systematized (grouped) as an individual control target from the unit transistors 17 other than the first system transistor 16A.

The output transistor 15 includes a plurality of group regions 77 that are provided in the output region 6 in this embodiment. The group regions 77 include a plurality of first group regions 77A and a plurality of second group regions 77B. The first group regions 77A are regions in which one or a plurality of (in this embodiment, a plurality of) the unit transistors 17 for the first system transistor 16A are arranged. The second group regions 77B are regions in which one or a plurality of (in this embodiment, a plurality of) the unit transistors 17 for the second system transistor 16B are arranged.

The first group regions 77A are arranged at intervals in the first direction X. A number of the unit transistors 17 in each of the first group regions 77A is arbitrary. In this embodiment, two unit transistors 17 are arranged in each of the first group regions 77A. As the number of the unit transistors 17 in each of the first group regions 77A increases, the amount of heat generated in each of the first group regions 77A increases. Therefore, the number of the unit transistors 17 in each of the first group regions 77A is preferably not less than 2 and not more than 5.

The second group regions 77B are arranged alternately with the first group regions 77A along the first direction X so that one of the first group regions 77A is sandwiched between the second group regions 77B. This allows the second group regions 77B to thin out the heat generation points caused by the first group regions 77A, and at the same time, allows the first group regions 77A to thin out the heat generation points caused by the second group regions 77B.

A number of the unit transistors 17 in each of the second group regions 77B is arbitrary. In this embodiment, two unit transistors 17 are arranged in each of the second group regions 77B. As the number of the unit transistors 17 in each of the second group regions 77B increases, the amount of heat generated in each of the second group regions 77B increases.

Therefore, the number of the unit transistors 17 in each of the second group regions 77B is preferably not less than 2 and not more than 5. In consideration of an in-plane temperature variation in the output region 6, it is preferably that the number of the unit transistors 17 in the second group regions 77B is the same as the number of the unit transistors 17 in the first group regions 77A.

The semiconductor device 1 includes a pair (in this embodiment, multiple pairs) of connection structures 80 of a trench electrode type that connects both of the end portions of the plurality (in this embodiment, two) of gate structures 40 to be systematized (grouped) in each of the group regions 77. That is, a pair of the connection structures 80 respectively connects both of the end portions of the gate structures 40 to be systematized as the system transistor 16. The connection structure 80 may be referred to as a “trench connection structure.”

The connection structure 80 on one side connects the first end portions of the plurality (in this embodiment, two) of the corresponding gate structures 40 each other in an arch shape in the plan view. The connection structure 80 on the other side connects the second end portions of the plurality (in this embodiment, two) of the corresponding gate structures 40 each other in an arch shape in the plan view.

Specifically, the connection structure 80 on one side has a first portion extending in the first direction X and a plurality (in this embodiment, two) of second portions extending in the second direction Y. The first portion faces the first end portions of the gate structures 40 in the plan view. The second portions extend toward the first end portions from the first portion so as to be connected to the first end portions.

The connection structure 80 on the other side has a first portion extending in the first direction X and a plurality (in this embodiment, two) of second portions extending in the second direction Y. The first portion faces the second end portions of the gate structures 40 in the plan view. The second portions extend toward the second end portions from the first portion so as to be connected to the second end portions. The plurality of connection structures 80 form a single trench structure of an annular shape or a ladder shape with the gate structures 40 in each of the group regions 77.

The connection structures 80 are formed in regions between the separation structure 30 and the high concentration drift region 35 at intervals from the separation structure 30 and the high concentration drift region 35. The connection structures 80 are formed at intervals to the first main surface 3 side from the bottom portion of the drift region 9, and face the drain region 8 across a part of the drift region 9.

The connection structures 80 may each be formed with a width substantially equal to that of the gate structure 40 and with a depth substantially equal to that of the gate structure 40. As a matter of course, the first portion and the second portions of the connection structure 80 may have different widths. For example, the second portions of the connection structure 80 may be formed narrower than the first portion of the connection structure 80.

In this case, the first portion may have a width substantially equal to the width of the separation structure 30, and the second portions may each have a width substantially equal to the width of the gate structure 40. Further, in this case, the first portion may have a depth substantially equal to the depth of the separation structure 30, and the second portions may each have a depth substantially equal to the depth of the gate structure 40.

The connection structure 80 on the other side has a structure similar to that of the connection structure 80 on one side, except that the connection structure 80 on the other side is connected to the second end portions of the gate structures 40. Hereinafter, a configuration of the connection structure 80 on one side shall be described, and the description of the configuration of the connection structure 80 on the other side shall be omitted.

The connection structure 80 includes a connection trench 81, a connection insulating film 82 and a connection electrode 83. The connection trench 81 is formed in the first main surface 3 and defines a wall surface of the connection structure 80. The connection trench 81 is connected to the trenches 41.

The connection insulating film 82 covers the wall surface of the connection trench 81. The connection insulating film 82 is connected to the insulating film 42 at a communicating portion between the trench 41 and the connection trench 81. Specifically, the connection insulating film 82 is connected to the first insulating film 47, the second insulating film 48, the third insulating film 49 and the intermediate insulating film 56.

The connection insulating film 82 is thicker than the first insulating film 47. The connection insulating film 82 is thicker than the second insulating film 48. The thickness of the connection insulating film 82 may be substantially equal to that of the third insulating film 49. The connection insulating film 82 may include a silicon oxide film. The connection insulating film 82 may include a silicon oxide film made of an oxide of the chip 2, or may include a silicon oxide film (an oxide separated from the chip 2) formed by a CVD method.

The connection electrode 83 is embedded in the connection trench 81 across the connection insulating film 82, and faces the drift region 9 across the connection insulating film 82. The connection electrode 83 is connected to the second electrode 55 at the communicating portion between the trench 41 and the connection trench 81, and is electrically insulated from the first electrode 54 by the intermediate insulating film 56. The connection electrode 83 consists of a drawn out portion in which the second electrode 55 is drawn out into the connection trench 81 from inside the trench 41. The connection electrode 83 may include a conductive polysilicon of the n-type or the p-type.

The semiconductor device 1 includes a field insulating film 85 that selectively covers the first main surface 3 inside and outside the output region 6. The field insulating film 85 covers the first main surface 3 along an outer wall of the separation structure 30 outside the output region 6 and is connected to the separation insulating film 32. The field insulating film 85 covers the first main surface 3 along an inner wall of the separation structure 30 inside the output region 6 and is connected to the separation insulating film 32 and the connection insulating film 82.

The field insulating film 85 is formed at an interval on the separation structure 30 side from the gate structures 40, and has a field opening 86 that exposes the gate structures 40. The field opening 86 is formed at an interval toward the inside of the output region 6 from the separation structure 30 in the plan view, and has an opening wall surface that extends along the separation structure 30. The field opening 86 exposes the embedded electrodes 43.

The field insulating film 85 is preferably thicker than the first insulating film 47. The field insulating film 85 is particularly preferably thicker than the second insulating film 48. The thickness of the field insulating film 85 may be not less than the thickness of the third insulating film 49, or less than the thickness of the third insulating film 49.

The field insulating film 85 may include a silicon oxide film made of an oxide of the chip 2. The field insulating film 85 may include a silicon oxide film formed by a CVD method. That is, the field insulating film 85 may include an oxide separated from the chip 2.

The semiconductor device 1 further includes a contact insulating film 87 that covers the output region 6. The contact insulating film 87 may include one or a plurality of insulators. The contact insulating film 87 may include at least one of a silicon oxide, a silicon nitride, and a silicon oxynitride. The contact insulating film 87 preferably includes an insulator different from the insulator that constitutes the insulating film 42.

The contact insulating film 87 preferably includes an insulator different from the insulator that constitutes the recess insulating film 57 (the insulating recess edge portion 58). The contact insulating film 87 preferably includes an insulator different from the insulator that constitutes the insulating buried object 63. The contact insulating film 87 includes either or both of a silicon nitride and a silicon oxynitride. That is, the edge insulating film 61 includes a nitride film in this embodiment.

The contact insulating film 87 has a portion covering the field insulating film 85, a portion covering the first main surface 3, and a portion covering the gate structures 40 within the output region 6. Specifically, the contact insulating film 87 enters the field opening 86 from on the field insulating film 85 and covers the first main surface 3 and the gate structures 40 in the field opening 86.

The contact insulating film 87 preferably directly covers the first silicide layers 75 and the second silicide layers 76 on the first main surface 3. As a matter of course, the contact insulating film 87 may indirectly cover the first silicide layers 75 and the second silicide layers 76. In this case, the contact insulating film 87 may cover the first silicide layers 75 and the second silicide layers 76 across an oxide film.

Hereinafter, a covering mode of the contact insulating film 87 with respect to one gate structures 40 shall be described. The contact insulating film 87 enters the opening recess 51 (the trench 41) from on the first main surface 3 through the edge portion insulator 60, and covers the embedded electrodes 43 within the opening recess 51.

The contact insulating film 87 covers the electrode surface 50 and the edge portion insulator 60 within the opening recess 51 in a film shape. A portion of the contact insulating film 87 that is arranged within the opening recess 51 has a film surface formed on the electrode surface 50 side with respect to the first main surface 3. That is, the portion of the contact insulating film 87 that is arranged within the opening recess 51 does not protrude upward with respect to the first main surface 3.

The contact insulating film 87 covers the first extension portion 61a and the second extension portion 61b of the edge insulating film 61 and has a portion that is directly in contact with the insulating buried object 63 which is exposed from a region between the first extension portion 61a and the second extension portion 61b. The contact insulating film 87 has a portion that is drawn out onto the recess insulating film 57 from on the edge insulating film 61.

The contact insulating film 87 has a portion that faces the embedded electrode 43 across the recess insulating film 57. The contact insulating film 87 may partially face the protruding edge portion 53 across the recess insulating film 57. The contact insulating film 87 may have a portion that is in contact with the first insulating film 47 at the opening end of the trench 41.

The contact insulating film 87 preferably has a thickness greater than the first film thickness TF1. The thickness of the contact insulating film 87 is particularly preferably greater than the second film thickness TF2. The thickness of the contact insulating film 87 is preferably less than the third film thickness TF3. The thickness of the contact insulating film 87 is particularly preferably less than the thickness of the field insulating film 85.

The aforementioned interlayer film 10 covers the first main surface 3 inside and outside the output region 6. The interlayer film 10 includes a lowermost interlayer film 10a that covers the field insulating film 85 and the contact insulating film 87. The lowermost interlayer film 10a preferably includes an insulator that has properties different from those of the edge portion insulator 60 (the edge insulating film 61). The lowermost interlayer film 10a includes an oxide film (specifically a silicon oxide film) in this embodiment.

The lowermost interlayer film 10a covers the separation structure 30, the gate structures 40, the connection structures 80 and the field insulating film 85. Specifically, the lowermost interlayer film 10a enters the trenches 41 (the opening recess 51) from a region above the first main surface 3 through the edge portion insulator 60, and includes anchor portions that are embedded in the trenches 41 (the opening recess 51).

The anchor portion is sandwiched by the edge portion insulators 60 on both sides within the trench 41 (the opening recess 51). The anchor portion covers the edge portion insulator 60 across the contact insulating film 87, and covers the embedded electrode 43 (the electrode surface 50) across the contact insulating film 87. That is, the anchor portion covers the first extension portion 61a and the second extension portion 61b of the edge insulating film 61 across the contact insulating film 87, and covers the insulating buried object 63 across the contact insulating film 87.

The semiconductor device 1 includes a plurality of gate wirings 91 that are arranged inside the interlayer film 10. The gate wirings 91 are routed in the output region 6 and the control region 7, and electrically connected to the output transistor 15 in the output region 6, and electrically connected to the control circuit 18 (the gate control circuit 19) in the control region 7. The gate wirings 91 individually transmit the plurality of gate signals generated by the control circuit 18 (the gate control circuit 19) to the output transistor 15.

The gate wirings 91 include a first gate wiring 91A and a second gate wiring 91B. The first gate wiring 91A individually transmits the gate signal to the first system transistor 16A. The first gate wiring 91A is electrically connected to the gate structures 40 for the first system transistor 16A via a plurality of gate contact electrodes 92 arranged inside the interlayer film 10 (the lowermost interlayer film 10a). Specifically, the first gate wiring 91A is electrically connected to the corresponding first electrodes 54 and the corresponding connection electrodes 83 via the gate contact electrodes 92.

That is, the first electrode 54 and the second electrode 55 for the first system transistor 16A are simultaneously controlled to be turned on and off by the same gate signal. This suppresses a voltage drop between the first electrode 54 and the second electrode 55, and suppresses an undesirable electric field concentration. As a result, a decrease in withstand voltage (breakdown voltage) caused by the electric field concentration is suppressed.

The second gate wiring 91B is electrically independent from the first gate wiring 91A and individually transmits the gate signal to the second system transistor 16B. The second gate wiring 91B is electrically connected to the gate structures 40 for the second system transistor 16B via gate contact electrodes 92 arranged inside the interlayer film 10 (the lowermost interlayer film 10a). Specifically, the second gate wiring 91B is electrically connected to the corresponding first electrodes 54 and the corresponding connection electrodes 83 via the gate contact electrodes 92.

That is, the first electrode 54 and the second electrode 55 for the second system transistor 16B are simultaneously controlled to be turned on and off by the same gate signal. This suppresses a voltage drop between the first electrode 54 and the second electrode 55, and suppresses an undesirable electric field concentration. As a result, a decrease in withstand voltage (breakdown voltage) caused by the electric field concentration is suppressed.

The gate contact electrode 92 for the gate structure 40 has a width less than the gate width WG of each of the gate structures 40, and is mechanically and electrically connected to the inner portion of the electrode surface 50 at intervals from the edge portion insulators 60 on both sides in the cross sectional view.

The gate contact electrode 92 may have a width not less than ⅕ of the gate width WG. The gate contact electrode 92 preferably has a width not less than ¼ of the gate width WG. The gate contact electrode 92 particularly preferably has a width not less than ⅓ of the trench pitch TP. The gate contact electrode 92 may have a width not less than ½ of the trench pitch TP.

The aforementioned edge portion insulator 60 functions as a short circuit blocking structure for the gate contact electrode 92 with respect to the channel cell 70. Therefore, even if the gate contact electrode 92 is misaligned in a direction approaching the channel cell 70, a short circuiting of the gate contact electrode 92 to the channel cell 70 is suppressed in a range where the gate contact electrode 92 is in contact with the edge portion insulator 60.

The gate contact electrodes 92 are arranged in contact openings 93 that are formed in the interlayer film 10 (the lowermost interlayer film 10a), respectively. Each of the gate contact electrodes 92 includes a first electrode film 94 and a second electrode film 95 laminated in that order from a wall surface side of the contact opening 93.

The first electrode film 94 is formed as a barrier electrode film and covers the wall surface of the contact opening 93 in a film shape. The first electrode film 94 is in contact with the interlayer film 10 (the lowermost interlayer film 10a) and the contact insulating film 87 within the contact opening 93. The first electrode film 94 may have a thickness less than the thickness of the contact insulating film 87. The first electrode film 94 may include a Ti-based metal film. The first electrode film 94 may include either or both of a Ti film and a TiN film. In a case in which the first electrode film 94 has a layered structure, the layering order of the Ti film and the TiN film is arbitrary.

The second electrode film 95 is formed as an electrode body and is embedded in the contact openings 93 across the first electrode film 94. The second electrode film 95 preferably includes at least one of a Cu film, a W film and an Al film. The second electrode film 95 has a thickness greater than the thickness of the first electrode film 94. A volume of the second electrode film 95 that occupies the contact openings 93 is greater than a volume of the first electrode film 94 that occupies the contact openings 93.

The semiconductor device 1 includes a source wiring 96 that is arranged inside the interlayer film 10. The source wiring 96 is electrically connected to the source terminal 11, the separation structure 30, and the channel cells 70. The source wiring 96 is electrically connected to the separation structure 30 and the channel cells 70 via a plurality of source contact electrodes 97 arranged inside the interlayer film 10 (the lowermost interlayer film 10a).

The source contact electrode 97 for the channel cell 70 has a width less than the trench pitch TP, and is arranged so as to straddle two adjacent channel cells 70 at intervals from the gate structures 40. The source contact electrodes 97 are each formed in a band shape extending along the corresponding channel cells 70 in the plan view. This allows the source terminals 11 to be electrically connected to the system sources of all the system transistors 16 (the unit sources of the unit transistors 17).

The source contact electrodes 97 may have a width not less than 1/5 of the trench pitch TP. The source contact electrodes 97 preferably have a width not less than 1/4 of the trench pitch TP. The source contact electrodes 97 particularly preferably have a width not less than 1/3 of the trench pitch TP. The source contact electrodes 97 may have a width not less than 1/2 of the trench pitch TP.

The aforementioned edge portion insulator 60 functions as a short circuit blocking structure for the source contact electrodes 97 with respect to the gate structures 40. Therefore, even if the source contact electrodes 97 is misaligned in a direction approaching the gate structure 40, a short circuiting of the source contact electrodes 97 to the gate structure 40 is suppressed in a range where the source contact electrode 97 is in contact with the edge portion insulator 60.

The source contact electrodes 97 are arranged in contact openings 93 that are formed in the interlayer film 10 (the lowermost interlayer film 10a). Each of the source contact electrodes 97 includes a first electrode film 94 and a second electrode film 95 laminated in that order from the wall surface side of the contact openings 93, as with the gate contact electrode 92.

As described above, the semiconductor device 1 includes the chip 2, the trench 41, the embedded electrode 43 and the edge portion insulator 60. The chip 2 has the first main surface 3. The trench 41 is formed in the first main surface 3 and has the side wall and the bottom wall. The embedded electrode 43 is embedded in the trench 41. The embedded electrode 43 has the electrode surface 50 located on the bottom wall side of the trench 41 with respect to the first main surface 3. The embedded electrode 43 has the recess edge portion 52 recessed toward the bottom wall at the edge portion of the electrode surface 50 along the side wall of the trench 41. The edge portion insulator 60 is embedded in the recess edge portion 52.

According to this structure, the semiconductor device 1 that has a novel layout for the trench structure can be provided. In particular, according to this structure, a decrease in reliability due to the recess edge portion 52 can be suppressed by the edge portion insulator 60. Examples of factors that may cause a decrease in reliability when the edge portion insulator 60 is not present include undesired residues (particularly conductive residues) attached to the recess edge portion 52, undesired shape defects caused by the recess edge portion 52, a decrease in film formability caused by the recess edge portion 52, and fluctuations in electrical characteristics caused by the recess edge portion 52.

The edge portion insulator 60 preferably includes the edge insulating film 61 formed in the film shape along the side wall of the trench 41 and the wall surface of the recess edge portion 52. According to this structure, the edge portion insulator 60 can be formed with a film formation precision of the edge insulating film 61, so that it is possible to suppress a part of the edge portion insulator 60 from remaining in a region outside the recess edge portion 52. This configuration is particularly effective in forming the edge portion insulator 60 to the fine recess edge portion 52. The embedded electrode 43 may include the silicon (polysilicon). In this case, the edge insulating film 61 preferably includes the nitride (the nitride film).

The edge insulating film 61 may demarcate the groove portion 62 in the region above the recess edge portion 52 that is recessed toward the bottom portion of the recess edge portion 52. In this case, the edge portion insulator 60 preferably includes the insulating buried object 63 (the buried object) that is buried in the groove portion 62. According to this structure, an unevenness formed in the edge portion insulator 60 can be mitigated by the insulating buried object 63. This can improve the reliability of the edge portion insulator 60.

The insulating buried object 63 preferably includes the insulating material different from that of the edge insulating film 61. According to this structure, the edge insulating film 61 and the insulating buried object 63 can be suppressed from being removed simultaneously during a manufacturing process. Therefore, a shape of the edge portion insulator 60 can be appropriately controlled. The insulating buried object 63 preferably includes the oxide. The insulating buried object 63 particularly preferably includes the tetraethyl orthosilicate as an example of the oxide.

The embedded electrode 43 may include the protruding edge portion 53 that protrudes toward the opening side of the trench 41 at the edge portion of the electrode surface 50. In this case, the protruding edge portion 53 defines the recess edge portion 52 between the side wall of the trench 41 and the protruding edge portion 53.

The trench 41 may have the opening end formed to be wider than the other portion. In this embodiment, the trench 41 includes the relatively wide first trench portion 44 and the second trench portion 45 narrower than the first trench portion 44 that are formed in that order from the first main surface 3 side. In this case, the recess edge portion 52 is demarcated along the portion of the side wall of the trench 41 that forms the opening end (that is, the first trench portion 44).

The semiconductor device 1 preferably further includes the insulating film 42 that covers the side wall of the trench 41. In this case, the embedded electrode 43 may be in contact with the insulating film 42 within the trench 41. Also, the edge portion insulator 60 may be in contact with the insulating film 42 within the recess edge portion 52.

The semiconductor device 1 may include the contact insulating film 87 that covers the electrode surface 50 and the edge portion insulator 60 in a film shape within the trench 41.

According to this structure, the electrode surface 50 and the edge portion insulator 60 can be protected by the contact insulating film 87. This suppresses a shape abnormality of the electrode surface 50 and a shape abnormality of the edge portion insulator 60.

The semiconductor device 1 preferably includes the source region 71 formed in the region along the side wall of the trench 41 in the surface layer portion of the first main surface 3 so as to face the embedded electrode 43 and the edge portion insulator 60 in the horizontal direction along the first main surface 3. According to this structure, the depth position of the source region 71 with respect to the embedded electrode 43 can be determined based on the depth position of the edge portion insulator 60.

The semiconductor device 1 preferably includes the source contact electrode 97 that is connected to the first main surface 3 at the side of the trench 41. According to this structure, the edge portion insulator 60 serves as the short circuit blocking structure for the source contact electrodes 97 with respect to the embedded electrode 43.

Therefore, even if the source contact electrode 97 is misaligned, the short circuiting of the source contact electrode 97 with respect to the embedded electrode 43 is suppressed in the range where the source contact electrode 97 is in contact with the edge portion insulator 60. That is, the semiconductor device 1 may include the source contact electrode 97 that is mechanically connected to the edge portion insulator 60.

The semiconductor device 1 preferably includes the gate contact electrode 92 that is connected to the electrode surface 50 of the embedded electrode 43 and applies a potential to the embedded electrode 43. According to this structure, the edge portion insulator 60 functions as the short circuit blocking structure for the gate contact electrode 92 with respect to the first main surface 3 (the region outside the trench 41).

Therefore, even if the gate contact electrode 92 is misaligned, the short circuit of the gate contact electrode 92 with respect to the embedded electrode 43 is suppressed in the range where the gate contact electrode 92 is in contact with the edge portion insulator 60. That is, the semiconductor device 1 may include the gate contact electrode 92 that is mechanically connected to the edge portion insulator 60.

The semiconductor device 1 preferably includes the first silicide layer 75 (the second silicide layer 76) that faces the edge portion insulator 60 in the horizontal direction along the first main surface 3 at the surface layer portion of the first main surface 3. According to this structure, the edge portion insulator 60 functions as the short circuit blocking structure for the first silicide layer 75 (the second silicide layer 76) with respect to the embedded electrode 43. Therefore, the short circuit of the first silicide layer 75 (the second silicide layer 76) with respect to the embedded electrode 43 is suppressed.

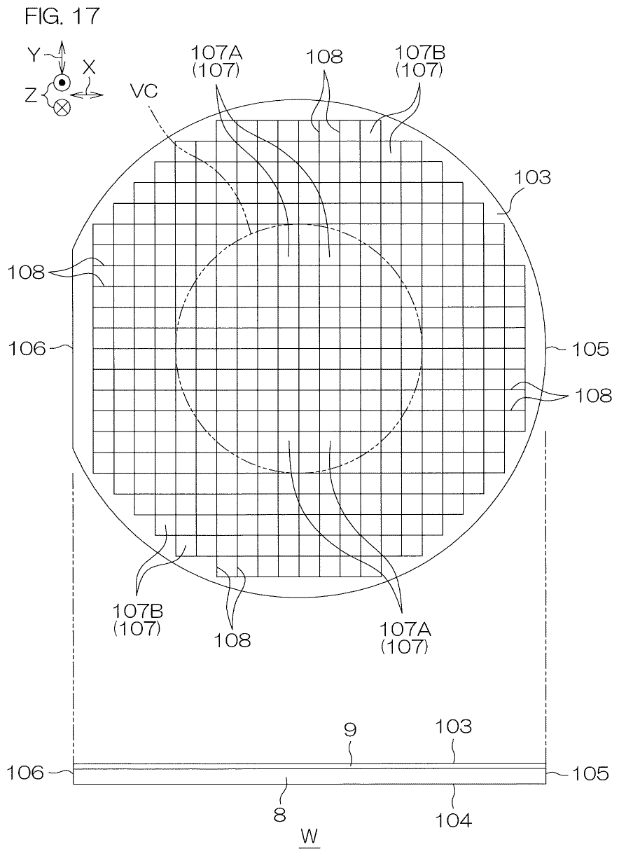

FIG. 17 is a schematic diagram showing a wafer W to be used for a manufacturing method for the semiconductor device 1. With reference to FIG. 17, the wafer W is formed in a flat disk shape in this embodiment. As a matter of course, the wafer W may be formed in a flat rectangular parallelepiped shape. The wafer W is made of silicon monocrystal in this embodiment.

The wafer W has a first wafer main surface 103 on one side, a second wafer main surface 104 on the other side, and a wafer side wall 105 connecting the first wafer main surface 103 and the second wafer main surface 104. The first wafer main surface 103 and the second wafer main surface 104 correspond to the first main surface 3 and the second main surface 4 of the chip 2, respectively.

The wafer W has a mark 106 on the wafer side wall 105, which indicates a crystal orientation of the Si monocrystal. The mark 106 may include either or both of an orientation flat and an orientation notch. The orientation flat is a cutout portion cut in a straight line in the plan view. The orientation notch is a cutout portion cut in a recessed shape toward a center of the wafer W in the plan view.

The mark 106 may include a single or a plurality of orientation flats. The orientation flat may extend in the first direction X or the second direction Y in the plan view. In FIG. 17, the orientation flat extends in the second direction Y in the plan view. As a matter of course, the mark 106 may include a first orientation flat extending in the first direction X, and a second orientation flat extending in the second direction Y.

The mark 106 may include a single or a plurality of orientation notches. The orientation notch may be a narrowing shape (tapered shape or triangular shape) toward the center of the wafer W in the plan view. The orientation notch may be recessed in the first direction X or the second direction Y in the plan view. As a matter of course, the mark 106 may include a first orientation notch recessed in the first direction X, and a second orientation notch recessed in the second direction Y. As a matter of course, the wafer W may be employed without the mark 106.

The wafer W includes the drain region 8 of the n-type that is formed in a surface layer portion of the second wafer main surface 104. The drain region 8 is formed in a layered shape extending along the second wafer main surface 104 in a whole region of the surface layer portion of the second wafer main surface 104, and is exposed from the second wafer main surface 104 and the wafer side wall 105. In this embodiment, the drain region 8 is formed by a semiconductor substrate (an Si substrate) of the n-type.

The wafer W includes the drift region 9 of the n-type that is formed in a surface layer portion of the first wafer main surface 103. The drift region 9 is formed in a layered shape extending along the first wafer main surface 103 in a whole region of the surface layer portion of the first wafer main surface 103, and is exposed from the first wafer main surface 103 and the wafer side wall 105. The drift region 9 is electrically connected to the drain region 8 inside the wafer W. The drift region 9 is formed by an epitaxial layer (an Si epitaxial layer) of the n-type in this embodiment.

The wafer W includes a plurality of device regions 107 and a plurality of planned cutting lines 108 that are set in the first wafer main surface 103. For example, the plurality of device regions 107 and the plurality of planned cutting lines 108 are defined (set) by alignment marks, etc., formed in the first wafer main surface 103. Each of the device regions 107 corresponds to a semiconductor device 1.

The device regions 107 are each set in a quadrangular shape in the plan view. The device regions 107 are arranged in a matrix pattern along the first direction X and the second direction Y in the plan view. The device regions 107 are each arranged at an interval inward from a peripheral edge of the first wafer main surface 103 in the plan view. The planned cutting lines 108 are set in a lattice shape extending along the first direction X and the second direction Y so as to partition the device regions 107.

In this embodiment, the device regions 107 include a plurality of first device regions 107A and a plurality of second device regions 107B. The first device regions 107A are the device regions 107 that are arranged in an inner portion of the first wafer main surface 103. The second device regions 107B are the device regions 107 that are arranged in a peripheral edge portion of the first wafer main surface 103.

The inner portion of the wafer W is defined by a portion located within an imaginary circle VC that has a radius of 25% of a diameter of the wafer W, drawn based on the center of the wafer W. The diameter of the wafer W is defined by a length of a chord that passes through the center of the wafer W outside the mark 106. On the other hand, the peripheral edge portion of the wafer W is defined by a portion located outside the imaginary circle VC. The device regions 107 located on a line of the imaginary circle VC are included in the first device region 107A.

The semiconductor devices 1 formed in the first device region 107A may be referred to as a first semiconductor device, and the semiconductor device 1 formed in the second device region 107B may be referred to as a second semiconductor device. The wafer W having a predetermined structure in a middle of the manufacturing process may be referred to as a “wafer structure,” a “wafer intermediate body,” etc.

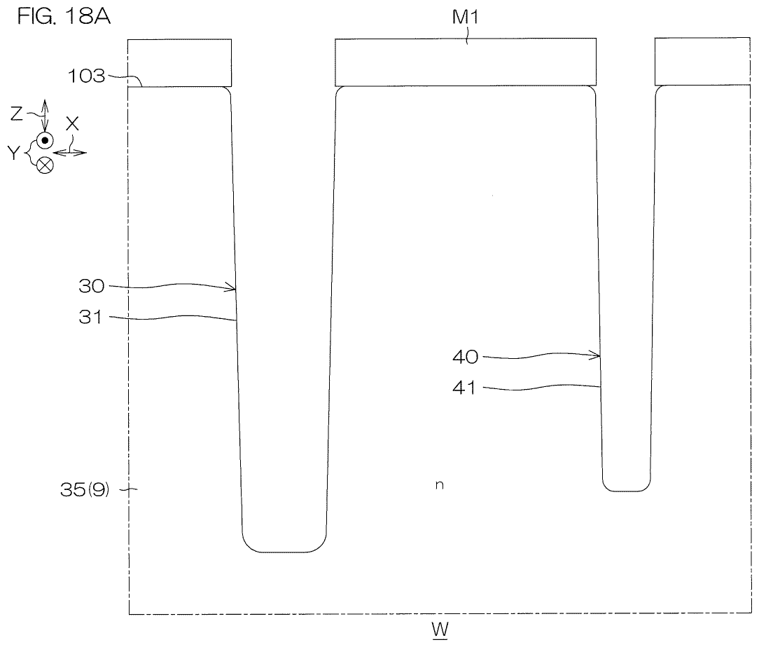

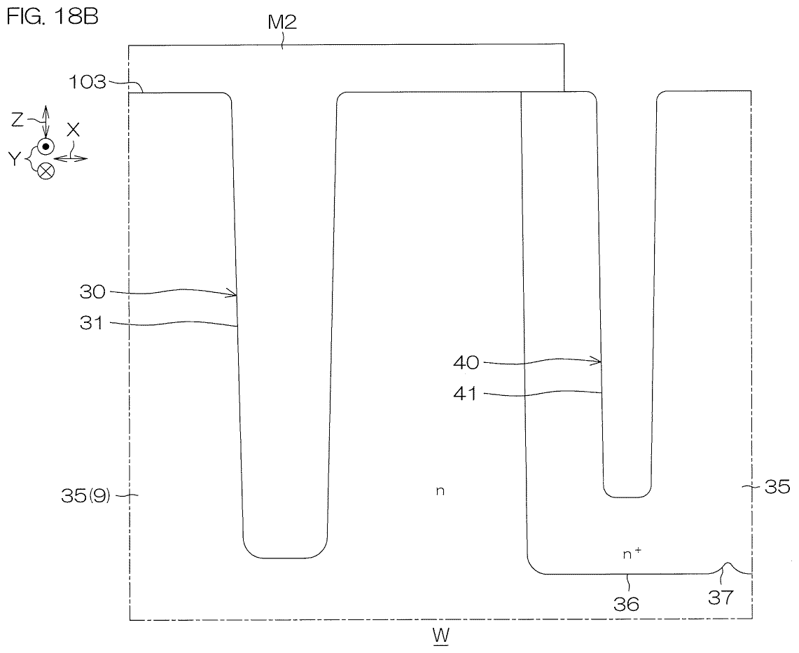

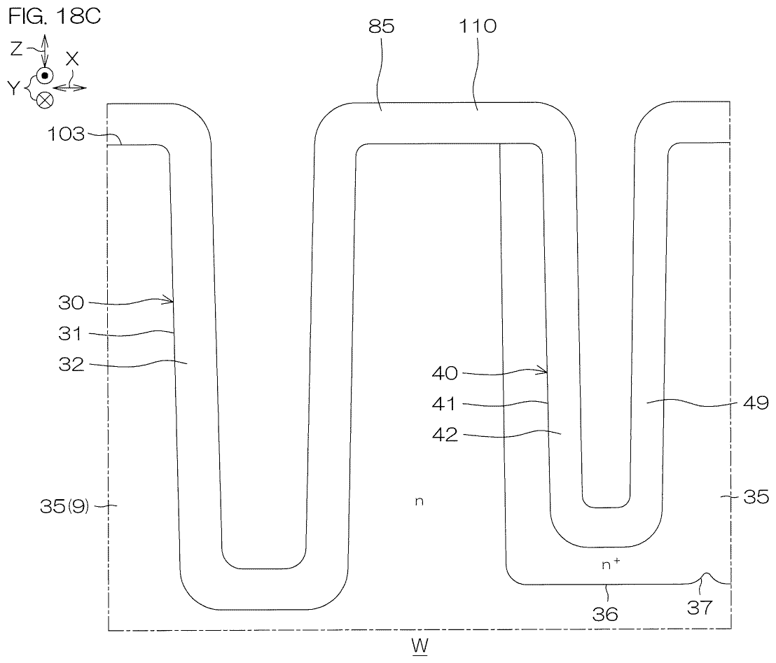

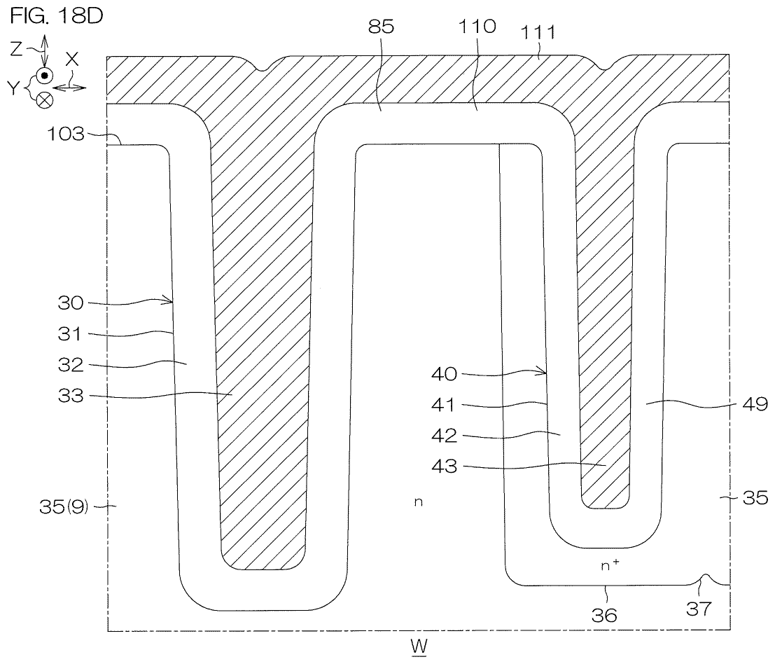

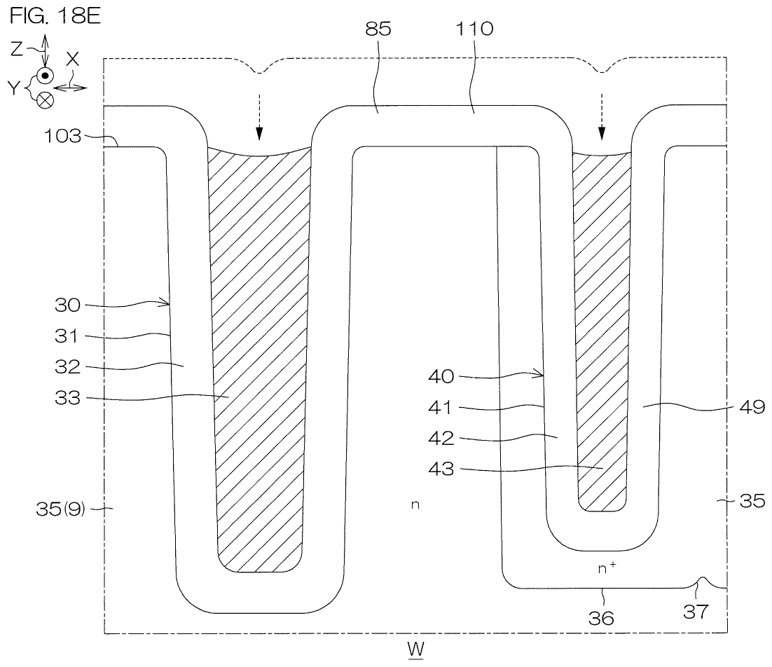

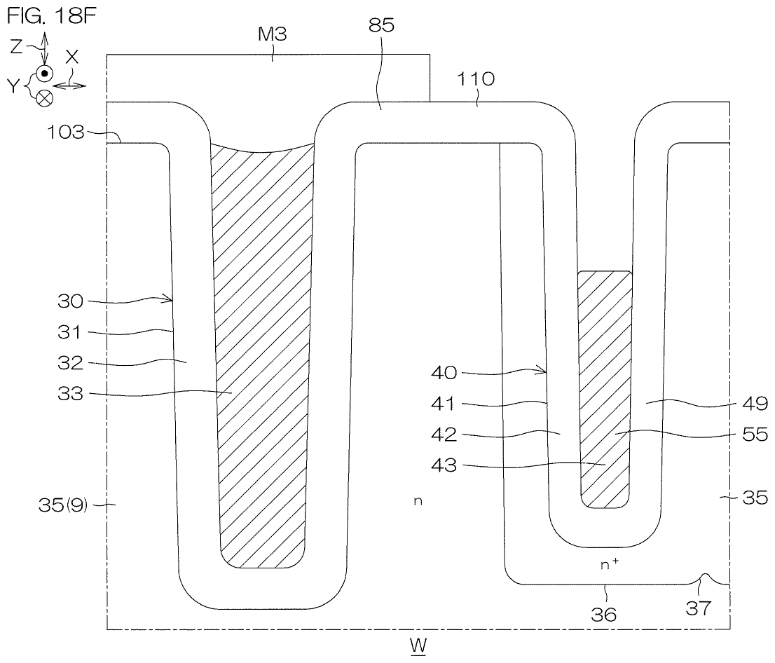

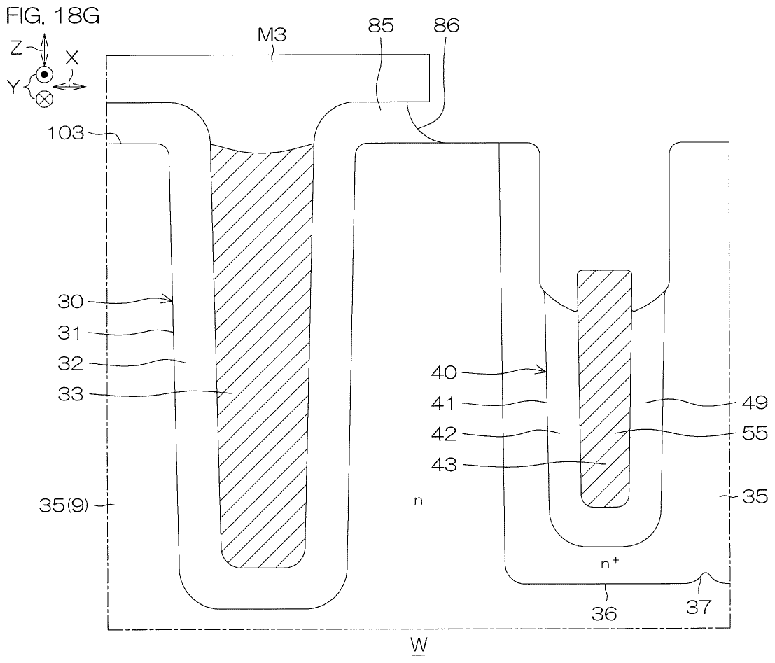

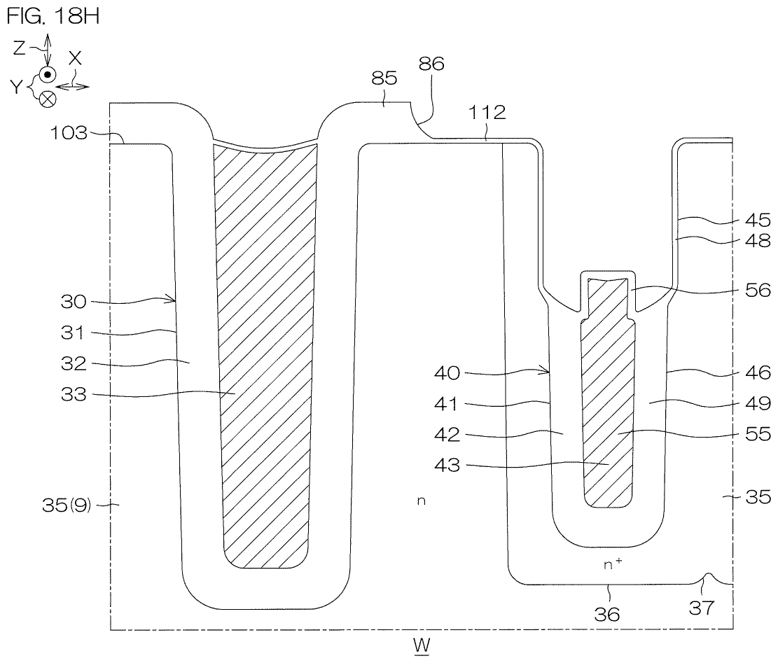

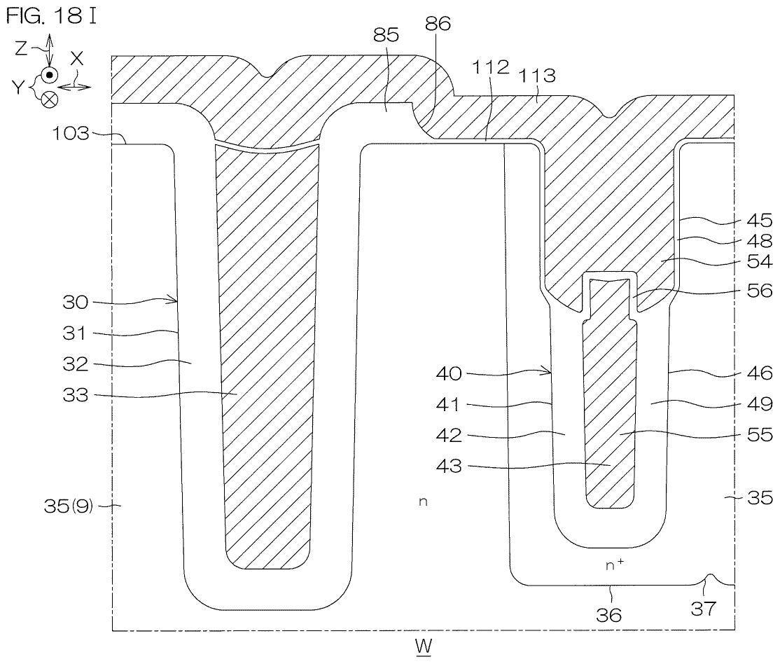

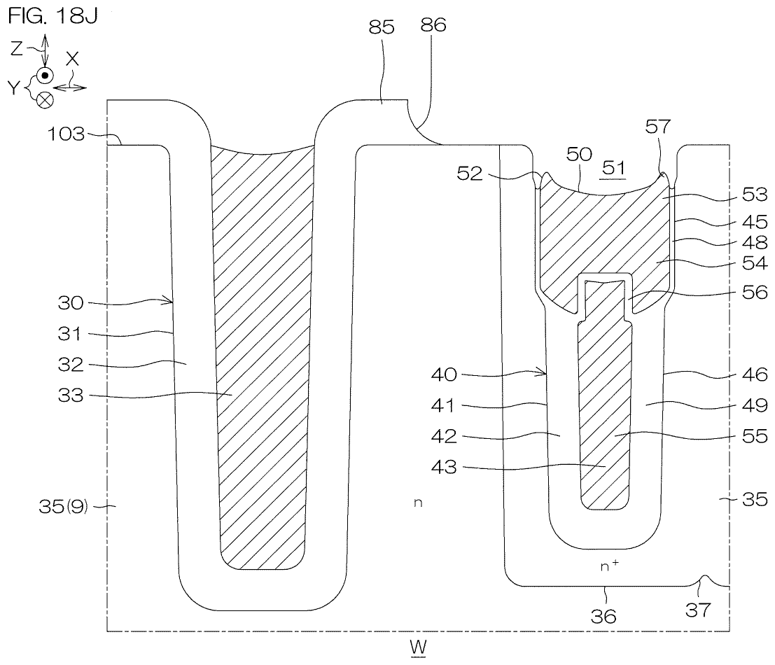

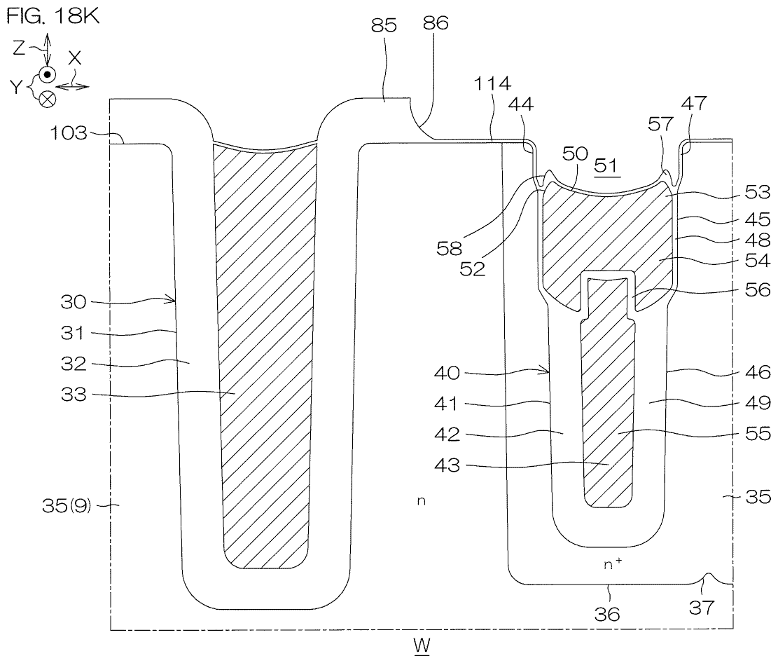

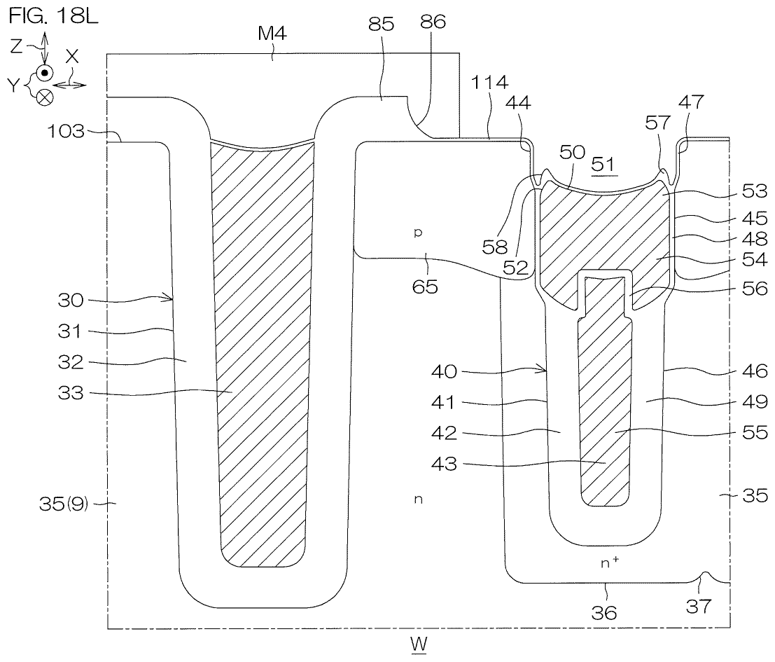

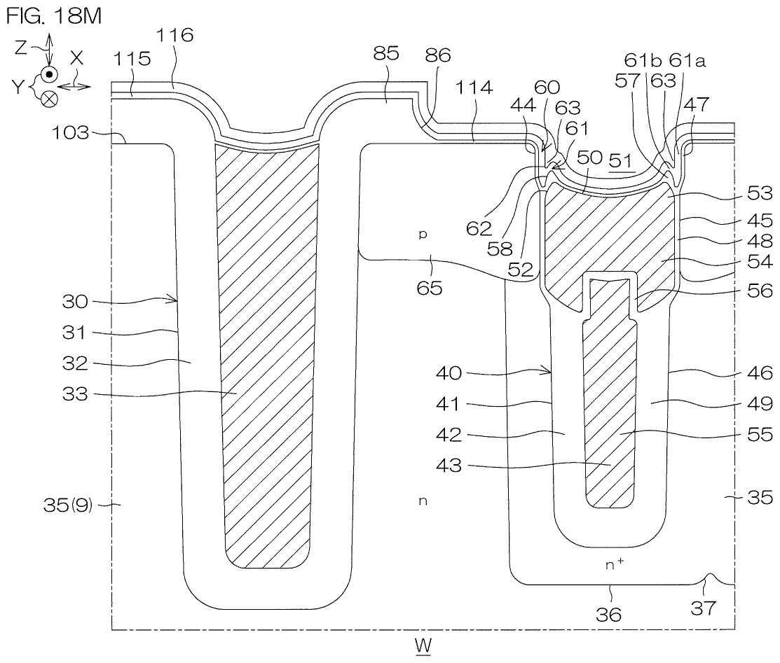

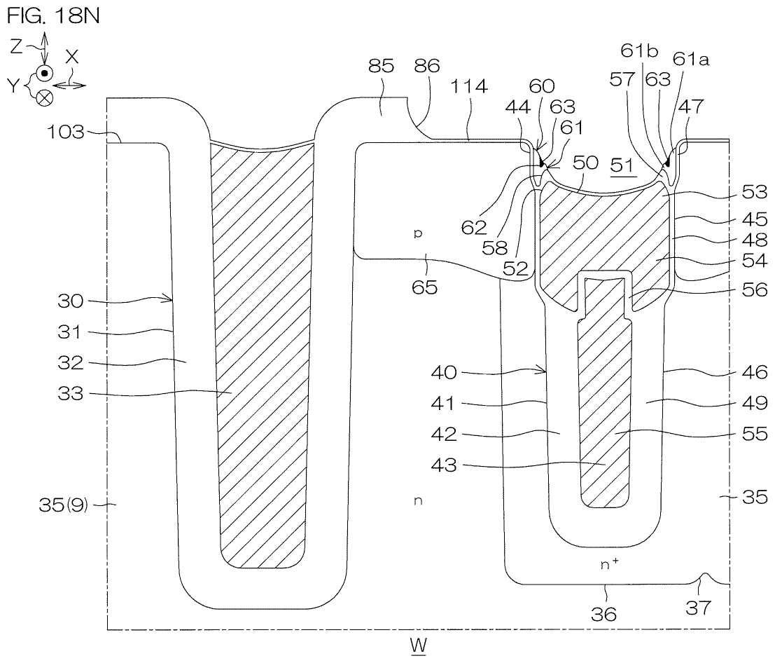

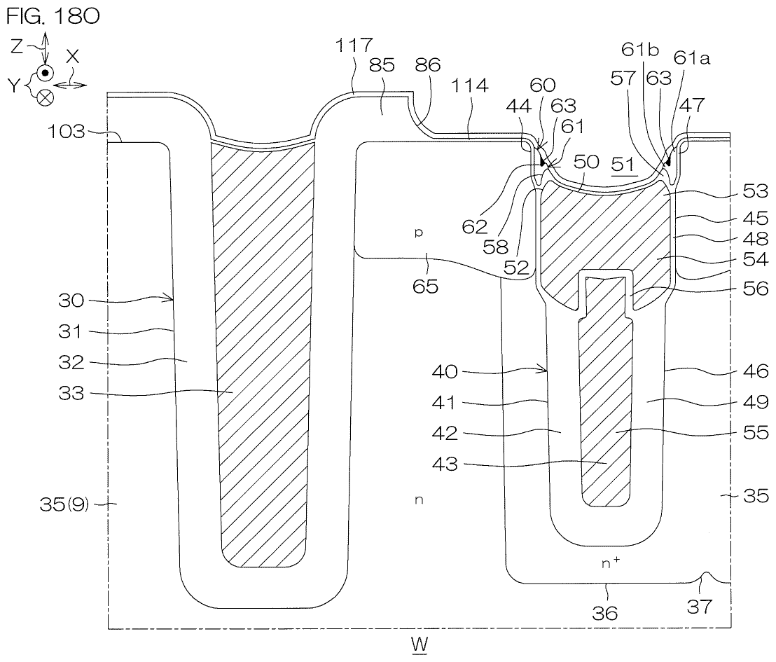

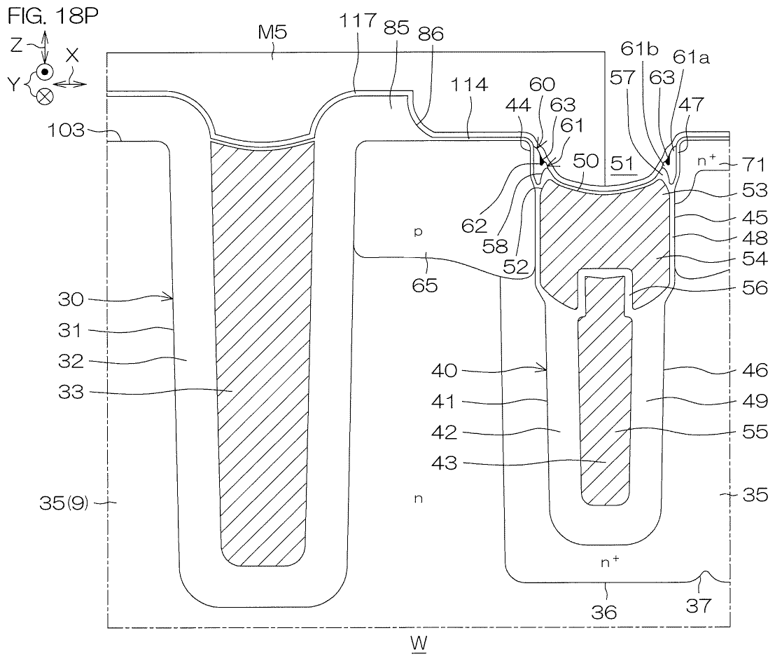

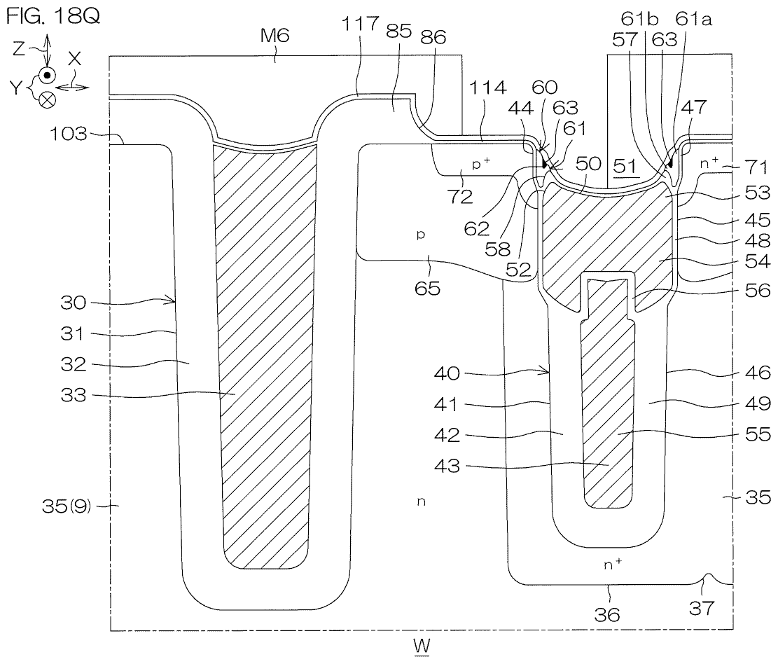

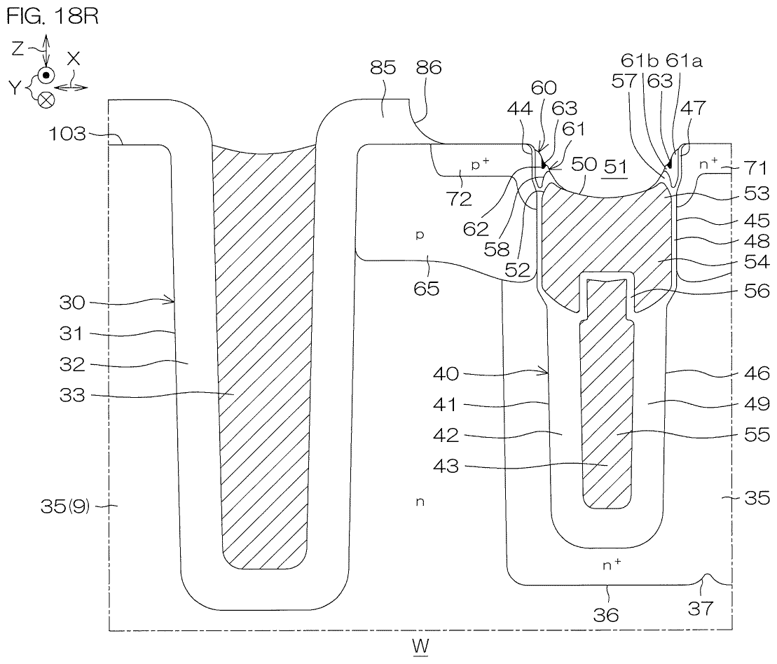

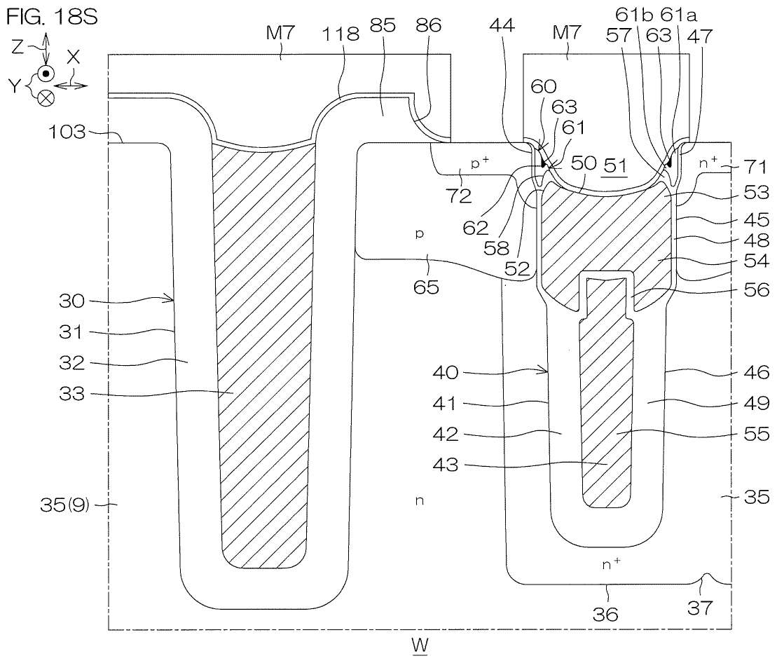

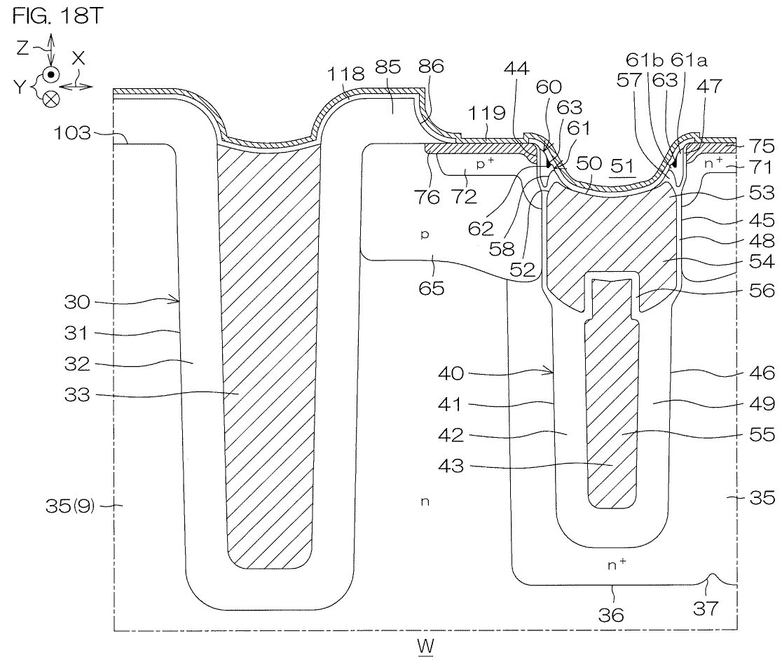

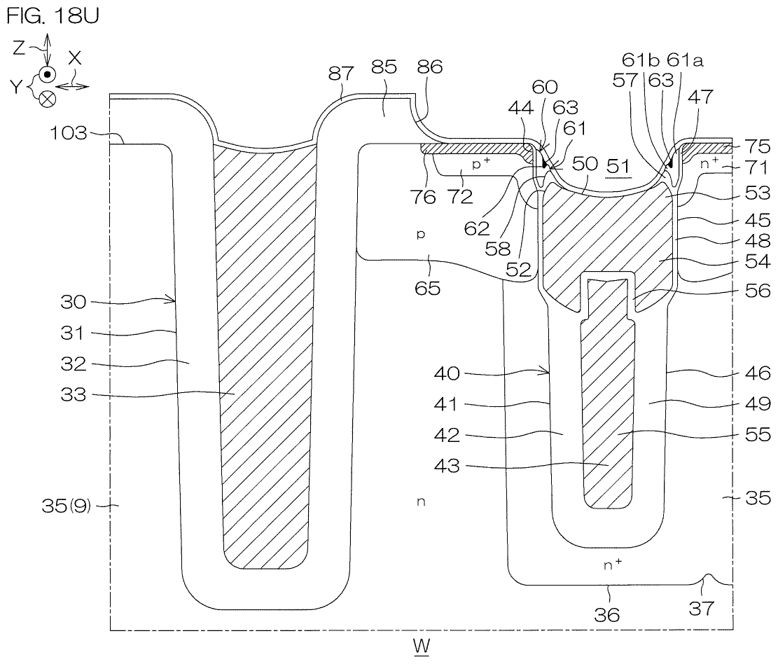

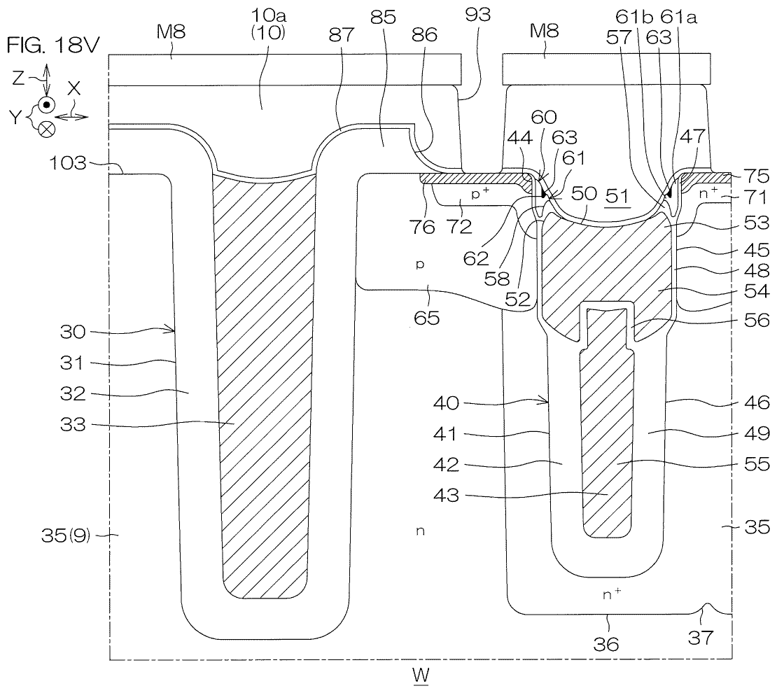

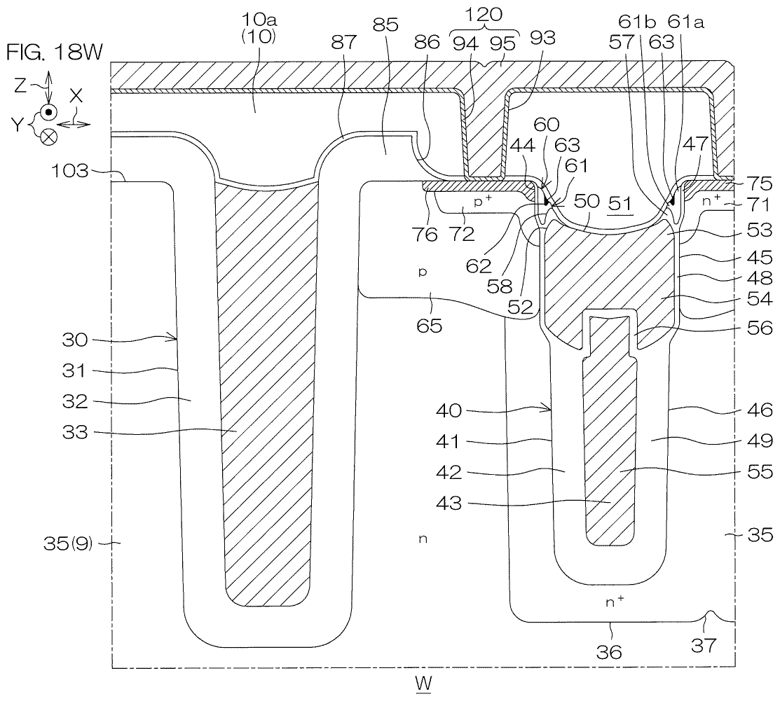

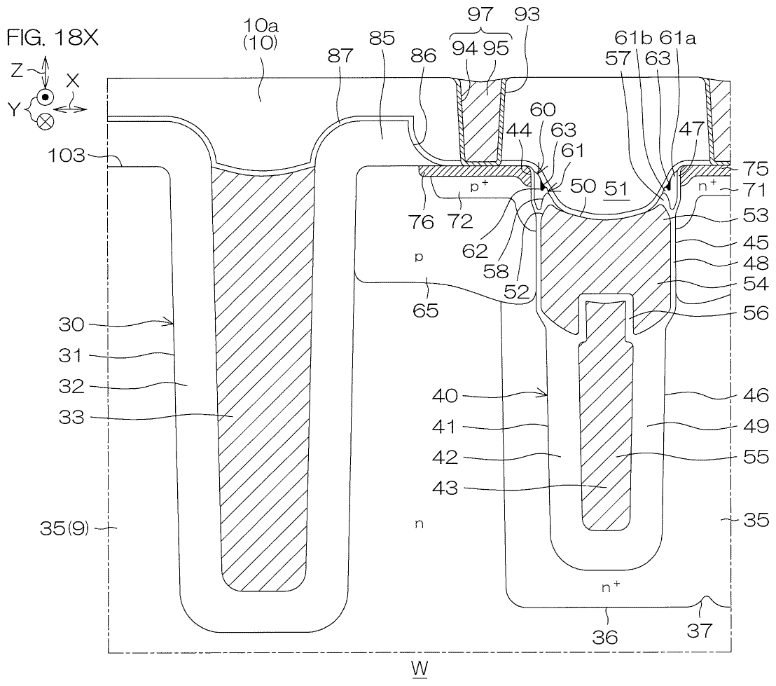

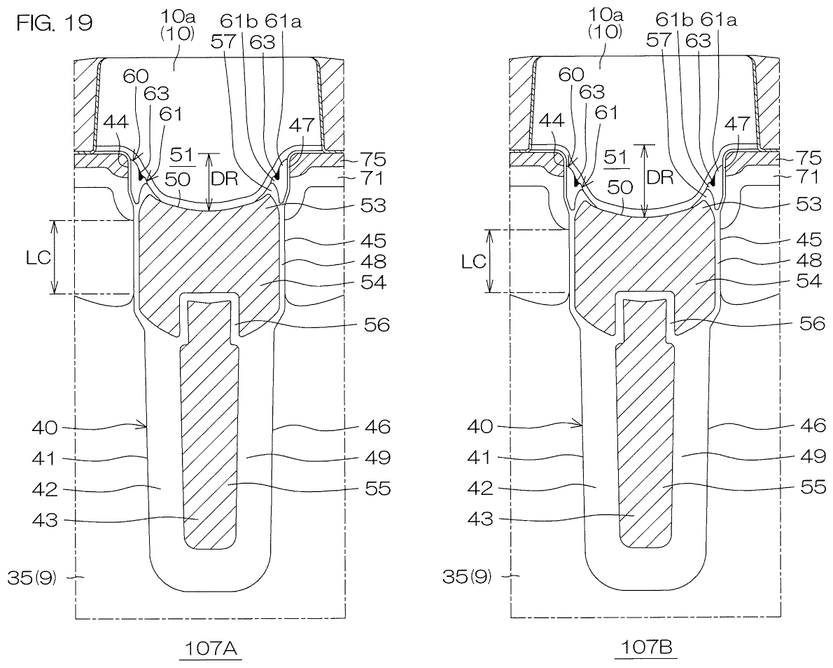

FIG. 18A to FIG. 18X are cross sectional views for describing the manufacturing method for the semiconductor device 1. FIG. 19 is a cross sectional view in which the gate structure 40 on the first device region 107A side and the gate structure 40 on the second device region 107B side in the wafer W (the wafer structure) are to be compared. In FIG. 18A to FIG. 18X, a region in which one of the separation structures 30 and one of the gate structures 40 are to be formed in one device region 107 is shown.

With reference to FIG. 18A, for manufacturing the semiconductor device 1, first, the aforementioned wafer W is prepared. Next, a first mask M1 having a predetermined pattern is formed on the first wafer main surface 103. The first mask M1 may be made of a hard mask that includes an inorganic insulating film. The first mask M1 has a layout that exposes regions where the separation trench 31, the trenches 41 and the connection trenches 81 are to be formed and covers the other region.

Next, unnecessary portions of the wafer W are removed by an etching method via the first mask M1. The etching method may be a wet etching method and/or a dry etching method. Through this step, the separation trench 31, the trenches 41 and the connection trenches 81 are formed in the first wafer main surface 103. The first mask M1 is removed thereafter.

Next, with reference to FIG. 18B, a second mask M2 having a predetermined pattern is formed on the first wafer main surface 103. The second mask M2 may be a resist mask (an ion implantation mask) that includes an organic insulating film. The second mask M2 has a layout that exposes a region where the high concentration drift region 35 is to be formed and covers the other region. Specifically, the second mask M2 exposes a region where the trenches 41 are formed and covers the other region.

Next, an n-type impurity is introduced into a surface layer portion of the first wafer main surface 103 by an ion implantation method via the second mask M2. In this embodiment, the n-type impurity is introduced into the surface layer portion of the first wafer main surface 103 from the first wafer main surface 103 and the wall surface of the trench 41 by an oblique ion implantation method.

In the oblique ion implantation method, a relative implantation angle of the n-type impurity with respect to the first wafer main surface 103 is to be adjusted, and the n-type impurity is to be introduced obliquely into the surface layer portion of the first wafer main surface 103.

That is, the wafer W may be supported in a horizontal posture or in an obliquely inclined posture with respect to the horizontal direction. In either case, the implantation angle of the n-type impurity with respect to the wafer W is to be adjusted. When a normal line with respect to the first wafer main surface 103 is taken as a reference angle (0°), the implantation angle (absolute value) of the n-type impurity with respect to the first wafer main surface 103 may be more than 0° and not more than 15°.

The implantation angle (absolute value) may have a value falling within at least one of ranges of more than 0° and not more than 3°, not less than 3° and not more than 6°, not less than 6° and not more than 9°, not less than 9° and not more than 12°, and not less than 12° and not more than 15°. The implantation angle (absolute value) is preferably not less than 2° and not more than 12°. The second mask M2 is removed after the introduction of the n-type impurity. The high concentration drift region 35 is formed through a diffusion process of the n-type impurity by a heat treatment method thereafter.

Next, with reference to FIG. 18C, a relatively thick first base insulating film 110 is formed on the first wafer main surface 103. The first base insulating film 110 serves as a base for the separation insulating film 32, the third insulating films 49 of the insulating films 42, the connection insulating films 82 and the field insulating film 85.

The first base insulating film 110 covers the first wafer main surface 103, the wall surface of the separation trench 31, the wall surfaces of the trenches 41 and the wall surfaces of the connection trenches 81 in a film shape. The first base insulating film 110 may be formed by a CVD method (Chemical Vapor Deposition method) and/or an oxidation treatment method. The oxidation method may be a wet oxidation treatment method and/or a thermal oxidation treatment method.

Next, with reference to FIG. 18D, a first base electrode 111 is formed on the first wafer main surface 103. The first base electrode 111 serves as a base for the separation electrode 33, the second electrodes 55 of the embedded electrodes 43, and the connection electrodes 83. The first base electrode 111 covers the first wafer main surface 103 across the first base insulating film 110, and is embedded in the separation trench 31, the trenches 41, and the connection trenches 81 across the first base insulating film 110. The first base electrode 111 includes conductive polysilicon and is formed by a CVD method in this embodiment.

Next, with reference to FIG. 18E, unnecessary portions of the first base electrode 111 are removed by an etching method. The etching method may be a wet etching method and/or a dry etching method. The first base electrode 111 is removed until a portion of the first base insulating film 110 that covers the first wafer main surface 103 is exposed. Through this step, the separation electrode 33 and the connection electrodes 83 are formed.

Next, with reference to FIG. 18F, a third mask M3 having a predetermined pattern is formed on the first base insulating film 110. The third mask M3 may be a resist mask that includes an organic insulating film. The third mask M3 has a layout that exposes portions of the first base electrode 111 that are buried in the trenches 41, and covers a portion of the first base electrode 111 that is buried in the separation trench 31 (that is, the separation electrode 33) and portions of the first base electrode 111 that are buried in the connection trenches 81 (that is, the connection electrodes 83).

Next, unnecessary portions of the first base electrode 111 are removed by an etching method via the third mask M3. The etching method may be a wet etching method and/or a dry etching method. Through this step, the portions of the first base electrode 111 that are embedded in the trenches 41 are further dug down and the second electrodes 55 of the embedded electrodes 43 are thereby formed.

Next, with reference to FIG. 18G, unnecessary portions of the first base insulating film 110 are removed by an etching method via the third mask M3. The etching method may be a wet etching method and/or a dry etching method. The first base insulating film 110 is removed until etching surfaces is located on the side of the bottom walls of the trenches 41 with respect to the upper end portions of the second electrodes 55 of the embedded electrodes 43. Through this step, the separation insulating film 32, the third insulating films 49 of the insulating films 42, the connection insulating films 82 and the field insulating film 85 are formed. The third mask M3 is removed thereafter.

Next, with reference to FIG. 18H, a second base insulating film 112 thinner than the first base insulating film 110 is formed on the first wafer main surface 103. The second base insulating film 112 serves as a base for the second insulating films 48 and the intermediate insulating films 56 of the insulating films 42. The second base insulating film 112 may be formed by a CVD method and/or an oxidation treatment method. The oxidation treatment method may be a wet oxidation treatment method and/or a thermal oxidation treatment method.

The second base insulating film 112 is formed by the oxidation treatment method (specifically the thermal oxidation treatment method) in this embodiment. The second base insulating film 112 covers portions of the wall surfaces of the trenches 41 that are exposed from the third insulating films 49, and portions (the upper end portions) of the second electrodes 55 that are exposed from the third insulating films 49 in a film shape. Also, the second base insulating film 112 covers a portion of the separation electrode 33 that is exposed from the separation insulating film 32 in a film shape, and covers portions of the connection electrodes 83 that are exposed from the connection insulating films 82 in a film shape.

Oxidation in the portions of the second base insulating films 112 that covers the wall surfaces of the trenches 41 progresses from the wall surfaces of the trenches 41 toward the inside of the wafer W. Through this step, relatively wide second trench portions 45 are defined on the side of the openings of the trenches 41, and third trench portions 46 narrower than the second trench portions 45 are defined on the side of the bottom walls of the trenches 41.

Next, with reference to FIG. 18I, a second base electrode 113 is formed on the second wafer main surface 104. The second base electrode 113 serves as a base for the first electrodes 54 of the embedded electrodes 43. The second base electrode 113 covers the first wafer main surface 103, the separation electrode 33 and the connection electrodes 83 across the second base insulating film 112, and is embedded in the side of the openings of the trenches 41 across the second base insulating film 112. The second base electrode 113 includes conductive polysilicon and is formed by a CVD method in this embodiment.

Next, with reference to FIG. 18J, unnecessary portions of the second base electrode 113 are removed by an etching method. The etching method may be a wet etching method and/or a dry etching method. The second base electrode 113 is removed until etching surfaces are located on the side of the bottom walls of the trenches 41 with respect to the first wafer main surface 103. Through this step, the embedded electrodes 43 each including the first electrode 54 and the second electrode 55 are formed.

Next, unnecessary portions of the second base insulating film 112 is removed by an etching method. Specifically, in the second base insulating film 112, the portion that covers the first wafer main surface 103, the portion that covers the separation electrode 33, the portion that covers the connection electrode 83, and the portions that are exposed from the embedded electrodes 43 (the first electrodes 54) in the trench 41 are removed. The etching method may be a wet etching method and/or a dry etching method. The unnecessary portions of the second base insulating film 112 may be removed simultaneously with the second base electrode 113 in the step of removing the second base electrode 113.

The embedded electrodes 43 have electrode surfaces 50 located on the side of the bottom walls of the trenches 41 with respect to the first wafer main surface 103. The electrode surfaces 50 define the opening recesses 51 with the side walls of the trenches 41 at the side of the openings of the trenches 41. With reference to FIG. 19, the recess depth DR of the opening recess 51 on the second device region 107B side differs in a value from the recess depth DR of the opening recess 51 on the first device region 107A side due to process deviations (in-plane deviations) occurring within a plane of the first wafer main surface 103.

Specifically, the recess depth DR on the second device region 107B side becomes larger than the recess depth DR on the first device region 107A side. The recess depth DR on the first device region 107A side may be not less than 50 nm and not more than 300 nm. The recess depth DR on the second device region 107B side may be not less than 300 nm and not more than 600 nm.

The embedded electrode 43 has the recess edge portion 52 that is recessed toward the bottom wall of the trench 41 at the edge portion of the electrode surface 50 along the side wall of the trench 41. The embedded electrode 43 has the protruding edge portion 53 protruding toward the opening side of the trench 41 at the edge portion of the electrode surface 50. As it is aforementioned, the recess depth DR of the opening recess 51 on the second device region 107B side is greater than the recess depth DR of the opening recess 51 on the first device region 107A side.

Therefore, a depth position of the recess edge portion 52 on the second device region 107B side is placed at a region lower than a depth position of the recess edge portion 52 on the first device region 107A side. Also, a depth position of a tip portion of the protruding edge portion 53 on the second device region 107B side is placed at a region lower than a depth position of a tip portion of the protruding edge portion 53 on the first device region 107A side. The descriptions of the electrode surface 50, the opening recess 51, the recess edge portion 52 and the protruding edge portion 53 have been described above and will be omitted.

Next, with reference to FIG. 18K, a third insulating film 114 thinner than the second base insulating film 112 is formed on the first wafer main surface 103. The third insulating film 114 serves as a base for the first insulating films 47 of the insulating films 42. The third insulating film 114 may be formed by a CVD method and/or an oxidation treatment method. The oxidation treatment method may be a wet oxidation treatment method and/or a thermal oxidation treatment method.

The third insulating film 114 is formed by the oxidation treatment method (specifically the thermal oxidation treatment method) in this embodiment. The third insulating film 114 covers, a portion that is exposed from the field insulating film 85 in the first wafer main surface 103, portions of the wall surfaces of the trenches 41 that are exposed from the second insulating films 48, and the electrode surfaces 50 of the embedded electrodes 43 (the first electrodes 54) in a film shape. Also, the third insulating film 114 covers a portion of the separation electrode 33 that is exposed from the separation insulating film 32 in a film shape, and covers portions of the connection electrodes 83 that are exposed from the connection insulating films 82 in a film shape.

Oxidation in the portions of the third insulating film 114 that cover the wall surfaces of the trenches 41 progresses from the wall surfaces of the trenches 41 toward the inside of the wafer W. Through this step, relatively wide first trench portions 44 are defined on the side of the openings of the trenches 41, and the second trench portions 45 narrower than the first trench portions 44 are defined on the side of the bottom walls of the trenches 41.

The third insulating film 114 may be formed as a part of the recess insulating film 57. The third insulating film 114 defines the insulating recess edge portion 58 that conforms to the recess edge portion 52 between the wall surface of the trench 41 and the third insulating film 114 within the trench 41. The description of the insulating recess edge portion 58 is omitted as it has been described above.

Next, with reference to FIG. 18L, a fourth mask M4 having a predetermined pattern is formed on the first wafer main surface 103. The fourth mask M4 may be a resist mask (an ion implantation mask) that includes an organic insulating film. The fourth mask M4 has a layout that exposes regions where the body regions 65 are to be formed and covers the other regions. Specifically, the fourth mask M4 exposes a region where the trenches 41 are formed and covers the other regions.

Next, a p-type impurity is introduced into the surface layer portion of the first wafer main surface 103 by an ion implantation method via the fourth mask M4. In this embodiment, the p-type impurity is introduced into the surface layer portion of the first wafer main surface 103 from the first wafer main surface 103 and the side walls of the trenches 41 by an oblique ion implantation method.

In the oblique ion implantation method, a relative implantation angle of the p-type impurity with respect to the first wafer main surface 103 is to be adjusted, and the p-type impurity is to be introduced obliquely into the surface layer portion of the first wafer main surface 103.

That is, the wafer W may be supported in a horizontal posture or in an obliquely inclined posture with respect to the horizontal direction. In either case, the implantation angle of the p-type impurity with respect to the wafer W is to be adjusted. When the normal line with respect to the first wafer main surface 103 is taken as a reference angle (0°), the implantation angle (absolute value) of the p-type impurity with respect to the first wafer main surface 103 may be not less than 1° and not more than 10°.

The implantation angle (absolute value) may have a value falling within at least one of ranges of not less than 1° and not more than 2.5°, not less than 2.5° and not more than 5°, not less than 5° and not more than 7.5°, not less than 7.5° and not more than 10°. The implantation angle (absolute value) is preferably not less than 5° and not more than 10°. The fourth mask M4 is removed after the introduction of the p-type impurity. The body regions 65 are formed through a diffusion process of the p-type impurity by a heat treatment method thereafter.

Next, with reference to FIG. 18M, a fourth base insulating film 115 is formed on the first wafer main surface 103. The fourth base insulating film 115 serves as a base for the edge insulating film 61 of the edge portion insulator 60. The fourth base insulating film 115 covers the third insulating film 114 in a film shape. Specifically, the fourth base insulating film 115 covers the first wafer main surface 103, the separation electrode 33, the wall surfaces of the trenches 41, the electrode surfaces 50 of the embedded electrodes 43, the connection electrodes 83 and the field insulating film 85 in a film shape across the third insulating film 114.

The fourth base insulating film 115 includes an insulator that has properties different from those of the insulating film 42 (the first insulating film 47) in this embodiment. Specifically, the fourth base insulating film 115 includes an insulator that has an etching rate different from an etching rate of the insulating film 42 (the first insulating film 47). The fourth base insulating film 115 includes the nitride film (specifically the silicon nitride film) and is formed by a CVD method in this embodiment.

The fourth base insulating film 115 covers the side walls of the trenches 41 and the wall surfaces of the recess edge portions 52 as the edge insulating films 61 of the edge portion insulators 60 in a film shape within the trenches 41. Also, the fourth base insulating film 115 includes the first extension portions 61a, the second extension portions 61b and the groove portions 62 in portions that are to be the edge insulating films 61. The descriptions of the portions of the fourth base insulating film 115 that are to be the edge insulating films 61 are omitted as they have been described above. Also, the descriptions of the first extension portion 61a, the second extension portion 61b and the groove portion 62 in the fourth base insulating film 115 are omitted as they have been described above.

Next, a fifth base insulating film 116 is formed on the first wafer main surface 103. The fifth base insulating film 116 serves as a base of the insulating buried object 63 of the edge portion insulator 60. The fifth base insulating film 116 fills the groove portions 62 and covers the fourth base insulating film 115 in a film shape. Specifically, the fifth base insulating film 116 covers the first wafer main surface 103, the separation electrode 33, the wall surfaces of the trenches 41, the electrode surfaces 50 of the embedded electrodes 43, the connection electrodes 83 and the field insulating film 85 in a film shape across the third insulating film 114 and the fourth base insulating film 115.

The fifth base insulating film 116 includes an insulator that has properties different from those of the fourth base insulating film 115 in this embodiment. Specifically, the fifth base insulating film 116 includes an insulator that has an etching rate different from the etching rate of the fourth base insulating film 115. The fifth base insulating film 116 includes the tetraethyl orthosilicate film (TEOS film) and is formed by a CVD method in this embodiment.

Next, with reference to FIG. 18N, unnecessary portions of the fifth base insulating film 116 are removed by an etching method. Specifically, this step includes a step of selectively removing portions of the fifth base insulating film 116 that are located outside the groove portions 62 so as to leave portions of the fifth base insulating film 116 that are located within the groove portions 62.

The etching method may be a wet etching method and/or a dry etching method. The etching method is preferably an anisotropic etching method. The etching method is preferably an RIE (Reactive Ion Etching method) as an example of an anisotropic dry etching method. Through this step, the portions of the fifth base insulating film 116 that are located outside the groove portions 62 are selectively removed, and the portions of the fifth base insulating film 116 that are located within the groove portions 62 remain within the groove portions 62 as the insulating buried objects 63.

Next, unnecessary portions of the fourth base insulating film 115 are removed by an etching method. The etching method may be a wet etching method and/or a dry etching method. The etching method is preferably an anisotropic etching method. The etching method is preferably an RIE as an example of an anisotropic dry etching method.

This step includes a step of selectively removing portions of the fourth base insulating film 115 other than portions that cover the side walls of the trenches 41 so as to leave portions of the fourth base insulating film 115 that cover the side walls of the trenches 41. That is, this step includes a step of removing portions of the fourth base insulating film 115 other than the portions that serve as the edge insulating films 61.

The fifth base insulating film 116 (the insulating buried object 63) has an etching rate different from that of the fourth base insulating film 115. Therefore, the fifth base insulating film 116 (the insulating buried object 63) remains buried in the groove portion 62 during the step of removing the fourth base insulating film 115. Through this step, the edge portion insulator 60 that has the laminated structure including the edge insulating film 61 and the insulating buried object 63 is formed. The edge portion insulator 60 suppresses conductive residues and insulating residues from intruding into the recess edge portion 52 (the insulating recess edge portion 58) in subsequent steps.

Next, with reference to FIG. 180, a first barrier insulating film 117 is formed on the first wafer main surface 103. The first barrier insulating film 117 serves as a base of the insulating buried object 63 of the edge portion insulator 60. The first barrier insulating film 117 covers the separation structure 30, the connection structures 80 and the field insulating film 85 on the first wafer main surface 103, and covers the electrode surfaces 50 and the edge portion insulators 60 within the trenches 41. The first barrier insulating film 117 covers the electrode surfaces 50 across the third insulating film 114 in the trenches 41 in this embodiment.

The first barrier insulating film 117 includes an insulator that has properties different from those of the edge insulating film 61 (the fourth base insulating film 115) in this embodiment. Specifically, the first barrier insulating film 117 includes an insulator that has an etching rate different from the etching rate of the edge insulating film 61. The first barrier insulating film 117 includes the tetraethyl orthosilicate film (TEOS film) and is formed by a CVD method in this embodiment.

Next, with reference to FIG. 18P, a fifth mask M5 having a predetermined pattern is formed on the first wafer main surface 103. The fifth mask M5 may be a resist mask (an ion implantation mask) that includes an organic insulating film. The fifth mask M5 has a layout that exposes regions where the source regions 71 are to be formed and covers the other regions. Specifically, the fifth mask M5 exposes regions where the trenches 41 are formed and covers the other regions.

Next, an n-type impurity is introduced into the surface layer portion of the first wafer main surface 103 by an ion implantation method via the fifth mask M5. In this embodiment, the n-type impurity is introduced into the surface layer portion of the first wafer main surface 103 from the first wafer main surface 103 and the wall surfaces of the trenches 41 by an oblique ion implantation method. The n-type impurity toward the side wall of the trench 41 is implanted into the surface layer portion of the first wafer main surface 103 through the insulating film 42 (the first insulating film 47), the edge portion insulator 60 and the first barrier insulating film 117.

With reference to FIG. 19, as it is aforementioned, the depth of the recess edge portion 52 (the opening recess 51) on the second device region 107B side is greater than the depth of the recess edge portion 52 (the opening recess 51) on the first device region 107A side. Therefore, in a case in which the edge portion insulator 60 does not exist, an introduction depth of the n-type impurity on the second device region 107B side becomes greater than an introduction depth of the n-type impurity on the first device region 107A side due to the relatively deep recess edge portion 52 (the opening recess 51).

As a result, a depth of the source region 71 on the second device region 107B side becomes greater than a depth of the source region 71 on the first device region 107A side, and the channel length LC on the second device region 107B side becomes shorter than the channel length

LC on the first device region 107A side. That is, an in-plane deviation occurs in the depths of the source regions 71 between the first device region 107A and the second device region 107B, and therefore an in-plane deviation occurs in the electrical characteristics of the multiple semiconductor devices 1 between the first device region 107A and the second device region 107B.

In contrast, in a case in which the n-type impurity is introduced into the surface layer portion of the first wafer main surface 103 via the edge portion insulator 60, the introduction of the n-type impurity is partially shielded by the edge portion insulator 60, and therefore the introduction depth of the n-type impurity is limited by the edge portion insulator 60. That is, the n-type impurity is suppressed from being introduced deeply into both of the first device region 107A and the second device region 107B.

As a result, the channel length LC on the second device region 107B side is suppressed from becoming shorter than the channel length LC on the first device region 107A side. That is, the in-plane deviation of the source regions 71 that possibly occurs between the first device region 107A and the second device region 107B is suppressed, and therefore the in-plane deviation of the electrical characteristics of the semiconductor devices 1 is suppressed.

In the oblique ion implantation method, a relative implantation angle of the n-type impurity with respect to the first wafer main surface 103 is to be adjusted, and the n-type impurity is to be introduced obliquely into the surface layer portion of the first wafer main surface 103. That is, the wafer W may be supported in a horizontal posture or in an obliquely inclined posture with respect to the horizontal direction. In either case, the implantation angle of the n-type impurity with respect to the wafer W is to be adjusted. When the normal line with respect to the first wafer main surface 103 is taken as a reference angle (0°), the implantation angle (absolute value) of the n-type impurity with respect to the first wafer main surface 103 may be not less than 5° and not more than 35°.

The implantation angle (absolute value) may have a value falling within at least one of ranges of not less than 5° and not more than 10°, not less than 10° and not more than 15°, not less than 15° and not more than 20°, not less than 20° and not more than 25°, not less than 25° and not more than 30°, and not less than 30° and not more than 35°. The implantation angle (absolute value) is preferably not less than 10° and not more than 25°. The second mask M2 is removed after the introduction of the n-type impurity. The source regions 71 are formed through a step of diffusing the n-type impurity by a heat treatment method thereafter.

Next, with reference to FIG. 18Q, a sixth mask M6 having a predetermined pattern is formed on the first wafer main surface 103. The sixth mask M6 may be a resist mask (an ion implantation mask) that includes an organic insulating film. The sixth mask M6 has a layout that exposes regions where the contact regions 72 are to be formed and covers the other regions. Specifically, the sixth mask M6 exposes a region where the trenches 41 are formed and covers the other regions.

Next, a p-type impurity is introduced into the surface layer portion of the first wafer main surface 103 by an ion implantation method via the sixth mask M6. In this embodiment, the p-type impurity is introduced into the surface layer portion of the first wafer main surface 103 from the first wafer main surface 103 and the wall surfaces of the trenches 41 by an oblique ion implantation method. The p-type impurity toward the side wall of the trench 41 is implanted into the surface layer portion of the first wafer main surface 103 via the insulating film 42 (the first insulating film 47), the edge portion insulator 60 and the first barrier insulating film 117.

With reference to FIG. 19, as it is aforementioned, the depth of the recess edge portion 52 (the opening recess 51) on the second device region 107B side is greater than the depth of the recess edge portion 52 (the opening recess 51) on the first device region 107A side. Therefore, in a case in which the edge portion insulator 60 does not exist, an introduction depth of the p-type impurity on the second device region 107B side becomes greater than an introduction depth of the p-type impurity on the first device region 107A side due to the relatively deep recess edge portion 52 (the opening recess 51).

As a result, a depth of the contact region 72 on the second device region 107B side becomes greater than a depth of the contact region 72 on the first device region 107A side. That is, an in-plane deviation occurs in the depths of the contact regions 72 between the first device region 107A and the second device region 107B, and therefore an in-plane deviation occurs in the electrical characteristics of the semiconductor devices 1 between the first device region 107A and the second device region 107B. In contrast, in a case in which the p-type impurity is introduced into the surface layer

portion of the first wafer main surface 103 via the edge portion insulator 60, the introduction of the p-type impurities is partially shielded by the edge portion insulator 60, and therefore the introduction depth of the p-type impurity is limited by the edge portion insulator 60. That is, the p-type impurity is suppressed from being introduced deeply into both of the first device region 107A and the second device region 107B. That is, the in-plane deviation of the contact regions 72 that possibly occurs between the first device region 107A and the second device region 107B is suppressed, and therefore the in-plane deviation of the electrical characteristics of the semiconductor devices 1 are suppressed.

In the oblique ion implantation method, a relative implantation angle of the p-type impurity with respect to the first wafer main surface 103 is to be adjusted, and the p-type impurity is to be introduced obliquely into the surface layer portion of the first wafer main surface 103. That is, the wafer W may be supported in a horizontal posture or in an obliquely inclined posture with respect to the horizontal direction. In either case, the implantation angle of the p-type impurity with respect to the wafer W is to be adjusted. When the normal line with respect to the first wafer main surface 103 is taken as a reference angle (0°), the implantation angle (absolute value) of the p-type impurity with respect to the first wafer main surface 103 may be not less than 5° and not more than 35°.

The implantation angle (absolute value) may have a value falling within at least one of ranges of not less than 5° and not more than 10°, not less than 10° and not more than 15°, not less than 15° and not more than 20°, not less than 20° and not more than 25°, not less than 25° and not more than 30°, and not less than 30° and not more than 35°. The implantation angle (absolute value) is preferably not less than 10° and not more than 25°.

The sixth mask M6 is removed after the introduction of the p-type impurity. The contact region 72 are formed through a step of diffusing the p-type impurity by a heat treatment method thereafter. The step of forming the contact regions 72 may be performed prior to the step of forming the source regions 71.

Next, with reference to FIG. 18R, the first barrier insulating film 117 is removed. This step may include a step of partially removing the third insulating film 114, and a step of partially removing the field insulating film 85. The step of forming the first barrier insulating film 117 is not necessarily performed and may be omitted if necessary. In this case, the source regions 71 and the contact regions 72 are introduced into the surface layer portion of the first wafer main surface 103 via the edge portion insulator 60.

Next, with reference to FIG. 18S, a second barrier insulating film 118 is formed on the first wafer main surface 103. The second barrier insulating film 118 covers the separation structure 30, the connection structures 80 and the field insulating film 85 on the first wafer main surface 103, and covers the electrode surfaces 50 and the edge portion insulators 60 within the trenches 41. The second barrier insulating film 118 includes an insulator that has properties different from those of the edge insulating film 61 in this embodiment.

Specifically, the second barrier insulating film 118 includes an insulator that has an etching rate different from the etching rate of the edge insulating film 61. The second barrier insulating film 118 includes the oxide film and is formed by a CVD method in this embodiment. The second barrier insulating film 118 may include an undoped silicon oxide film. The undoped silicon oxide film may be referred to as a USG (Undoped Silicate Glass) film.

Next, a seventh mask M7 having a predetermined pattern is formed on the second barrier insulating film 118. The seventh mask M7 may be a resist mask (an ion implantation mask) that includes an organic insulating film. The seventh mask M7 has a layout that exposes regions where the first silicide layers 75 and the second silicide layers 76 are to be formed and covers the other regions.

Specifically, the seventh mask M7 has a layout that exposes the mesa portions defined in the regions between the trenches 41 and covers the other regions. Next, unnecessary portions of the second barrier insulating film 118 are removed by an etching method via the seventh mask M7. The etching method may be a wet etching method and/or a dry etching method.

Next, with reference to FIG. 18T, a metal film 119 is formed on the first wafer main surface 103. The metal film 119 is a seed metal for the first silicide layers 75 and the second silicide layers 76. The metal film 119 may include at least one of a Ti film, an Ni film, a Co film, an M film, and a W film. The metal film 119 may be formed by a sputtering method. The metal film 119 covers the second barrier insulating film 118 and portions of the first wafer main surface 103 that are exposed from the second barrier insulating film 118.

Next, the metal film 119 is reacted with the wafer W by a heat treatment method, and the first silicide layers 75 and the second silicide layers 76 are thereby formed on the surface layer portion of the first wafer main surface 103. The heat treatment method may be an RTA method (Rapid Thermal Annealing method). After the heat treatment step, the unreacted portions of the metal film 119 are removed.

The metal film 119 may be removed by an etching method (wet etching method and/or dry etching method). The second barrier insulating film 118 is removed after the step of removing the metal film 119. The second barrier insulating film 118 may be removed by an etching method (wet etching method and/or dry etching method).

Next, with reference to FIG. 18U, the contact insulating film 87 is formed on the first

wafer main surface 103. The contact insulating film 87 covers the separation structure 30, the connection structures 80 and the field insulating film 85 on the first wafer main surface 103, and covers the electrode surfaces 50 and the edge portion insulators 60 within the trenches 41. The contact insulating film 87 includes an insulator different from the insulator that constitutes the recess insulating film 57 (the insulating recess edge portion 58) in this embodiment. The contact insulating film 87 includes the nitride film (silicon nitride film) and is formed by a CVD method in this embodiment.

Next, with reference to FIG. 18V, the lowermost interlayer film 10a of the interlayer film 10 is formed on the first wafer main surface 103. Specifically, the lowermost interlayer film 10a is formed on the contact insulating film 87. The lowermost interlayer film 10a includes an insulator that has properties different from those of the edge portion insulator 60 (the edge insulating film 61) in this embodiment. Specifically, the lowermost interlayer film 10a includes an insulator that has an etching rate different from the etching rate of the edge portion insulator 60 (the edge insulating film 61). The lowermost interlayer film 10a includes the oxide film (specifically the silicon oxide film) and is formed by a CVD method in this embodiment.

Next, an eighth mask M8 having a predetermined pattern is formed on the lowermost interlayer film 10a. The eighth mask M8 has a layout that exposes regions where the contact openings 93 for the gate contact electrode 92 and the source contact electrodes 97 are to be formed, and covers the other regions.

Next, unnecessary portions of the lowermost interlayer film 10a are removed by an etching method (for example) via the eighth mask M8. The etching method may be a wet etching method and/or a dry etching method. Through this step, the contact openings 93 are formed in the lowermost interlayer film 10a.

In this step, the edge portion insulators 60 include an insulating material different from that of the lowermost interlayer film 10a, and thus functions as an etching stopper against the etching of the lowermost interlayer film 10a. In other words, if misalignment occurs in the eighth mask M8, the contact openings 93 may be formed directly above the edge portion insulators 60. This risk increases as the trench pitch TP becomes narrower. For example, a narrow pitch means a state in which the trench pitch TP is less than the gate width WG of the gate structure 40.

In a case in which the contact openings 93 are formed directly above the edge portion insulators 60, the etchant for the lowermost interlayer film 10a is in contact with the edge portion insulators 60 through the contact openings 93. If the insulating material of the edge portion insulators 60 is the same as the insulating material of the lowermost interlayer film 10a, parts or all of the edge portion insulators 60 are removed by the etchant for the lowermost interlayer film 10a.

However, because the edge portion insulator 60 includes the insulating material different from the insulating material of the lowermost interlayer film 10a, undesired loss of the edge portion insulators 60 due to etching is suppressed. Through this step, the etchant for the lowermost interlayer film 10a is suppressed from intruding into the recess edge portions 52. That is, undesired loss of the insulating film 42 (the first insulating film 47, the second insulating film 48, etc.) due to the etchant for the lowermost interlayer film 10a is also suppressed.

Next, with reference to FIG. 18W, a base contact electrode 120 is formed in the lowermost interlayer film 10a. The base contact electrode 120 serves as a base for the gate contact electrodes 92 and the source contact electrodes 97. The base contact electrode 120 is embedded in the contact openings 93 and formed so as to cover the lowermost interlayer film 10a.

The base contact electrode 120 has a laminated structure including the first electrode film 94 and the second electrode film 95 laminated in that order from the lowermost interlayer film 10a side. The first electrode film 94 may be formed by a sputtering method, and the second electrode film 95 may be formed by a sputtering method.

Next, with reference to FIG. 18X, unnecessary portions of the base contact electrodes 120 are removed by an etching method. The etching method may be a wet etching method and/or a dry etching method. The base contact electrode 120 is removed until the lowermost interlayer film 10a is exposed. Through this step, the gate contact electrodes 92 and the source contact electrodes 97 are formed.

Thereafter, the remaining manufacturing steps are carried out with respect to the wafer W, and the wafer W is cut along the planned cutting lines 108. Through those steps, the semiconductor devices 1 are manufactured from one wafer W.

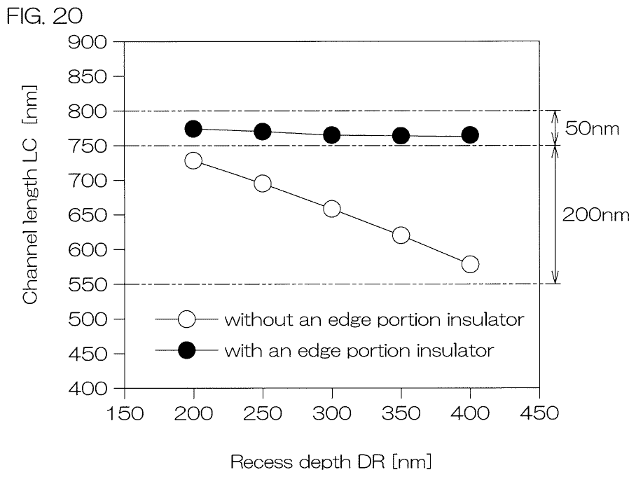

FIG. 20 is a graph showing a relationship between the channel length LC and the recess depth DR. In FIG. 20, a vertical axis indicates the channel length LC, and a horizontal axis indicates the recess depth DR of the opening recess 51. As it approaches a left side of the horizontal axis, it gets closer to the center of the wafer W, and as it approaches a right side of the horizontal axis, it gets closer to the peripheral edge of the wafer W.

The graph shown in FIG. 20 includes a first characteristic S1 and a second characteristic S2. The first characteristic S1 shows characteristics of the channel length LC when the edge portion insulator 60 is not included, and is composed of five white circle plot points. The second characteristic S2 shows characteristics of the channel length LC when the edge portion insulator 60 is included, and is composed of five black circle plot points.

With reference to the first characteristic S1, when the edge portion insulator 60 is not included, the recess depths DR (depth positions of the recess edge portions 52) increased from the central portion to the peripheral edge portion of the wafer W, while the depth positions of the source regions 71 with respect to the bottom portions of the body regions 65 increased and the channel lengths LC decreased.

That is, the recess depth DR (depth position of the recess edge portion 52) of the second device region 107B was larger than the recess depth DR (depth position of the recess edge portion 52) of the first device region 107A. Also, the channel length LC of the second device region 107B was smaller than the channel length LC of the first device region 107A.

With reference to specific values, in the case of the first characteristic S1, when the recess depths DR increased from 200 nm to 400 nm, the channel lengths LC decreased from 730 μm to 580 μm. That is, when 100 nm is taken as one unit, the amount of decrease in the channel length LC of the recess depth DR per unit was not less than 50 nm and not more than 100 nm (specifically, about 75 nm).

In a case in which a differential value between the recess depth DR on the first device region 107A side and the recess depth DR on the second device region 107B side is more than 0 nm and not more than 100 nm, a differential value between the channel length LC of the first device region 107A and the channel length LC of the second device region 107B falls within a range of not less than 50 nm and not more than 100 nm.

Also, in a case in which the differential value between the recess depths DR is not less than 100 nm and not more than 200 nm, the differential value between the channel lengths LC falls within a range of not less than 100 nm and not more than 200 nm. That is, in a case in which the differential value between the recess depths DR is more than 0 nm and not more than 200 nm, the differential value between the channel lengths LC falls within a range of not less than 50 nm and not more than 200 nm.

On the other hand, with reference to the second characteristic S2, when the edge portion insulator 60 is included, the recess depths DR (depth positions of the recess edge portions 52) increased from the central portion to the peripheral edge portion of the wafer W, while the depth positions of the source regions 71 with respect to the bottom portions of the body regions 65 increased and the channel lengths LC decreased.

That is, the recess depth DR (depth position of the recess edge portion 52) of the second device region 107B was larger than the recess depth DR (depth position of the recess edge portion 52) of the first device region 107A. Also, the channel length LC of the second device region 107B was shorter than the channel length LC of the first device region 107A. However, a decrease amount (decrease rate) of the channel length LC of the second characteristic S2 was less than a decrease amount (decrease rate) of the channel length LC of the first characteristic S1.

With reference to the specific values, in the case of the second characteristic S2, when the recess depths DR increased from 200 nm to 400 nm, the channel lengths LC decreased from 775 μm to 765 μm. That is, when 100 nm is taken as one unit, the amount of decrease in the channel length LC of the recess depth DR per unit was not less than 5 nm and not more than 25 nm (specifically, about 10 nm).

In a case in which a differential value between the recess depth DR on the first device region 107A side and the recess depth DR on the second device region 107B side is more than 0 nm and not more than 100 nm, a differential value between the channel length LC of the first device region 107A and the channel length LC of the second device region 107B falls within a range of not less than 5 nm and not more than 25 nm.

Also, in a case in which the differential value between the recess depths DR is not less than 100 nm and not more than 200 nm, the differential value between the channel lengths LC falls within a range of not less than 10 nm and not more than 50 nm. That is, in a case in which the differential value between the recess depths DR is not more than 0 nm and not more than 200 nm, the differential value between the channel lengths LC falls within a range of not less than 5 nm and not more than 50 nm.

As described above, according to the manufacturing method for the semiconductor device 1, the same effects as those described for the semiconductor device 1 above can be achieved. Also, according to the manufacturing method for the semiconductor device 1, the in-plane variation of the channel lengths LC in the wafer W can be suppressed. Also, according to the manufacturing method for the semiconductor device 1, the wafer structure in which the in-plane variation of the channel lengths LC in the wafer W is suppressed can be manufactured and provided.

For example, by suppressing the in-plane variation of the channel lengths LC, an in-plane variation of the gate threshold voltages can be suppressed. The in-plane variation of the gate threshold voltages may be calculated by a differential value (absolute value) between the gate threshold voltage on the first device region 107A side and the gate threshold voltage on the second device region 107B side. When the edge portion insulator 60 does not exist, the in-plane variation of the gate threshold voltages is not less than 0.05 V and not more than 0.1 V. On the other hand, when the edge portion insulator 60 is formed, the in-plane variation of the gate threshold voltages is not less than 0.001 V and not more than 0.02 V. The in-plane variation of the gate threshold voltages may have a value falling within at least one of ranges of not less than 0.001 V and not more than 0.005 V, not less than 0.005 V and not more than 0.01 V, not less than 0.01 V and not more than 0.015 V, and not less than 0.015 V and not more than 0.02 V. It is preferable that the in-plane variation of the gate threshold voltages is adjusted to not more than 0.015 V.

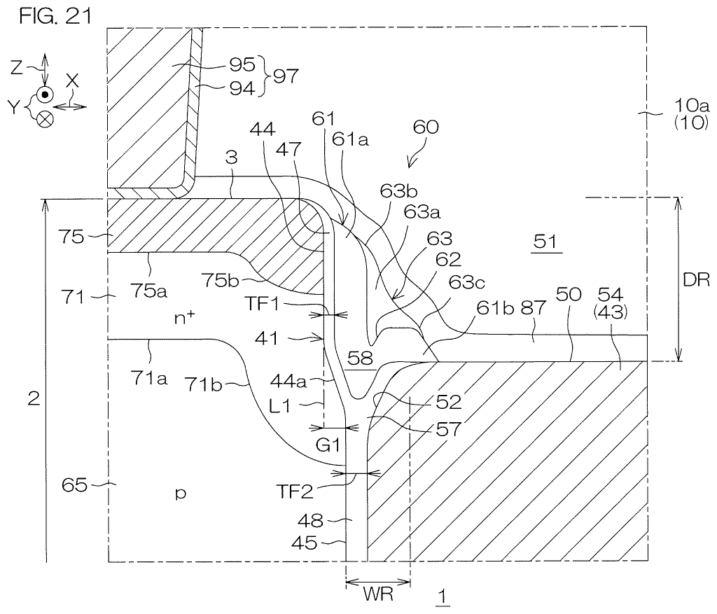

Hereinafter, with reference to FIG. 21 to FIG. 25, some other configuration examples of the gate structure 40 shall be described. The configuration examples shown in FIG. 21 to FIG. 25 may be applied independently to the aforementioned configuration. As a matter of course, a configuration example in which at least two of the configuration examples shown in FIG. 21 to FIG. 25 are combined may be applied to the aforementioned configuration. The structures shown in FIG. 21 to FIG. 25 can be obtained by appropriately adjusting the process conditions in the aforementioned manufacturing steps.

FIG. 21 is a cross sectional view showing the gate structure 40 according to another configuration example. The embedded electrode 43 according to the aforementioned embodiment has the protruding edge portion 53 that protrudes from the edge portion of the electrode surface 50 toward the opening side. However, with reference to FIG. 21, the embedded electrode 43 does not necessarily have to have the protruding edge portion 53 on the electrode surface 50. That is, the embedded electrode 43 may have the electrode surface 50 located on the opening side of the trench 41 (the first main surface 3 side) with respect to the recess edge portion 52.

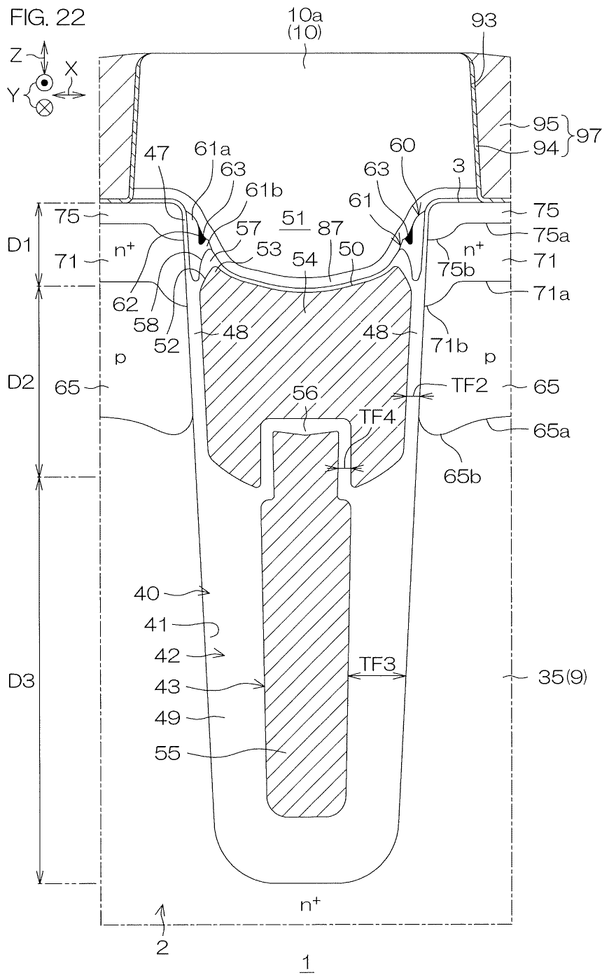

FIG. 22 is a cross sectional view showing the gate structure 40 according to another configuration example. The gate structure 40 according to the aforementioned embodiment includes the trench 41 having the first trench portion 44, the second trench portion 45, and the third trench portion 46. However, with reference to FIG. 22, the gate structure 40 may include the trench 41 without the first trench portion 44, the second trench portion 45, and the third trench portion 46.

The trench 41 is formed in a tapered shape having an opening width that gradually narrows from the opening side toward the bottom wall side of the trench 41 in the cross sectional view, in this embodiment. As a matter of course, the trench 41 may be formed substantially perpendicular with respect to the first main surface 3.

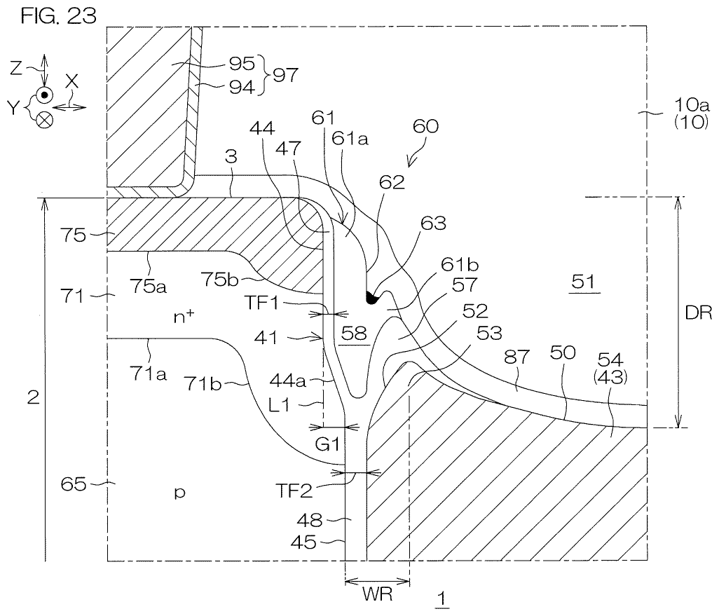

FIG. 23 is a cross sectional view showing the gate structure 40 according to another configuration example. The insulating buried object 63 in the aforementioned embodiment was buried in a substantially whole region of the groove portion 62 in the cross sectional view. That is, the contact insulating film 87 covered the region of the edge insulating film 61 outside the groove portion 62. However, with reference to FIG. 23, the insulating buried object 63 may be buried at an interval to the bottom wall side of the groove portion 62 from the opening end portion of the groove portion 62 in the cross sectional view. That is, the insulating buried object 63 exposes the opening end portion of the groove portion 62 in the cross sectional view.

On the other hand, the contact insulating film 87 has a portion that enters the groove portion 62 from on the edge insulating film 61 in this embodiment. The portion of the contact insulating film 87 that is located within the groove portion 62 covers the insulating buried object 63 within the groove portion 62. The contact insulating film 87 may be in direct contact with the edge insulating film 61 (the first extension portion 61a and the second extension portion 61b) within the groove portion 62. Also, the contact insulating film 87 may be in direct contact with the insulating buried object 63 within the groove portion 62.

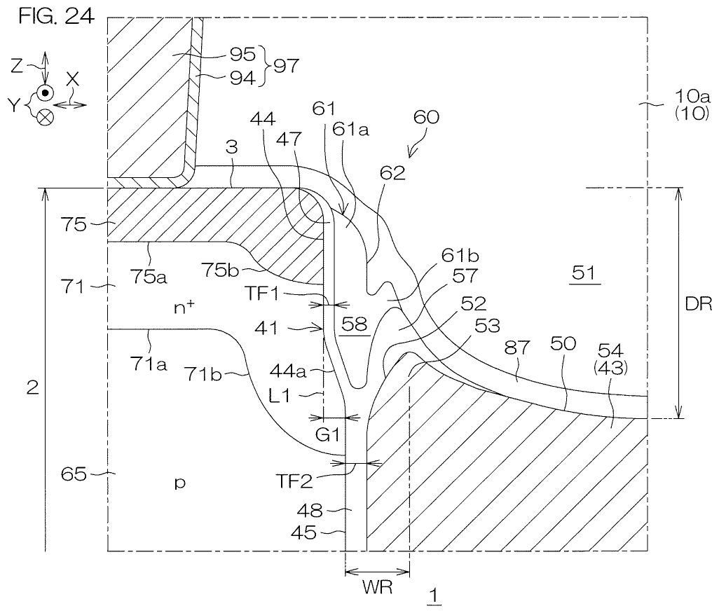

FIG. 24 is a cross sectional view showing the gate structure 40 according to another configuration example. The edge portion insulator 60 in the aforementioned embodiment has a laminated structure including the edge insulating film 61 and the insulating buried object 63.

However, with reference to FIG. 24, the edge portion insulator 60 may have a single-layer structure consisting of only the edge insulating film 61 without the insulating buried object 63.

On the other hand, the contact insulating film 87 has a portion that enters the groove portion 62 from on the edge insulating film 61 in this embodiment. The contact insulating film 87 may be in direct contact with the edge insulating film 61 (the first extension portion 61a and the second extension portion 61b) within the groove portion 62.

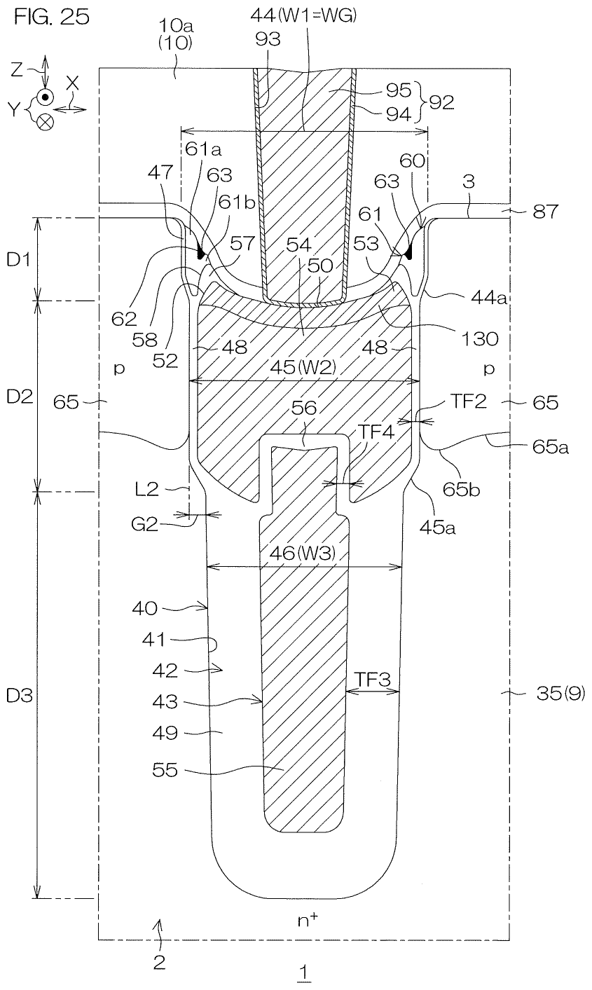

FIG. 25 is a cross sectional view showing the gate structure 40 according to another configuration example. The embedded electrode 43 in the aforementioned embodiment has the electrode surface 50 from which the polysilicon (the first electrode 54) is exposed. However, with reference to FIG. 25, the embedded electrode 43 may have a silicide buried layer 130 formed in a surface layer portion of the electrode surface 50.

The silicide buried layer 130 consists of a region in which the surface layer portion of the electrode surface 50 (the first electrode 54) is silicided with a metal material. The silicide buried layer 130 is composed of a polycide containing the impurity of the embedded electrode 43 (the first electrode 54). The silicide buried layer 130 may include at least one of a TiSi layer, a TiSi₂ layer, an NiSi layer, a CoSi layer, a CoSi₂ layer, an MoSi₂ layer, and a WSi₂ layer.

The silicide buried layer 130 may be exposed from a whole region of the electrode surface 50. The silicide buried layer 130 may form at least a part of or a whole of the recess edge portion 52. The silicide buried layer 130 may form at least a part or a whole of the protruding edge portion 53. A portion of the contact insulating film 87 that covers the electrode surface 50 may cover the silicide buried layer 130. The silicide buried layer 130 may be formed simultaneously with the first silicide layer 75 and the second silicide layer 76.

The aforementioned embodiment can be embodied in other embodiments. For example, in the aforementioned embodiment, an example in which the output region 6 and the control region 7 are formed in the single chip 2 has been shown. However, the semiconductor device 1 having the output region 6 without the control region 7 may be adopted. Also, the semiconductor device 1 having the control region 7 without the output region 6 may be adopted. As a matter of course, the semiconductor device 1 having the output region 6 and the semiconductor device 1 having the control region 7 may constitute the IPD as shown in FIG. 3 be being incorporated into a semiconductor module, a semiconductor circuit, or the like.

In the aforementioned embodiment, the output transistor 15 of multiple systems has been shown. However, the output transistor 15 of a single system may be adopted. In this case, the second system transistor 16B is formed as the first system transistor 16A, and all the gate structures 40 for the output transistor 15 are simultaneously controlled to be on and off.

As a matter of course, in the aforementioned embodiment, the output transistor 15 of not less than three systems may be adopted. In this case, the group regions 77 for the system transistors 16 constituting not less than three systems are provided, and at the same time, the gate wirings 91 of not less than three systems corresponding to the group regions 77 are provided.

In the aforementioned embodiment, a configuration having the current monitor circuit 20 has been shown. The current monitor circuit 20 may be formed using at least one of the unit transistors 17.

In the aforementioned embodiment, an example has been shown in which the first electrode 54 and the second electrode 55 are controlled to be in the same potential. However, the source potential may be applied to the second electrode 55. In this case, the source wiring 96 is electrically connected to the connection electrodes 83 via the source contact electrodes 97.

In the aforementioned embodiment, an example has been shown in which the source terminal 11 is the output terminal and the drain terminal 13 is the power supply terminal. However, a configuration in which the source terminal 11 is a ground terminal and the drain terminal 13 is an output terminal may be adopted. In this case, the semiconductor device 1 becomes a low side switching device electrically connected between the load (the inductive load L) and the ground.

In the aforementioned embodiment, an example is shown in which the first conductivity type is the n-type and the second conductivity type is the p-type. However, the first conductivity type may be the p-type and the second conductivity type may be the n-type. In this case, the specific configuration can be obtained by replacing the n-type region with the p-type region and at the same time replacing the p-type region with the n-type region in the above descriptions and the attached drawings.

In the aforementioned embodiment, the first direction X and the second direction Y are defined by the extending directions of the first to fourth side surfaces 5A to 5D. However, the first direction X and the second direction Y may be any directions as long as they maintain a mutually intersecting (specifically perpendicular) relationship. For example, the first direction X may be an extending direction of the third side surfaces 5C (the fourth side surfaces 5D), and the second direction Y may be n extending direction of the first side surface 5A (the second side surfaces 5B). Also, the first direction X may be a direction intersecting the first to fourth side surfaces 5A to 5D, and the second direction Y may be a direction intersecting the first to fourth side surfaces 5A to 5D.

Hereinafter, examples of features extracted from this specification and the attached drawings are shown. Hereinafter, the alphanumeric characters in parentheses represent the corresponding components in the above described configurations, but are not intended to limit the scope of each Clause to the above described configurations. “Semiconductor device” according to the following Clauses may be replaced with “semiconductor switching device”, “semiconductor module”, “electronic circuit”, “semiconductor circuit”, “intelligent power device”, “intelligent power module”, “intelligent power switch”, “wafer structure”, “wafer intermediate body”, etc., as necessary.

[A1] A semiconductor device (1) comprising: a chip (2) that has a main surface (3); a trench (41) that is formed in the main surface (3), and that has a side wall and a bottom wall; an embedded electrode (43) that is embedded in the trench (41), and that has an electrode surface (50) positioned on the bottom wall side with respect to the main surface (3) and a recess edge portion (52) recessed toward the bottom wall side at an edge portion along the side wall in the electrode surface (50); and an edge portion insulator (60) that is embedded in the recess edge portion (52).

[A2] The semiconductor device (1) according to A1, wherein the edge portion insulator (60) includes an edge insulating film (61) that is formed in a film shape along the side wall of the trench (41) and a wall surface of the recess edge portion (52).

[A3] The semiconductor device (1) according to A2, wherein the embedded electrode (43) includes a silicon, and the edge insulating film (61) includes a nitride.

[A4] The semiconductor device (1) according to A2 or A3, wherein the edge insulating film (61) includes a first extension portion (61A) that covers the side wall of the trench (41) in a film shape, and a second extension portion (61B) that covers the recess edge portion (52) in a film shape so as to be inclined with respect to the first extension portion (61A).

[A5] The semiconductor device (1) according to A4, wherein the first extension portion (61A) is terminated within the trench (41), and the second extension portion (61B) is terminated within the trench (41).

[A6] The semiconductor device (1) according to A4 or A5, wherein the first extension portion (61A) has a first upper end portion positioned on an opening side of the trench (41), and the second extension portion (61B) has a second upper end portion positioned on the bottom wall side of the trench (41) with respect to the first upper end portion.

[A7] The semiconductor device (1) according to any one of A2to A6, wherein the

edge insulating film (61) defines a groove portion (62) that is grooved toward a bottom portion of the recess edge portion (52) above the recess edge portion (52).

[A8] The semiconductor device (1) according to A7, wherein the edge portion insulator (60) includes a buried object (63) that is buried in the groove portion (62).

[A9] The semiconductor device (1) according to A8, wherein the buried object (63) includes an insulating material different from that of the edge insulating film (61).

[A10] The semiconductor device (1) according to A8 or A9, wherein the buried object (63) includes an oxide.

[A11] The semiconductor device (1) according to A10, wherein the buried object (63) includes a tetraethyl orthosilicate as the oxide.

[A12] The semiconductor device (1) according to any one of A1 to A11, wherein the embedded electrode (43) includes a protruding edge portion (53) that protrudes toward an opening side of the trench (41) at the edge portion of the electrode surface (50), and that defines the recess edge portion (52) in a region between the side wall of the trench (41) and the embedded electrode (43).

[A13] The semiconductor device (1) according to any one of A1 to A12, wherein the trench (41) has an opening end (44) that is formed wider than the other portion (45, 46), and the recess edge portion (52) is defined along the opening end (44) of the trench (41).

[A14] The semiconductor device (1) according to any one of A1 to A13, further comprising: an insulating film (42) that covers the side wall of the trench (41); and wherein the embedded electrode (43) is in contact with the insulating film (42) in the trench (41), and the edge portion insulator (60) is in contact with the insulating film (42) in the recess edge portion (52).

[A15] The semiconductor device (1) according to any one of A1 to A14, further comprising: a contact insulating film (87) that covers the electrode surface (50) and the edge portion insulator (60) in a film shape in the trench (41).

[A16] The semiconductor device (1) according to A15, wherein the contact insulating film (87) has a film surface positioned on the electrode surface (50) side with respect to the main surface (3) in the trench (41).

[A17] The semiconductor device (1) according to any one of A1 to A16, further comprising: a source region (71) that is formed in a region along the side wall of the trench (41) in a surface layer portion of the main surface (3) so as to face both of the embedded electrode (43) and the edge portion insulator (60) in a horizontal direction along the main surface (3).

[A18] The semiconductor device (1) according to any one of A1 to A17, further comprising: a contact electrode (97) that is connected to the main surface (3) at a side of the trench (41).

[A19] The semiconductor device (1) according to any one of A1 to A18, further comprising: a silicide layer (75, 76) that faces the edge portion insulator (60) in a horizontal direction along the main surface (3) in a surface layer portion of the main surface (3).

[A20] The semiconductor device (1) according to any one of A1 to A19, further comprising: an inner contact electrode (92) that is connected to the electrode surface (50) at an interval from the edge portion insulator (60) in the trench (41).

[A21] The semiconductor device (1) according to any one of A1 to A20, wherein the trenches (41) are formed in the main surface (3) at an interval, the embedded electrodes (43) are each embedded in the trenches (41), and the edge portion insulators (60) are each embedded in the recess edge portions (52) within the trenches (41).

[A22] The semiconductor device (1) according to A21, wherein the trenches (41) are formed in the main surface (3) at an interval (P) less than a width (WG) of each of the trenches (41).

[A23] The semiconductor device (1) according to A21 or A22, further comprising: a mesa portion that is demarcated in a region between the trenches (41) at the main surface (3); and a contact electrode (97) that is connected to the mesa portion at intervals from the trenches (41).

[A24] A semiconductor device (1) comprising: a chip (2) that has a main surface (3); a trench (41) that is formed in the main surface (3), and that has side walls and a bottom wall; an embedded electrode (43) that is embedded in the trench (41), and that has an electrode surface (50) positioned on the bottom wall side with respect to the main surface (3) and recess edge portions (52) recessed toward the bottom wall side at edge portions on both sides of the electrode surface (50) in a cross sectional view; edge portion insulators (60) that are embedded in the recess edge portions (52) respectively in the cross sectional view; and an inner contact electrode (92) that is mechanically and electrically connected to an inner portion of the electrode surface (50) at intervals from the edge portion insulators (60).

[B1] A wafer structure comprising: a wafer (W) that has a main surface (103); a first device region (107A) that is set in an inner potion of the main surface (103); a second device region (107B) that is set in a peripheral edge portion of the main surface (103); trenches (41) each of which is formed in the main surface (103) at the first device region (107A) and at the second device region (107B), and has a side wall and a bottom wall; embedded electrodes (43) that are embedded in the trenches (41), and each of which has an electrode surface (50) positioned on the bottom wall side with respect to the main surface (103) and a recess edge portion (52) recessed toward the bottom wall side at an edge portion along the side wall in the electrode surface (50); and edge portion insulators (60) that are embedded in the recess edge portions (52) within the trenches (41).

[B2] The wafer structure according to B1, wherein the edge portion insulators (60) each includes an edge insulating film (61) that is formed in a film shape along the side wall of the corresponding trench (41) and a wall surface of the corresponding recess edge portion (52).

[B3] The wafer structure according to B2, wherein the edge portion insulators (60) each has a groove portion (62) that is defined by the edge insulating film (61) so as to be recessed toward a bottom portion of the corresponding recess edge portion (52).

[B4] The wafer structure according to B3, wherein the edge portion insulators (60) each includes a buried object (63) that is buried in the corresponding groove portion (62).

[B5] The wafer structure according to any one of B1 to B4, wherein the electrode surface (50) on the second device region (107B) side is located on a side of the bottom walls of the trenches (41) with respect to the electrode surface (50) on the first device region (107A) side.

[B6] The wafer structure according to any one of B1 to B5, wherein the recess edge portion (52) on the second device region (107B) side is located on a side of the bottom walls of the trenches (41) with respect to the recess edge portion (52) on the first device region (107A) side.

[B7] The wafer structure according to any one of B1 to B6, further comprising: a first channel that is formed in a region along the trench (41) at the first device region (107A); and a second channel that is formed in a region along the trench (41) at the second device region (107B).

[B8] The wafer structure according to B7, wherein a channel length (LC) of the second channel is shorter than a channel length (LC) of the first channel.

[B9] The wafer structure according to B8, wherein a differential value of the channel length (LC) of the second channel with respect to the channel length (LC) of the first channel is not less than 5 nm and not more than 50 nm. [B10] The wafer structure according to any one of B1 to B9, wherein a differential value of a gate threshold voltage on the second device region (107B) side with respect to a gate threshold voltage on the first device region (107A) side is not less than 0.001 V and not more than 0.02 V.

[B11] The wafer structure according to any one of B1 to B10, further comprising: a drift region (9) of a first conductivity type (n-type) that is formed in a surface layer portion of the main surface (103) at the first device region (107A) and the second device region (107B); body regions (65) of a second conductivity type (p-type) each of which is formed in surface layer portions of the drift region (9) along the trenches (41) at the first device region (107A) and the second device region (107B); and source regions (71) of the first conductivity type (p-type) each of which is formed in surface layer portions of the body regions (65) along the trenches (41) at the first device region (107A) and the second device region (107B).

[B12] The wafer structure according to any one of B1 to B11, further comprising: insulating films (42) each of which covers the side walls of the trenches (41); and wherein the embedded electrodes (43) are in contact with the corresponding insulating film (42) within the corresponding trench (41), and the edge portion insulators (60) are in contact with the corresponding insulating film (42) within the corresponding recess edge portion (52).

[B13] The wafer structure according to any one of B1 to B12, further comprising: a contact insulating film (87) that covers the electrode surface (50) and the edge portion insulator (60) in a film shape within the trench (41) of the first device region (107A), and covers the electrode surface (50) and the edge portion insulator (60) in a film shape within the trench (41) of the second device region (107B).

[B14] The wafer structure according to any one of B1 to B13, further comprising: contact electrodes (97) that are connected to the main surface (103) at sides of the trenches (41) in the first device region (107A) and the second device region (107B).

[B15] The wafer structure according to any one of B1 to B14, further comprising: silicide layers (75, 76) that face the corresponding edge portion insulator (60) in a horizontal direction along the main surface (103) in surface layer portions of the main surface (103) at the first device region (107A) and the second device region (107B).

While embodiments of the present invention have been described in detail above, those are merely specific examples used to clarify the technical contents. The various technical ideas extracted from this Description are not limited by the order of description, the order of the embodiments, etc., in the Description and can be combined as appropriate with each other.

What is claimed is:

1. A semiconductor device comprising:
a chip that has a main surface;
a trench that is formed in the main surface, and that has a side wall and a bottom wall;
an embedded electrode that is embedded in the trench, and that has an electrode surface positioned on the bottom wall side with respect to the main surface and a recess edge portion recessed toward the bottom wall side at an edge portion along the side wall in the electrode surface; and
an edge portion insulator that is embedded in the recess edge portion.

2. The semiconductor device according to claim 1,
wherein the edge portion insulator includes an edge insulating film that is formed in a film shape along the side wall of the trench and a wall surface of the recess edge portion.

3. The semiconductor device according to claim 2,
wherein the embedded electrode includes a silicon, and
the edge insulating film includes a nitride.

4. The semiconductor device according to claim 2,
wherein the edge insulating film includes a first extension portion that covers the side wall of the trench in a film shape, and a second extension portion that covers the recess edge portion in a film shape so as to be inclined with respect to the first extension portion.

5. The semiconductor device according to claim 4,
wherein the first extension portion is terminated within the trench, and
the second extension portion is terminated within the trench.

6. The semiconductor device according to claim 4,
wherein the first extension portion has a first upper end portion positioned on an opening side of the trench, and
the second extension portion has a second upper end portion positioned on the bottom wall side of the trench with respect to the first upper end portion.

7. The semiconductor device according to claim 2,
wherein the edge insulating film defines a groove portion that is grooved toward a bottom portion of the recess edge portion above the recess edge portion.

8. The semiconductor device according to claim 7,
wherein the edge portion insulator includes a buried object that is buried in the groove portion.

9. The semiconductor device according to claim 8,
wherein the buried object includes an insulating material different from that of the edge insulating film.

10. The semiconductor device according to claim 8,
wherein the buried object includes an oxide.

11. The semiconductor device according to claim 10,
wherein the buried object includes a tetraethyl orthosilicate as the oxide.

12. The semiconductor device according to claim 1,
wherein the embedded electrode includes a protruding edge portion that protrudes
toward an opening side of the trench at the edge portion of the electrode surface, and that defines
the recess edge portion in a region between the side wall of the trench and the embedded electrode.

13. The semiconductor device according to claim 1,
wherein the trench has an opening end that is formed wider than the other portion, and
the recess edge portion is defined along the opening end of the trench.

14. The semiconductor device according to claim 1, further comprising:
an insulating film that covers the side wall of the trench; and
wherein the embedded electrode is in contact with the insulating film in the trench, and
the edge portion insulator is in contact with the insulating film in the recess edge portion.

15. The semiconductor device according to claim 1, further comprising:
a contact insulating film that covers the electrode surface and the edge portion insulator in a film shape in the trench.

16. The semiconductor device according to claim 15,
wherein the contact insulating film has a film surface positioned on the electrode surface side with respect to the main surface in the trench.

17. The semiconductor device according to claim 1, further comprising:
a source region that is formed in a region along the side wall of the trench in a surface layer portion of the main surface so as to face both of the embedded electrode and the edge portion insulator in a horizontal direction along the main surface.

18. The semiconductor device according to claim 1, further comprising:
an outer contact electrode that is connected to the main surface at a side of the trench.

19. The semiconductor device according to claim 1, further comprising:
a silicide layer that faces the edge portion insulator in a horizontal direction along the main surface in a surface layer portion of the main surface.

20. The semiconductor device according to claim 1, further comprising:
an inner contact electrode that is connected to the electrode surface at an interval from the edge portion insulator in the trench.
